(19) United States
(12) Patent Application Publication
(10) Pub. No.: US 2025/0107313 A1
(43) Pub. Date: Mar. 27, 2025

(54) LIGHT-EMITTING ELEMENT, HETEROCYCLIC COMPOUND FOR LIGHT-EMITTING ELEMENT, AND ELECTRONIC DEVICE INCLUDING THE LIGHT-EMITTING ELEMENT

(71) Applicant: Samsung Display Co., Ltd., Yongin-si (KR)

(72) Inventor: HYUNYOUNG KIM, Yongin-si (KR)

(21) Appl. No.: 18/896,608

(22) Filed: Sep. 25, 2024

(30) Foreign Application Priority Data
Sep. 26, 2023 (KR) 10-2023-0129583
Sep. 24, 2024 (KR) 10-2024-0128602

(51) Int. Cl. H10K 50/11; C09K 11/06; H10K 59/38; H10K 85/30; H10K 85/40; H10K 85/60; H10K 102/00

(52) U.S. Cl. CPC H10K 50/11; C09K 11/06; H10K 59/38; H10K 85/346; H10K 85/40; H10K 85/654; H10K 85/658; C09K 2211/1014; H10K 2102/331

(57) ABSTRACT

A light-emitting element, a heterocyclic compound for the light-emitting element, and a display device including the light-emitting element are provided. The light-emitting element includes a first electrode, a second electrode on the first electrode, and at least one functional layer between the first electrode and the second electrode and including a first compound represented by Formula 1.

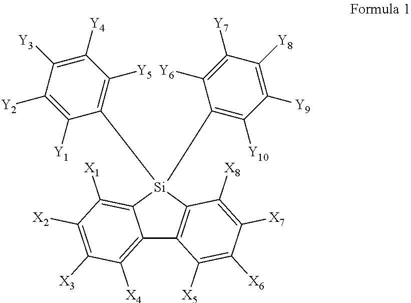

### CROSS-REFERENCE TO RELATED APPLICATIONS

The present application claims priority to and the benefit of Korean Patent Application No. 10-2023-0129583, filed on Sep. 26, 2023, and Korean Patent Application No. 10-2024-0128602, filed on Sep. 24, 2024, in the Korean Intellectual Property Office, the entire content of each of which is incorporated herein by reference.

### BACKGROUND

### 1. Field

One or more embodiments of the present disclosure relate to a light-emitting element, a heterocyclic compound utilized for the same, and an electronic device including the light-emitting element.

### 2. Description of the Related Art

Electronic devices include display devices. Recently, organic electroluminescence display devices and/or the like as image display devices have been actively developed. The organic electroluminescence display devices and/or the like are display devices including a self-luminous type or kind of a light-emitting element that recombines holes and electrons in a light-emitting layer of the light-emitting element, injected, respectively, from a first electrode and a second electrode of the light-emitting element, thereby emitting light utilizing a light-emitting material of the light-emitting layer of the light-emitting element to implement displays (e.g., of images).

In applying a light-emitting element to display devices, improvements in light efficiency, lifespan, and/or the like of the light-emitting element are desired or required, and the development of materials for the light-emitting element capable of stably achieving such improvements is continuously desired or pursued.

### SUMMARY

One or more aspects of embodiments of the present disclosure are directed toward a light-emitting element having low voltage characteristics, and improved (e.g., high or desired) emission efficiency and long lifespan characteristics.

One or more aspects of embodiments of the present disclosure are directed toward a heterocyclic compound for improving the emission efficiency and lifespan of a light-emitting element.

One or more aspects of embodiments of the present disclosure are directed toward an electronic device having excellent or suitable display quality by including a light-emitting element that exhibits low voltage characteristics and has improved emission efficiency and lifespan characteristics.

Additional aspects will be set forth in part in the description which follows and, in part, will be apparent from the description, or may be learned by practice of the presented embodiments.

According to one or more embodiments of the disclosure, a light-emitting element includes a first electrode, a second electrode on the first electrode, and at least one functional layer between the first electrode and the second electrode and containing a first compound represented by Formula 1.

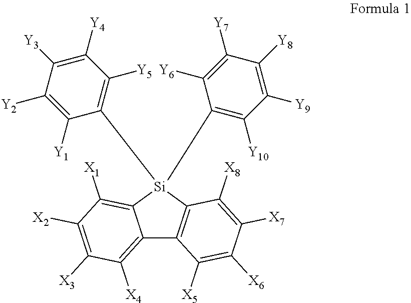

In Formula 1, X₁ to X₈ and Y₁ to Y₁₀ may each independently be hydrogen, deuterium, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 5 to 30 ring-forming carbon atoms.

In one or more embodiments, the at least one functional layer may include a hole transport region on the first electrode, an emission layer on the hole transport region, and an electron transport region on the emission layer, and the emission layer may include the first compound represented by Formula 1.

In one or more embodiments, the emission layer may include a second compound represented by Formula ET.

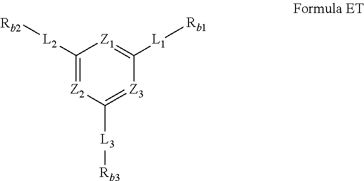

In Formula ET, at least one selected from among Z₁ to Z₃ may be N, and the rest may be CR_{b4}. R_{b1} to R_{b3} may each independently be hydrogen, deuterium, a halogen, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R_{b4} may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms. L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

In one or more embodiments, the emission layer may further include a third compound represented by Formula F-1.

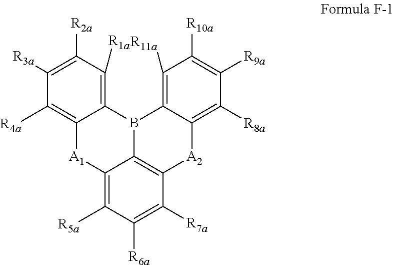

In Formula F-1, A₁ and A₂ may each independently be NRₘ or O. Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ₐ to R₁₁ₐ may each independently be hydrogen, deuterium, a halogen, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or may be bonded with an adjacent group to form a ring.

In one or more embodiments, the emission layer may further include a fourth compound represented by Formula D-1.

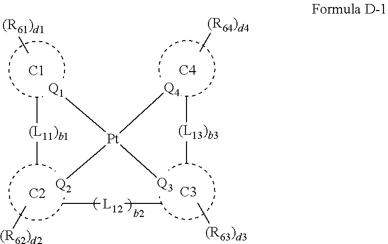

In Formula D-1, Q₁ to Q₄ may each independently be C or N, C₁ to C₄ may each independently be a substituted or unsubstituted hydrocarbon ring having 5 to 30 ring-forming carbon atoms or a substituted or unsubstituted hetero ring having 2 to 30 ring-forming carbon atoms, L₁₁ to L₁₃ may each independently be a direct linkage,

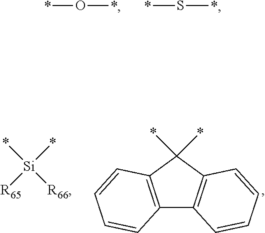

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b1 to b3 may each independently be 0 or 1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and d1 to d4 may each independently be an integer of 0 to 4.

In one or more embodiments, the emission layer may be to emit blue light with a maximum center wavelength of about 470 nanometers (nm) or less.

In one or more embodiments, in Formula 1, at least one selected from among X₁ to X₈ and Y₁ to Y₁₀ is represented by Formula 1a or Formula 1b.

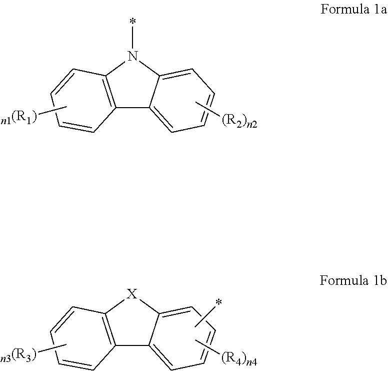

In Formula 1a and Formula 1b, X may be O or S, and R₁ to R₄ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring. n1 to n3 may each independently be an integer of 0 to 4, and n4 may be an integer of 0 to 3.

In one or more embodiments, at least one selected from among X₁ to X₈ in Formula 1 may be represented by Formula 1a or Formula 1b; and the remaining among X₁ to X₈, which are not represented by Formula 1a or Formula 1b, and Y₁ to Y₁₀ may each independently be hydrogen, deuterium, a substituted or unsubstituted methyl group, a substituted or unsubstituted phenyl group, or a substituted or unsubstituted carbazole group

In one or more embodiments, the first compound represented by Formula 1 may be represented by Formula 2 or Formula 3.

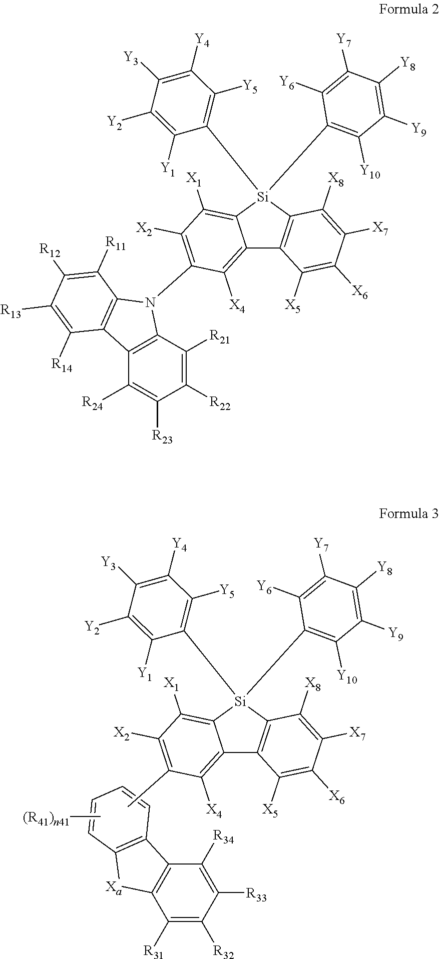

In Formula 2 and Formula 3, Xₐ may be O or S, R₁₁ to R₁₄, R₂₁ to R₂₄, and R₃₁ to R₃₄ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring. R₄₁ may be hydrogen or deuterium, n41 may be an integer of 0 to 3, and X₁, X₂, X₄ to X₈, and Y₁ to Y₁₀ may each be the same as defined in Formula 1.

In one or more embodiments, the first compound represented by Formula 2 may be represented by Formula 2-1 or Formula 2-2.

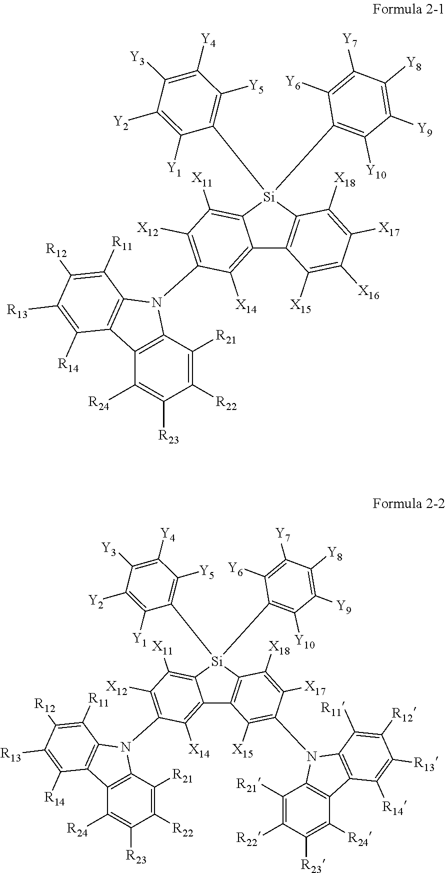

In Formula 2-1 and Formula 2-2, X₁₁, X₁₂, X₁₄, X₁₅, X₁₆, X₁₇, and X₁₈ may each independently be hydrogen or deuterium. R₁₁′ to R₁₄′ and R₂₁′ to R₂₄′ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring, and Y₁ to Y₁₀, R₁₁ to R₁₄, and R₂₁ to R₂₄ may each be the same as defined in Formula 1 and Formula 2.

In one or more embodiments, the first compound represented by Formula 3 may be represented by Formula 3-1 or Formula 3-2.

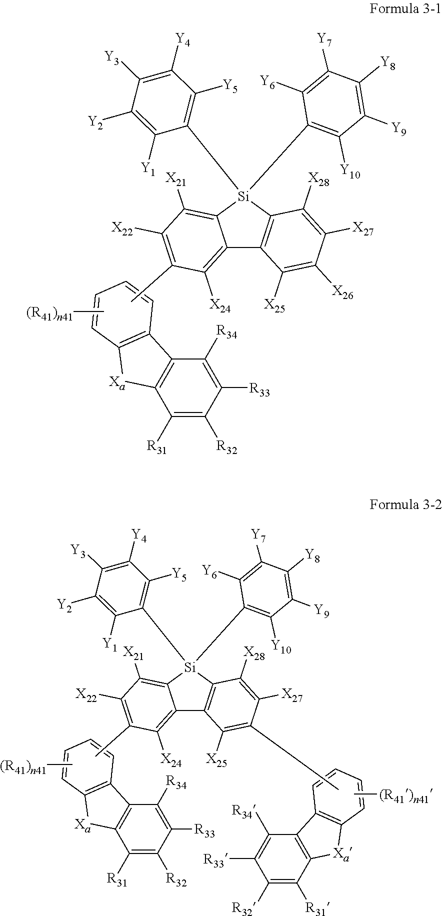

In Formula 3-1 and Formula 3-2, Xₐ′ may be 0 or S. X₂₁, X₂₂, X₂₄, X₂₅, X₂₆, X₂₇, X₂₈, and R₄₁′ may each independently be hydrogen or deuterium. R₃₁′ to R₃₄′ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring. n41′ may be an integer of 0 to 3, and Xₐ, Y₁ to Y₁₀, R₃₁ to R₃₄, R₄₁, and n41 may each be the same as defined in Formula 1 and Formula 3.

In one or more embodiments, Y₃ and Y₈ may each independently be hydrogen, deuterium, a substituted or unsubstituted methyl group, a substituted or unsubstituted phenyl group, or a substituted or unsubstituted carbazole group.

In one or more embodiments, the first compound may be represented by any one selected from among compounds in Compound Group 1, which will be described in more detail later.

In one or more embodiments of the disclosure, a heterocyclic compound may be represented by Formula 1.

### BRIEF DESCRIPTION OF THE DRAWINGS

The accompanying drawings are included to provide a further understanding of the disclosure, and are incorporated in and constitute a part of this disclosure. The drawings illustrate embodiments of the disclosure and, together with the description, serve to explain principles of the disclosure. Above and/or other aspects of the present disclosure should become apparent and appreciated from the following description of embodiments taken in conjunction with the accompanying drawings. In the drawings:

FIG. 1 is a plan view illustrating a display device according to one or more embodiments of the present disclosure;

FIG. 2 is a cross-sectional view illustrating a portion taken along the line I-I′ in FIG. 1;

FIG. 3 is a cross-sectional view schematically illustrating a light-emitting element according to one or more embodiments of the present disclosure;

FIG. 4 is a cross-sectional view schematically illustrating a light-emitting element according to one or more embodiments of the present disclosure;

FIG. 5 is a cross-sectional view schematically illustrating a light-emitting element according to one or more embodiments of the present disclosure;

FIG. 6 is a cross-sectional view schematically illustrating a light-emitting element according to one or more embodiments of the present disclosure;

FIG. 7 is a cross-sectional view schematically illustrating a light-emitting element according to one or more embodiments of the present disclosure;

FIG. 8 is a cross-sectional view illustrating a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure;

FIG. 11 is a cross-sectional view illustrating a display device according to one or more embodiments of the present disclosure; and

FIG. 12 is a view illustrating an inside of a vehicle in which display devices according to one or more embodiments are arranged.

### DETAILED DESCRIPTION

The disclosure may be modified in one or more suitable manners and have many forms, and thus specific embodiments will be exemplified in the drawings and described in more detail in the detailed description of present disclosure. It should be understood, however, that it is not intended to limit the disclosure to the particular forms disclosed, but rather, is intended to cover all modifications, equivalents, and alternatives falling within the spirit and scope of the disclosure.

When explaining each of drawings, like reference numbers are utilized for referring to like elements. In the accompanying drawings, the dimensions of each structure may be exaggeratingly illustrated for clarity of the present disclosure. It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the disclosure. As utilized herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

In the present disclosure, it will be understood that the terms “comprise(s)/comprising,” “include(s)/including,” “have(has)/having” and/or the like specify the presence of features, numbers, steps, operations, component, parts, and/or combination thereof disclosed in the disclosure, but do not exclude the possibility of presence or addition of one or more other features, numbers, steps, operations, component, parts, and/or combination thereof. As used herein, the terms “and,” “or,” and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the present disclosure, if (e.g., when) a layer, a film, a region, or a plate is referred to as being “on” or “in an upper portion of” another layer, film, region, or plate, it may be not only “directly on” the layer, film, region, or plate, but intervening layers, films, regions, or plates may also be present. Opposite this, if (e.g., when) a layer, a film, a region, or a plate is referred to as being “below” or “in a lower portion of” another layer, film, region, or plate, it may be not only directly under the layer, film, region, or plate, but intervening layers, films, regions, or plates may also be present. In addition, it will be understood that if (e.g., when) a part is referred to as being “on” another part, it may be arranged above the other part, or arranged under the other part as well. In the present disclosure, “directly on” may refer to that there are no additional layers, films, regions, plates, and/or the like, between a layer, a film, a region, a plate, and/or the like and the other part. For example, “directly on” may refer to two layers or two members are disposed without utilizing an additional member such as an adhesive member therebetween.

In the present disclosure, the term “substituted or unsubstituted” may refer to substituted or unsubstituted with at least one substituent selected from among the group consisting of deuterium, a halogen, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may each be monocyclic or polycyclic. In one or more embodiments, the rings formed by adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In one or more embodiments, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be linear or branched. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but embodiments of the disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched.

The number of carbon atoms in the alkenyl group is not specifically limited, for example, may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, and/or the like, but embodiments of the disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms in the alkynyl group is not specifically limited, it may be 2 to 30, 2 to 20, or 2 to 10. Examples of the alkynyl group may include an ethynyl group, a propynyl group, and/or the like, but embodiments of the present disclosure are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the disclosure are not limited thereto.

In the present disclosure, a fluorenyl group may be substituted, and two substituents may be bonded to each other to form a spiro structure. Examples of the substituted fluorenyl group are as follows. However, embodiments of the disclosure are not limited thereto.

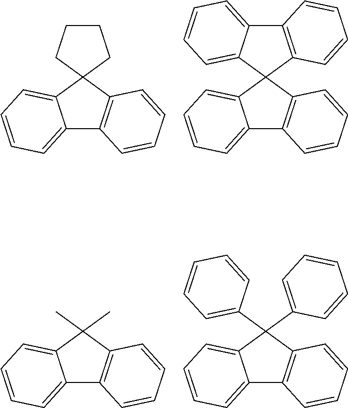

A heterocyclic group as utilized herein refers to any functional group or substituent derived from a ring containing at least one of B, O, N, P, Si, or Se as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, a heterocyclic group may contain at least one of B, O, N, P, Si, or S as a heteroatom. If the heterocyclic group contains two or more heteroatoms, the two or more heteroatoms may be the same as or different from each other. The heterocyclic group may be a monocyclic heterocyclic group or a polycyclic heterocyclic group, and may include a heteroaryl group. The number of ring-forming carbon atoms in the heterocyclic group may be 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the disclosure are not limited thereto.

In the present disclosure, a heteroaryl group may contain at least one of B, O, N, P, Si, or S as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the disclosure are not limited thereto.

In the present disclosure, the number of carbon atoms in a carbonyl group is not specifically limited, for example, may be 1 to 40, 1 to 30, or 1 to 20. For example, the carbonyl group may have the following structures, but embodiments of the disclosure are not limited thereto.

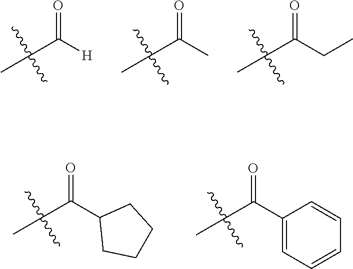

In the present disclosure, the number of carbon atoms in a sulfinyl group and/or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the disclosure are not limited thereto.

A boron group as utilized herein may refer to that a boron atom is bonded to the alkyl group or the aryl group defined above. The boron group includes an alkyl boron group and/or an aryl boron group. Examples of the boron group may include a dimethylboron group, a trimethylboron group, a t-butyldimethylboron group, a diphenylboron group, a phenylboron group, and/or the like, but embodiments of the disclosure are not limited thereto.

In the present disclosure, an alkenyl group may be linear or branched. The number of carbon atoms in the alkenyl group is not specifically limited, for example, may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but embodiments of the disclosure are not limited thereto.

In the present disclosure, the number of carbon atoms in an amine group is not specifically limited, for example, may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, a triphenylamine group, and/or the like, but embodiments of the disclosure are not limited thereto.

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, an arylamine group may be the same as the examples of the aryl group described above.

In the present disclosure, a direct linkage may refer to a single bond.

In the present disclosure,

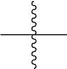

and “ [symbol] ” refer to a position to be connected.

Hereinafter, embodiments of the present disclosure will be described in more detail with reference to the accompanying drawings.

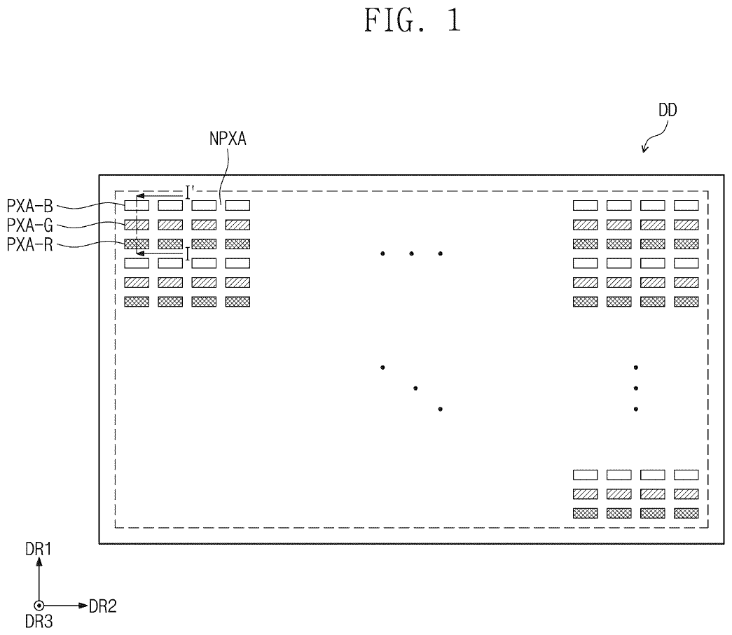

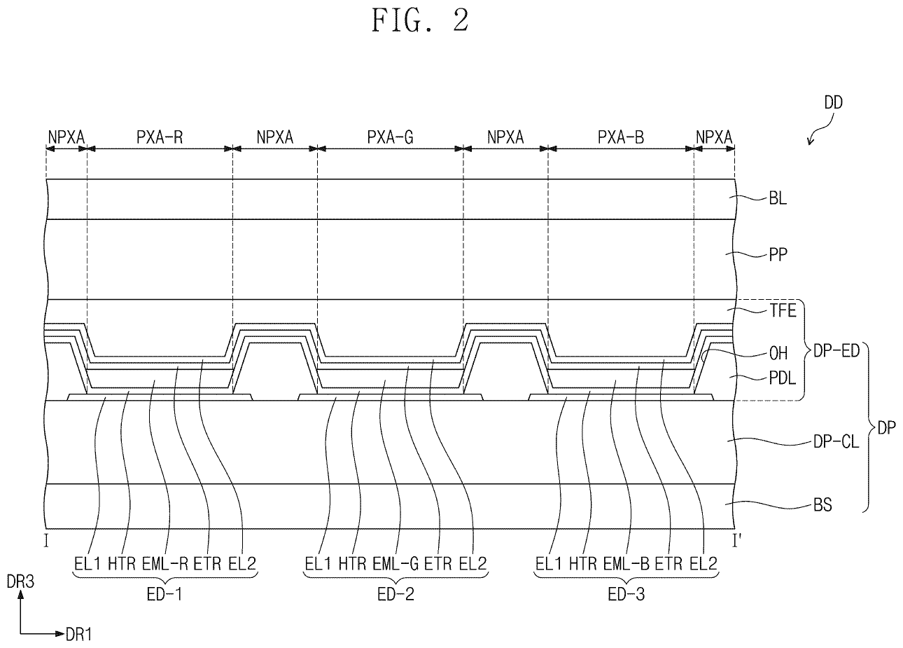

FIG. 1 is a plan view illustrating a display device DD according to one or more embodiments of the present disclosure. FIG. 2 is a cross-sectional view of the display device DD according to one or more embodiments. FIG. 2 is a cross-sectional view illustrating a part taken along the line I-I′ of FIG. 1.

The display device DD may include a display panel DP and an optical layer PP arranged on the display panel DP. The display panel DP may include light-emitting elements ED-1, ED-2, and ED-3. The display device DD may include a plurality of light-emitting elements ED-1, ED-2, and ED-3. The optical layer PP may be arranged on the display panel DP to control reflected light in the display panel DP due to external light. The optical layer PP may include, for example, a polarization layer and/or a color filter layer. In one or more embodiments, the optical layer PP may not be provided in the display device DD.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, embodiments of the disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and a display device layer DP-ED. The display device layer DP-ED may include a pixel defining film PDL, the light-emitting elements ED-1, ED-2, and ED-3 arranged between respective portions of the pixel defining film PDL, and an encapsulation layer TFE arranged on the light-emitting elements ED-1, ED-2, and ED-3.

The base layer BS may be a member which provides a base surface on which the display device layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors. Each of the transistors may include a control electrode, an input electrode, and an output electrode. For example, in some embodiments, the circuit layer DP-CL may include switching transistor(s) and driving transistor(s) for driving the light-emitting elements ED-1, ED-2, and ED-3 of the display device layer DP-ED.

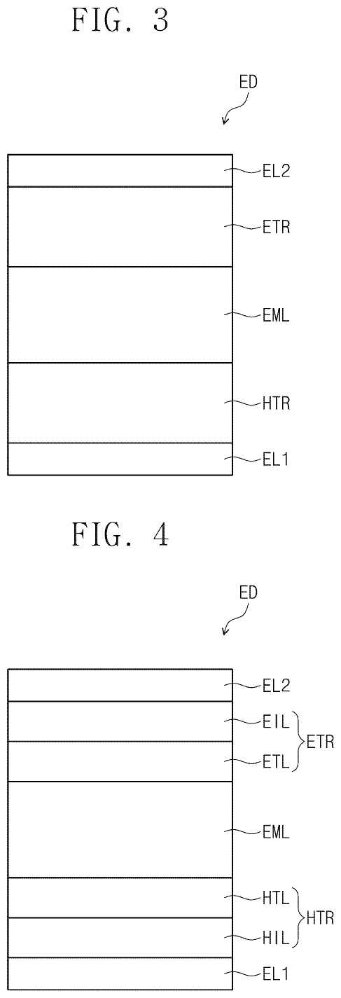

Each of the light-emitting elements ED-1, ED-2, and ED-3 may have a structure of one of light-emitting elements ED of embodiments according to FIGS. 3 to 7, which will be described in more detail later. Each of light-emitting elements ED-1, ED-2, and ED-3 may include a first electrode EL1, a hole transport region HTR, respective emission layers EML-R, EML-G, and EML-B, an electron transport region ETR, and a second electrode EL2.

FIG. 2 illustrates an embodiment in which the respective emission layers EML-R, EML-G, and EML-B of the light-emitting elements ED-1, ED-2, and ED-3 are arranged in openings OH defined in the pixel defining film PDL, and the hole transport region HTR, the electron transport region ETR, and the second electrode EL2 are provided as a common layer in the entire light-emitting elements ED-1, ED-2, and ED-3. However, embodiments of the disclosure are not limited thereto, for example, the hole transport region HTR and the electron transport region ETR in one or more embodiments may be provided by being patterned inside the openings OH defined in the pixel defining film PDL. For example, the hole transport region HTR, the respective emission layers EML-R, EML-G, and EML-B, and the electron transport region ETR of the light-emitting elements ED-1, ED-2, and ED-3 in one or more embodiments may be provided by being patterned in an inkjet printing method.

The encapsulation layer TFE may cover the light-emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE may include at least one insulation layer. In some embodiments, the encapsulation layer TFE may include at least one inorganic film (hereinafter, an encapsulation-inorganic film). In some embodiments, the encapsulation layer TFE may include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the disclosure are not particularly limited thereto. In one or more embodiments, the encapsulation-organic film may include an acrylic-based compound, an epoxy-based compound, and/or the like. In some embodiments, the encapsulation-organic film may include a photopolymerizable organic material, but embodiments of the disclosure are not particularly limited thereto.

The encapsulation layer TFE may be arranged on the second electrode EL2 and may be arranged filling the opening OH.

Referring to FIG. 1 and FIG. 2, the display device DD may include a non-light emitting region NPXA and light emitting regions PXA-R, PXA-G, and PXA-B. The light emitting regions PXA-R, PXA-G, and PXA-B may be regions in which light generated by the respective light-emitting elements ED-1, ED-2, and ED-3 is emitted. The light emitting regions PXA-R, PXA-G, and PXA-B may be spaced and/or apart (e.g., spaced apart or separated) from each other on a plane.

Each of the light emitting regions PXA-R, PXA-G, and PXA-B may be a region divided by the pixel defining film PDL. The non-light emitting areas NPXA may be areas between adjacent light emitting areas PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light-emitting elements ED-1, ED-2, and ED-3. The respective emission layers EML-R, EML-G, and EML-B of the light-emitting elements ED-1, ED-2, and ED-3 may be arranged in openings OH defined in the pixel defining film PDL and separated from each other.

The light emitting regions PXA-R, PXA-G, and PXA-B may be divided into a plurality of groups according to the color of light generated from the light-emitting elements ED-1, ED-2, and ED-3. In the display device DD of one or more embodiments illustrated in FIG. 1 and FIG. 2, three light emitting regions PXA-R, PXA-G, and PXA-B, which emit red light, green light, and blue light, respectively, are exemplarily illustrated. For example, in one or more embodiments, the display device DD may include a red light emitting region PXA-R, a green light emitting region PXA-G, a blue light emitting region PXA-B that are separated from each other.

In the display device DD according to one or more embodiments, the plurality of light-emitting elements ED-1, ED-2 and ED-3 may be to emit light beams having wavelengths different from each other. For example, in one or more embodiments, the display device DD may include a first light-emitting element ED-1 that emits red light, a second light-emitting element ED-2 that emits green light, and a third light-emitting element ED-3 that emits blue light. For example, in one or more embodiments, the red light emitting region PXA-R, the green light emitting region PXA-G, and the blue light emitting region PXA-B of the display device DD may correspond to the light-emitting element ED-1, the second light-emitting element ED-2, and the third light-emitting element ED-3, respectively.

However, embodiments of the disclosure are not limited thereto, and the first to third light-emitting elements ED-1, ED-2, and ED-3 may be to emit light beams in substantially the same wavelength range or at least one light-emitting element may be to emit a light beam in a wavelength range different from the others. For example, in some embodiments, the first to third light-emitting elements ED-1, ED-2, and ED-3 may all emit blue light.

The light emitting regions PXA-R, PXA-G, and PXA-B in the display device DD according to one or more embodiments may be arranged in a stripe form.

Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In one or more embodiments, the red light emitting region PXA-R, the green light emitting region PXA-G, and the blue light emitting region PXA-B may be alternately arranged in the stated order along a first direction axis DR1.

FIG. 1 and FIG. 2 illustrate that all the light emitting regions PXA-R, PXA-G, and PXA-B have similar area, but embodiments of the disclosure are not limited thereto. Thus, the light emitting regions PXA-R, PXA-G, and PXA-B may have different areas from each other according to the wavelength range of the emitted light. The areas of the light emitting regions PXA-R, PXA-G, and PXA-B may refer to areas if (e.g., when) viewed on a plane defined by the first direction axis DR1 and the second direction axis DR2 (e.g., the areas in a plan view).

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, in one or more embodiments, the arrangement form of the light emitting regions PXA-R, PXA-G, and PXA-B may be a pentile (PENTILE®) arrangement form (for example, an RGBG matrix, an RGBG structure, or an RGBG matrix structure), or a diamond (Diamond Pixel™) arrangement form (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In one or more embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but embodiments of the disclosure are not limited thereto.

Hereinafter, FIG. 3 to FIG. 7 are each a cross-sectional view schematically showing a light-emitting element ED according to one or more embodiments. Each of the light-emitting element ED of one or more embodiments may include a first electrode EL1, a hole transport region HTR, an emission layer EML, an electron transport region ETR, and a second electrode EL2 stacked in order.

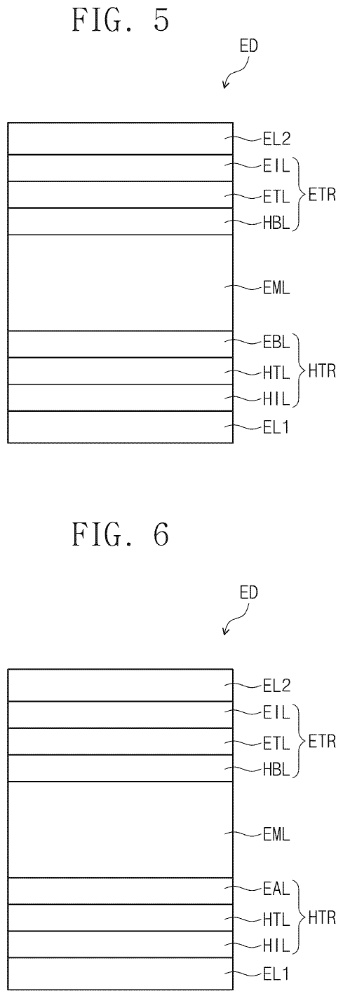

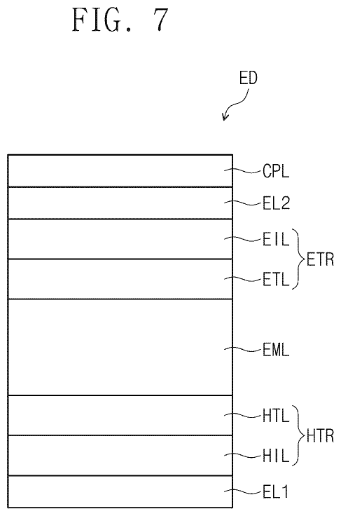

Compared with FIG. 3, FIG. 4 illustrates a cross-sectional view of a light-emitting element ED of one or more embodiments, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light-emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 3, FIG. 6 illustrates a cross-sectional view of a light-emitting element ED of one or more embodiments, in which a hole transport region HTR includes a hole injection layer HIL, a hole transport layer HTL, and an emission auxiliary layer EAL, and an electron transport region ETR includes an electron injection layer EIL, an electron transport layer ETL, and a hole blocking layer HBL. Compared with FIG. 4, FIG. 7 illustrates a cross-sectional view of a light-emitting element ED of one or more embodiments further including a capping layer CPL arranged on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, embodiments of the disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom (thereof), a mixture of two or more selected therefrom, or an oxide thereof.

If the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In one or more embodiments, the first electrode EL1 may have a multilayer structure including a reflective film or a transflective film formed of one or more of the above-described materials, and a transparent conductive film formed of ITO, IZO, ZnO, ITZO, and/or the like. For example, in some embodiments, the first electrode EL1 may have a three-layer structure of ITO/Ag/ITO, but embodiments of the disclosure are not limited thereto. In addition, one or more embodiments of the disclosure is not limited thereto, and the first electrode EL1 may include one of the above-described metal materials, combinations of at least two metal materials of the above-described metal materials, oxides of the above-described metal materials, and/or the like. A thickness of the first electrode EL1 may be from about 700 angstroms (Å) to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one selected from among a hole injection layer HIL, a hole transport layer HTL, an emission auxiliary layer EAL, and an electron blocking layer EBL. A thickness of the hole transport region HTR may be, for example, from about 50 Å to about 15,000 Å. The emission auxiliary layer EAL may be referred to as a buffer layer.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/emission auxiliary layer EAL, a hole injection layer HIL/emission auxiliary layer EAL, a hole transport layer HTL/emission auxiliary layer EAL, or a hole injection layer HIL/hole transport layer HTL/electron blocking layer EBL are stacked in order (e.g., in the stated order) from the first electrode EL1, but embodiments of the disclosure are not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

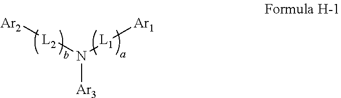

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, a plurality of L₁'s and L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ includes an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented in Compound Group H:

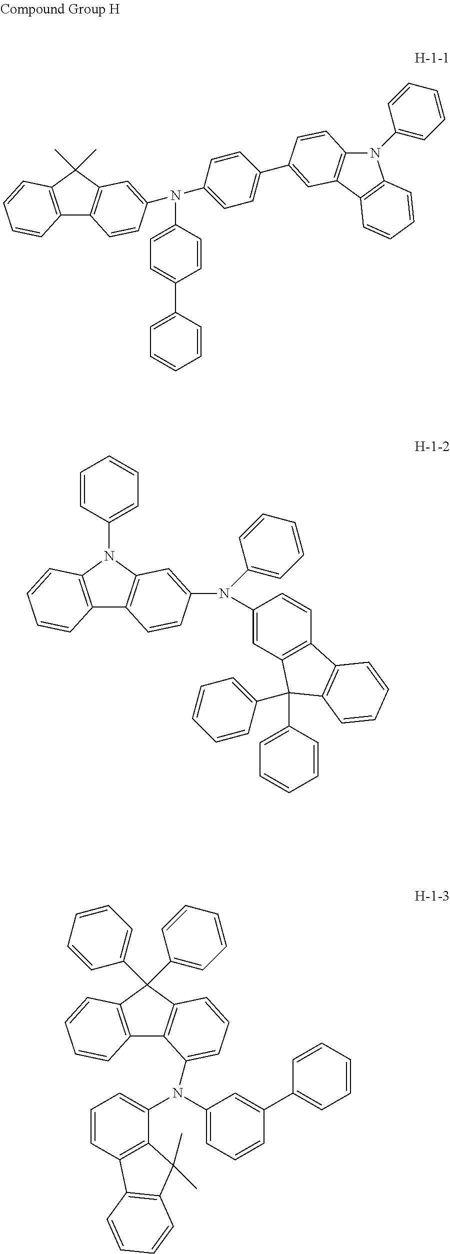 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

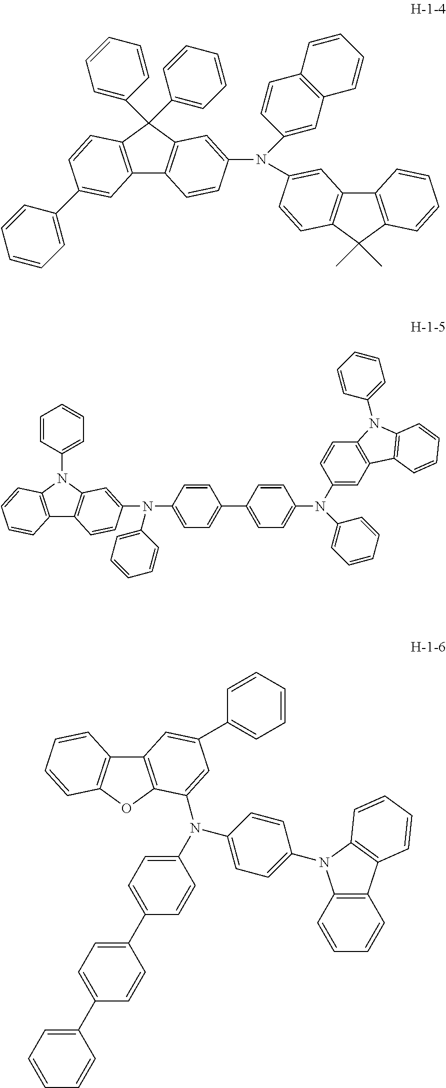 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

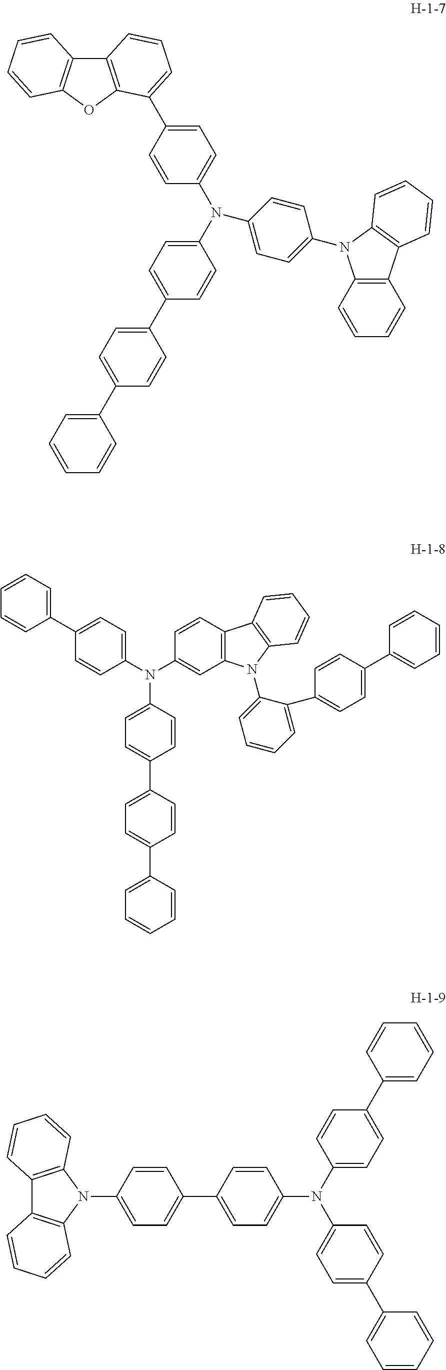 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

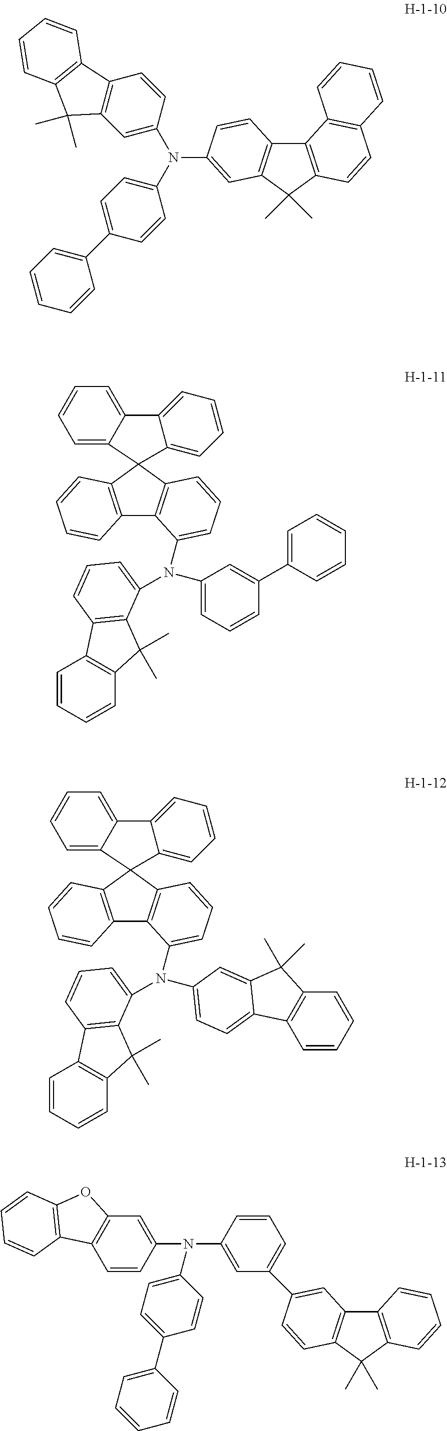 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

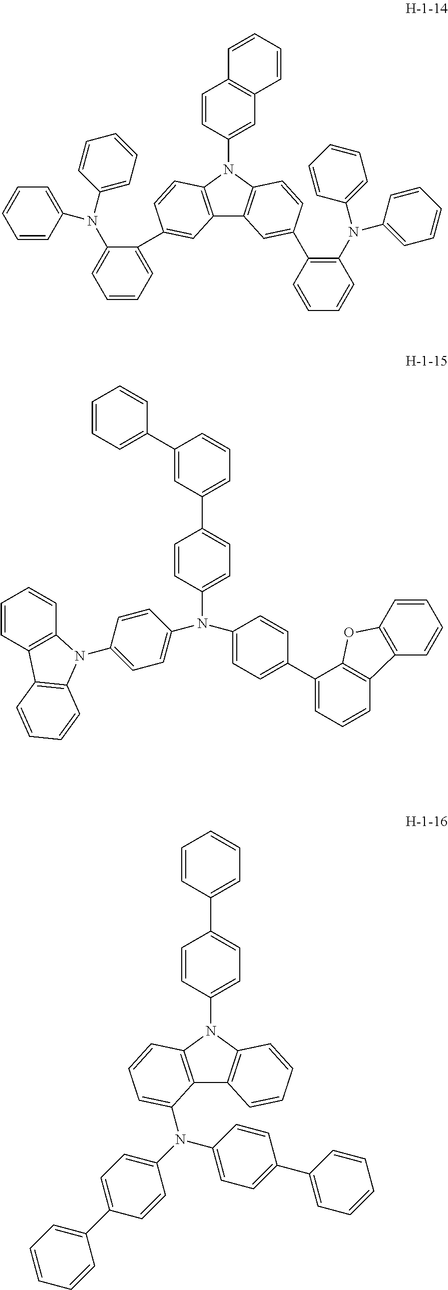 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

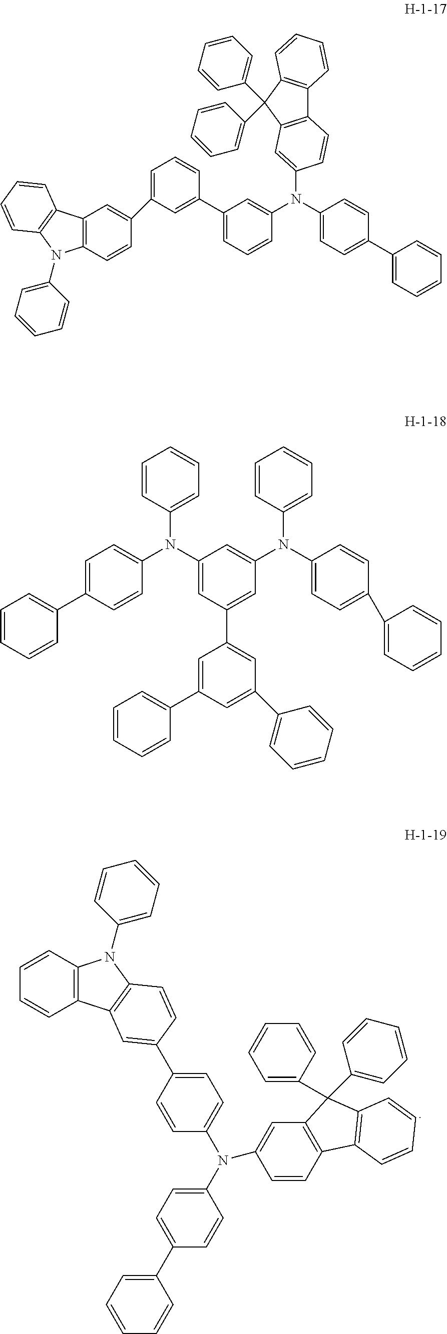 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include at least one selected from among a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), and/or the like.

In one or more embodiments, the hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include at least one selected from 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

A thickness of the hole transport region HTR may be from about 100 Å to about 10,000 Å, for example, from about 100 Å to about 5,000 Å. When the hole transport region HTR includes a hole injection layer HIL, the hole injection layer HIL may have, for example, a thickness of about 30 Å to about 1,000 Å. When the hole transport region HTR includes a hole transport layer HTL, the hole transport layer HTL may have a thickness of about 250 Å to about 1,000 Å. For example, if (e.g., when) the hole transport region HTR includes an electron blocking layer EBL, the electron blocking layer EBL may have a thickness of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

In one or more embodiments, the hole transport region HTR may further include a charge generating material to increase electrical conductivity in addition to one or more of the above-described materials. The charge generating material may be dispersed uniformly (e.g., substantially uniformly) or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the disclosure are not limited thereto. For example, in one or more embodiments, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the disclosure are not limited thereto.

The hole transport region HTR may include one or more of the above-described compounds of the hole transport region in at least one of a hole injection layer HIL, a hole transport layer HTL, an emission auxiliary layer EAL, or an electron blocking layer EBL.

The emission auxiliary layer EAL may compensate for a resonance distance according to a wavelength of light emitted in the emission layer EML, and may adjust a hole charge balance, thereby increasing light emission efficiency. In addition, the emission auxiliary layer EAL may serve to prevent or reduce electrons from being injected into the hole transport region HTR. In the emission auxiliary layer EAL, a material capable of being included in the hole transport region HTR may be included. The electron blocking layer EBL may be a layer that serves to prevent or reduce the electron injection from the electron transport region ETR to the hole transport region HTR.

In the light-emitting element ED according to one or more embodiments, the emission layer EML may include, as a host material, a first compound which is a heterocyclic compound according to one or more embodiments of the present disclosure. In the light-emitting element ED according to one or more embodiments, the emission layer EML may further include a second compound as a host material in addition to the first compound which is the heterocyclic compound according to one or more embodiments. The light-emitting element ED according to one or more embodiments may include the first compound, which is the heterocyclic compound according to one or more embodiments, as a hole-transporting host material, and include the second compound as an electron-transporting host material. In one or more embodiments, in the light-emitting element ED, the emission layer EML may include the first compound and the second compound, and may further include a third compound which is a thermally activated delayed fluorescent dopant, and a fourth compound. In one or more embodiments, the second compound may include a hexagonal ring group (e.g., a 6-membered ring) that contains at least one nitrogen atom as a ring-forming atom. The third compound may include a pentagonal fused ring (e.g., a 5-membered ring) that contains a nitrogen atom or an oxygen atom as a ring-forming atom. The fourth compound may be an organic metal compound that contains Pt as a core metal atom. The second to fourth compounds will be described in more detail, later.

As utilized herein, the first compound may be referred to as a heterocyclic compound according to one or more embodiments of the present disclosure. The heterocyclic compound according to one or more embodiments may have a dibenzoheterole skeletal structure containing a silicon (Si) atom as a ring-forming atom. In the heterocyclic compound according to one or more embodiments, two hydrogen atoms bonded to the silicon atom may be each substituted with a substituted or unsubstituted phenyl group. For example, the heterocyclic compound according to one or more embodiments may contain a silicon (Si) atom as a ring-forming atom, and may be a dibenzosilole derivative in which two substituted or unsubstituted phenyl groups are bonded to the silicon (Si) atom, which is a ring-forming atom.

The heterocyclic compound according to one or more embodiments may include dibenzosilole as a basic skeletal structure, and thus may achieve low driving voltage characteristics and an emission color of deep blue. In addition, the heterocyclic compound according to one or more embodiments may exhibit excellent or suitable emission efficiency and long lifespan characteristics in a deep blue emission wavelength range.

The heterocyclic compound according to one or more embodiments may be represented by Formula 1.

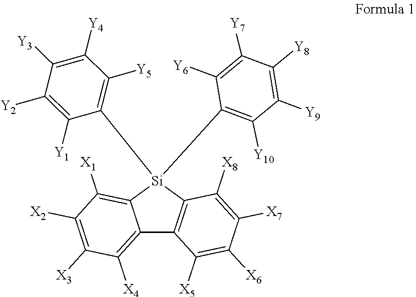

In Formula 1, X₁ to X₈ and Y₁ to Y₁₀ may each independently be hydrogen, deuterium, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 5 to 30 ring-forming carbon atoms.

In one or more embodiments, X₁ to X₈ may each independently be hydrogen, deuterium, or a substituted or unsubstituted heteroaryl group having 5 to 30 ring-forming carbon atoms. For example, in one or more embodiments, X₁ to X₈ may each independently be hydrogen, deuterium, a substituted or unsubstituted carbazole group, a substituted or unsubstituted dibenzofuran group, a substituted or unsubstituted dibenzothiophene group, a substituted or unsubstituted indolocarbazole group, or may be represented by

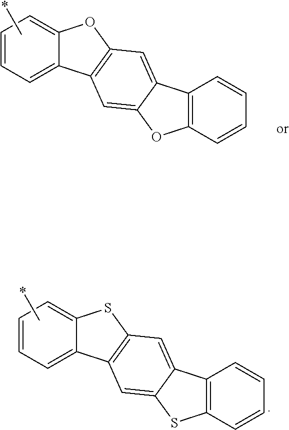

In one or more embodiments, Y₁ to Y₁₀ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 5 to 30 ring-forming carbon atoms. For example, in one or more embodiments, Y₁ to Y₁₀ may each independently be hydrogen, deuterium, a substituted or unsubstituted methyl group, a substituted or unsubstituted phenyl group, or a substituted or unsubstituted carbazole group. For example, in one or more embodiments, Y₁, Y₂, Y₄, Y₅, Y₆ and Y₇ may each independently be hydrogen or deuterium. Y₃ and Y₈ may each independently be hydrogen, deuterium, a substituted or unsubstituted methyl group, a substituted or unsubstituted phenyl group, or a substituted or unsubstituted carbazole group. However, embodiments of the disclosure are not limited thereto.

For example, in the heterocyclic compound according to one or more embodiments, represented by Formula 1, at least one selected from among X₁ to X₈ and Y₁ to Y₁₀ may be represented by Formula 1a or Formula 1b. The rest, which is not represented by Formula 1a or Formula 1b, among X₁ to X₈ and Y₁ to Y₁₀, may each independently be hydrogen, deuterium, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 5 to 30 ring-forming carbon atoms.

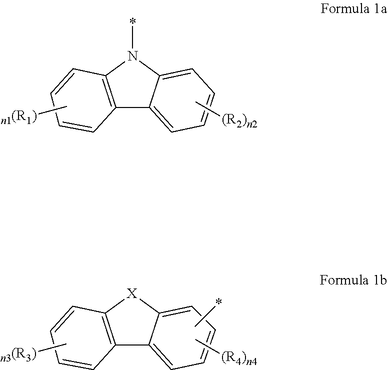

In Formula 1a and Formula 1b, R₁ to R₄ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring.

For example, in one or more embodiments, R₁ and R₂ may each independently be hydrogen, deuterium, a substituted or unsubstituted methyl group, a substituted or unsubstituted t-butyl group, or a substituted or unsubstituted carbazole group. When R₁ and R₂ are each independently bonded to an adjacent group to form a ring, the formed ring may be a hetero ring. For example, the ring formed by bonding with an adjacent group may be a heteroaryl ring.

For example, in one or more embodiments, in Formula 1b, R₃ and R₄ may each independently be hydrogen, deuterium, or a substituted or unsubstituted phenyl group. When R₃ and R₄ are independently bonded with an adjacent group to form a ring, the formed ring may be a hetero ring. For example, the ring formed by bonding with an adjacent group may be a heteroaryl ring.

In Formula 1a and Formula 1b, n1 to n3 may each independently be an integer of 0 to 4, and n4 may be an integer of 0 to 3. In Formula 1a and Formula 1b, if n1, n2, n3, and n4 are each 0, the heterocyclic compound according to one or more embodiments may be unsubstituted with R₁, R₂, R₃, and R₄, respectively. embodiments in which n1, n2, and n3 are each 4, and R₁, R₂, and R₃, the numbers of which are each 4, are each hydrogen in Formula 1a and Formula 1b, may be the same as the embodiments in which n1, n2, and n3 are each 0 in Formula 1a and Formula 1b. If n1, n2, and n3 are each an integer of 2 or greater, R₁, R₂, and R₃, each provided in plurality, may be all the same, or at least one selected from among the plurality of R₁(s), R₂(s), and R₃(s) may be different.

An embodiment in which n4 is 3 and three R₄(s) are all hydrogen in Formula 1b may be the same as the embodiment in which n4 is 0 in Formula 1b. If n4 is an integer of 2 or greater, R₄(s) provided in plurality may be all the same, or at least one selected from among the plurality of R₄(s) may be different.

For example, in the heterocyclic compound according to one or more embodiments, represented by Formula 1, at least one selected from among X₁ to X₈ may be represented by Formula 1a or Formula 1b. The rest that are not represented by Formula 1a or Formula 1b among X₁ to X₈, and Y₁ to Y₁₀ may each independently be hydrogen, deuterium, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 5 to 30 ring-forming carbon atoms. For example, in one or more embodiments, the rest that are not represented by Formula 1a or Formula 1b among X₁ to X₈, and Y₁ to Y₁₀ may each independently be represented by hydrogen, deuterium, a substituted or unsubstituted methyl group, a substituted or unsubstituted phenyl group, or a substituted or unsubstituted carbazole group. However, embodiments of the disclosure are not limited thereto.

For example, in the heterocyclic compound according to one or more embodiments, represented by Formula 1, at least one selected from among X₃ and X₆ may be a substituted or unsubstituted heteroaryl group having 5 to 30 ring-forming carbon atoms. For example, in one or more embodiments, at least one selected from among X₃ and X₆ may be represented by Formula 1a or Formula 1b above. In this case, the heterocyclic compound according to one or more embodiments may have improved material stability, and thus excellent or suitable emission efficiency and long lifespan characteristics may be achieved.

The heterocyclic compound according to one or more embodiments, represented by Formula 1, may be represented by Formula 2 or Formula 3.

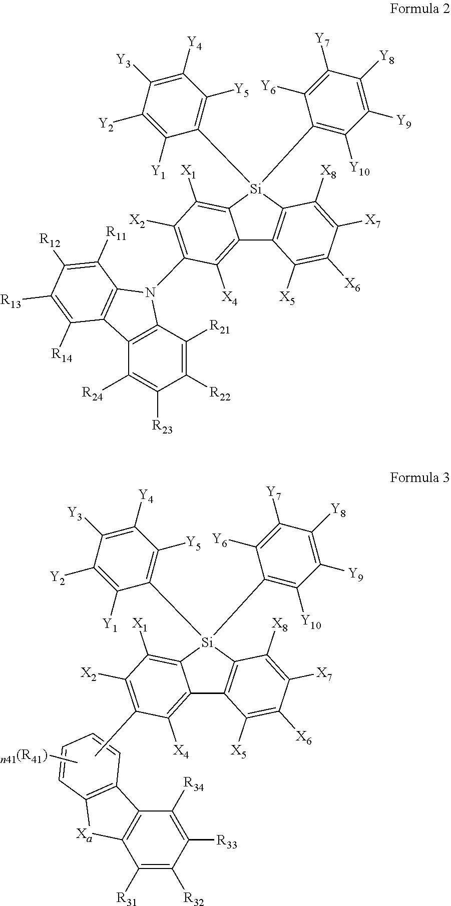

In Formula 2 and Formula 3, the same descriptions as in Formula 1 may be applied to X₁, X₂, X₄ to X₈, and Y₁ to Y₁₀.

In Formula 2 and Formula 3, R₁₁ to R₁₄, R₂₁ to R₂₄, and R₃₁ to R₃₄ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring.

For example, in the heterocyclic compound according to one or more embodiments, represented by Formula 2, R₁₁ to R₁₄, and R₂₁ to R₂₄ may each independently be hydrogen, deuterium, a substituted or unsubstituted methyl group, a substituted or unsubstituted t-butyl group, or a substituted or unsubstituted carbazole group. When R₁₁ to R₁₄ and R₂₁ to R₂₄ are each independently bonded with an adjacent group to form a ring, R₁₁ and R₁₂, R₁₂ and R₁₃, R₁₃ and R₁₄, R₂₁ and R₂₂, R₂₂ and R₂₃, and/or R₂₃ and R₂₄ may be bonded to form a ring, and the formed ring may be a hetero ring. For example, the ring formed by bonding with an adjacent group may be a heteroaryl ring.

For example, in the heterocyclic compound according to one or more embodiments, represented by Formula 3, R₃₁ to R₃₄ may each independently be hydrogen, deuterium, or a substituted or unsubstituted phenyl group. When R₃₁ to R₃₄ are each independently bonded with an adjacent group to form a ring, R₃₁ and R₃₂, R₃₂ and R₃₃, and/or R₃₃ and R₃₄ may be bonded to form a ring, and the formed ring may be a hetero ring. For example, the ring formed by bonding with an adjacent group may be a heteroaryl ring.

In Formula 3, R₄₁ may be hydrogen or deuterium. In addition, n41 may be an integer of 0 to 3. In Formula 3, if n41 is 0, the heterocyclic compound represented by Formula 3 may be unsubstituted with R₄₁. An embodiment in which n41 is 3, and three R₄₁ are each hydrogen in Formula 3, may be the same as the embodiment in which n41 is 0 in Formula 3. If n41 is an integer of 2 or greater, R₄₁(s) provided in plurality may be all the same, or at least one selected from among the plurality of R₄₁(s) may be different.

In Formula 3, Xₐ may be O or S. If Xₐ is O, the heterocyclic compound represented by Formula 3, according to one or more embodiments, may include a substituted or unsubstituted dibenzofuran group or a derivative of the substituted or unsubstituted dibenzofuran. If Xₐ is S, the heterocyclic compound represented by Formula 3, according to one or more embodiments, may include a substituted or unsubstituted dibenzothiophene group or a derivative of the substituted or unsubstituted dibenzothiophene.

The heterocyclic compound represented by Formula 2, according to one or more embodiments, may be represented by Formula 2-1 or Formula 2-2.

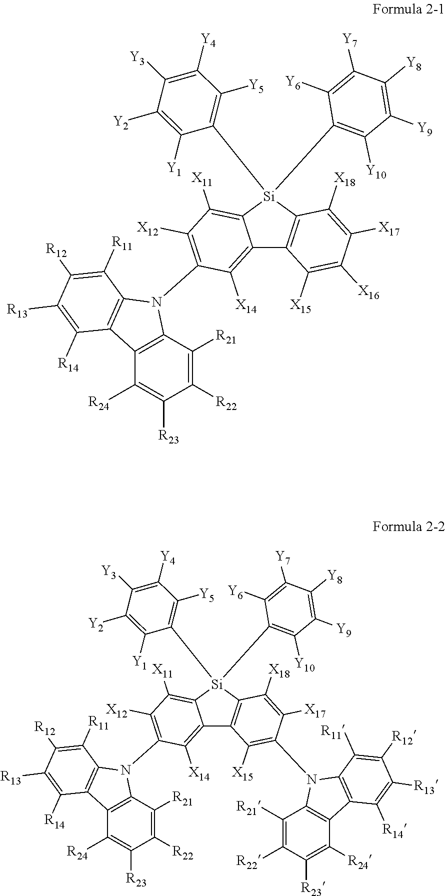

In Formula 2-1 and Formula 2-2, the same descriptions as in Formula 1 and Formula 2, described above, may be applied to Y₁ to Y₁₀, R₁₁ to R₁₄, and R₂₁ to R₂₄.

In Formula 2-1 and Formula 2-2, X₁₁, X₁₂, X₁₄, X₁₅, X₁₆, X₁₇, and X₁₈ may each independently be hydrogen or deuterium. For example, in one or more embodiments, X₁₁, X₁₂, X₁₄, X₁₅, X₁₆, X₁₇, and X₁₈ may each be hydrogen, but embodiments of the disclosure are not limited thereto.

In Formula 2-2, R₁₁′ to R₁₄′ and R₂₁′ to R₂₄′ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring.

For example, in the heterocyclic compound represented by Formula 2-2, according to one or more embodiments, R₁₁′ to R₁₄′ and R₂₁′ to R₂₄′ may each independently be hydrogen, deuterium, a substituted or unsubstituted methyl group, a substituted or unsubstituted t-butyl group, or a substituted or unsubstituted carbazole group. When R₁₁′ to R₁₄′ and R₂₁′ to R₂₄′ are independently bonded with an adjacent group to form a ring, R₁₁′ and R₁₂′, R₁₂′ and R₁₃′, R₁₃′ and R₁₄′, R₂₁′ and R₂₂′, R₂₂′ and R₂₃′, and/or R₂₃′ and R₂₄ are bonded to form a ring, and the formed ring may be a hetero ring. For example, the ring formed by bonding with an adjacent ring may be a heteroaryl ring.

The heterocyclic compound represented by Formula 3, according to one or more embodiments, may be represented by Formula 3-1 or Formula 3-2.

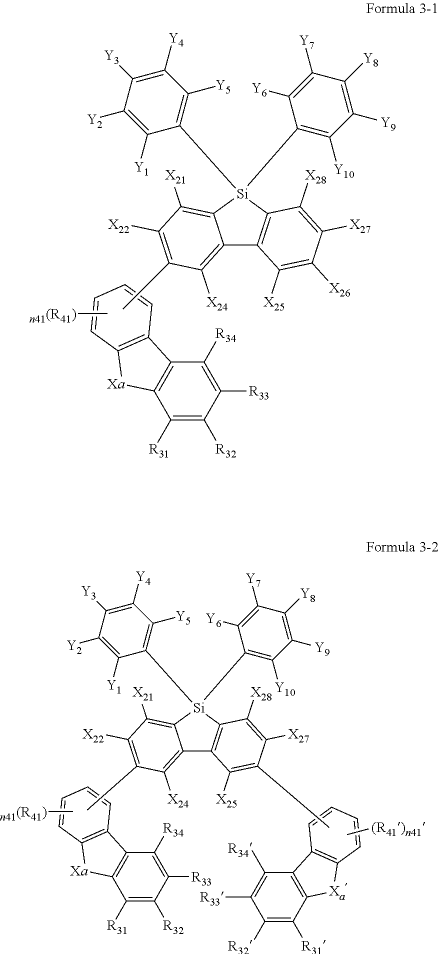

In Formula 3-1 and Formula 3-2, the same descriptions as in Formula 1 and Formula 3, described above, may be applied to Xₐ, Y₁ to Y₁₀, and R₃₁ to R₃₄, R₄₁, and n41.

In Formula 3-1 and Formula 3-2. X₂₁, X₂₂, X₂₄, X₂₅, X₂₆, X₂₇, and X₂₈ may each independently be hydrogen or deuterium. For example, in one or more embodiments, X₂₁, X₂₂, X₂₄, X₂₅, X₂₆, X₂₇, and X₂₈ may each be hydrogen, but embodiments of the disclosure are not limited thereto.

In Formula 3-2, R₃₁′ to R₃₄′ may each independently be hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded with an adjacent group to form a ring.

For example, in one or more embodiments, R₃₁′ to R₃₄′ may each independently be hydrogen, deuterium, or a substituted or unsubstituted phenyl group. When R₃₁′ to R₃₄′ are each independently bonded with an adjacent group to form a ring, R₃₁′ and R₃₂′, R₃₂′ and R₃₃′, and/or R₃₃′ and R₃₄′ may be bonded to form a ring, and the formed ring may be a hetero ring. For example, the ring formed by bonding with an adjacent group may be a heteroaryl ring.

In Formula 3-2, R₄₁′ may be hydrogen or deuterium. In addition, R₄₁′ may be an integer of 0 to 3. In Formula 3-2, if n41′ is 0, the heterocyclic compound represented by Formula 3-2 may be unsubstituted with R₄₁′. An embodiment in which n41′ is 3 and three R₄₁′(s) are each hydrogen in Formula 3-2, may be the same as the embodiment in which n41′ is 0 in Formula 3-2. If n41′ is an integer of 2 or greater, R₄₁′(s) provided in plurality may be all the same or at least one selected from among the plurality of R₄₁′(s) may be different.

In Formula 3-2, Xₐ′ may be O or S. If Xₐ′ is 0, the heterocyclic compound represented by Formula 3-2, according to one or more embodiments, may include a substituted or unsubstituted dibenzofuran group or a substituted or unsubstituted dibenzofuran derivative. If Xₐ′ is S, the heterocyclic compound represented by Formula 3-2, according to one or more embodiments, may include a substituted or unsubstituted dibenzothiophene group, or a substituted or unsubstituted dibenzothiophene derivative.

The heterocyclic compound according to one or more embodiments may be represented by any one selected from among compounds in Compound Group 1. The light-emitting element ED according to one or more embodiments may include at least one selected from among the compounds in Compound Group 1.

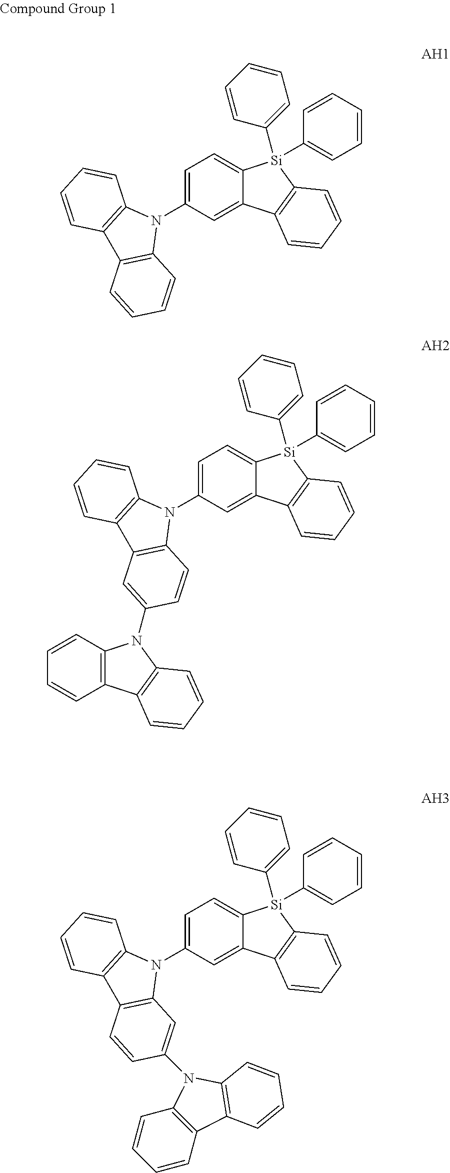 [SMILES: c1ccc([Si]2(c3ccccc3)c3ccccc3-c3cc(-n4c5ccccc5c5ccccc54)ccc32)cc1 ; c1ccc([Si]2(c3ccccc3)c3ccccc3-c3cc(-n4c5ccccc5c5cc(-n6c7ccccc7c7ccccc76)ccc54)ccc32)cc1 ; c1ccc([Si]2(c3ccccc3)c3ccccc3-c3cc(-n4c5ccccc5c5ccc(-n6c7ccccc7c7ccccc76)cc54)ccc32)cc1]

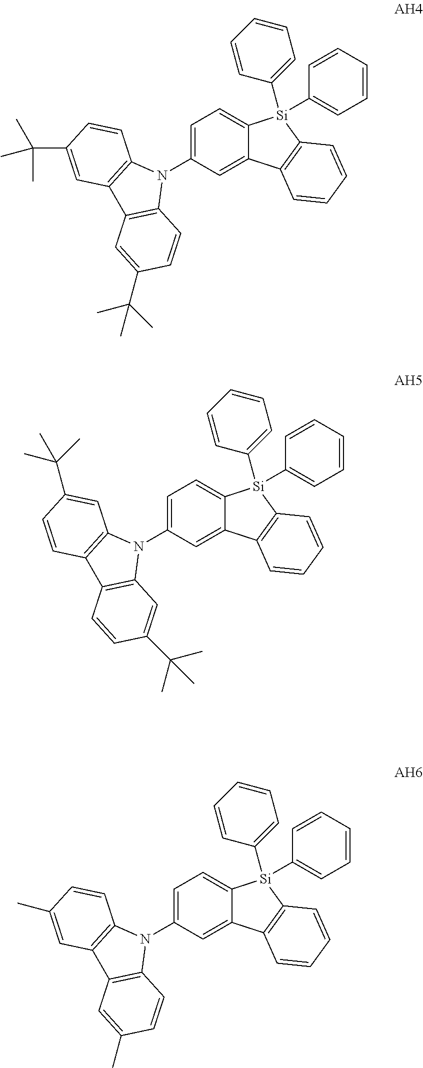 [SMILES: CC(C)(C)c1ccc2c(c1)c1cc(C(C)(C)C)ccc1n2-c1ccc2c(c1)-c1ccccc1[Si]2(c1ccccc1)c1ccccc1 ; CC(C)(C)c1ccc2c3ccc(C(C)(C)C)cc3n(-c3ccc4c(c3)-c3ccccc3[Si]4(c3ccccc3)c3ccccc3)c2c1 ; Cc1ccc2c(c1)c1cc(C)ccc1n2-c1ccc2c(c1)-c1ccccc1[Si]2(c1ccccc1)c1ccccc1]

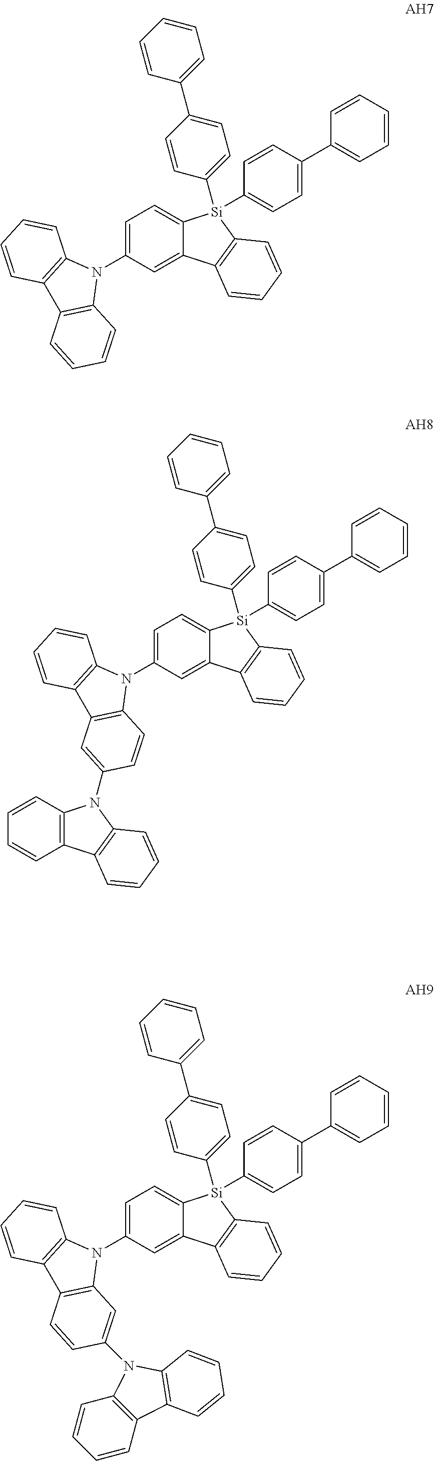 [SMILES: c1ccc(-c2ccc([Si]3(c4ccc(-c5ccccc5)cc4)c4ccccc4-c4cc(-n5c6ccccc6c6ccccc65)ccc43)cc2)cc1 ; c1ccc(-c2ccc([Si]3(c4ccc(-c5ccccc5)cc4)c4ccccc4-c4cc(-n5c6ccccc6c6cc(-n7c8ccccc8c8ccccc87)ccc65)ccc43)cc2)cc1 ; c1ccc(-c2ccc([Si]3(c4ccc(-c5ccccc5)cc4)c4ccccc4-c4cc(-n5c6ccccc6c6ccc(-n7c8ccccc8c8ccccc87)cc65)ccc43)cc2)cc1]

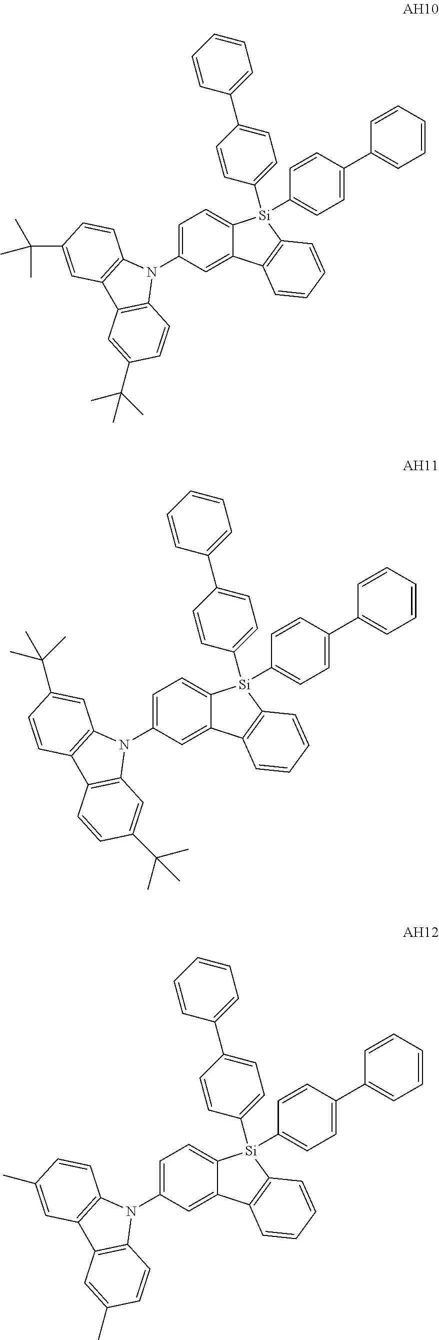 [SMILES: CC(C)(C)c1ccc2c(c1)c1cc(C(C)(C)C)ccc1n2-c1ccc2c(c1)-c1ccccc1[Si]2(c1ccc(-c2ccccc2)cc1)c1ccc(-c2ccccc2)cc1 ; CC(C)(C)c1ccc2c3ccc(C(C)(C)C)cc3n(-c3ccc4c(c3)-c3ccccc3[Si]4(c3ccc(-c4ccccc4)cc3)c3ccc(-c4ccccc4)cc3)c2c1 ; Cc1ccc2c(c1)c1cc(C)ccc1n2-c1ccc2c(c1)-c1ccccc1[Si]2(c1ccc(-c2ccccc2)cc1)c1ccc(-c2ccccc2)cc1]

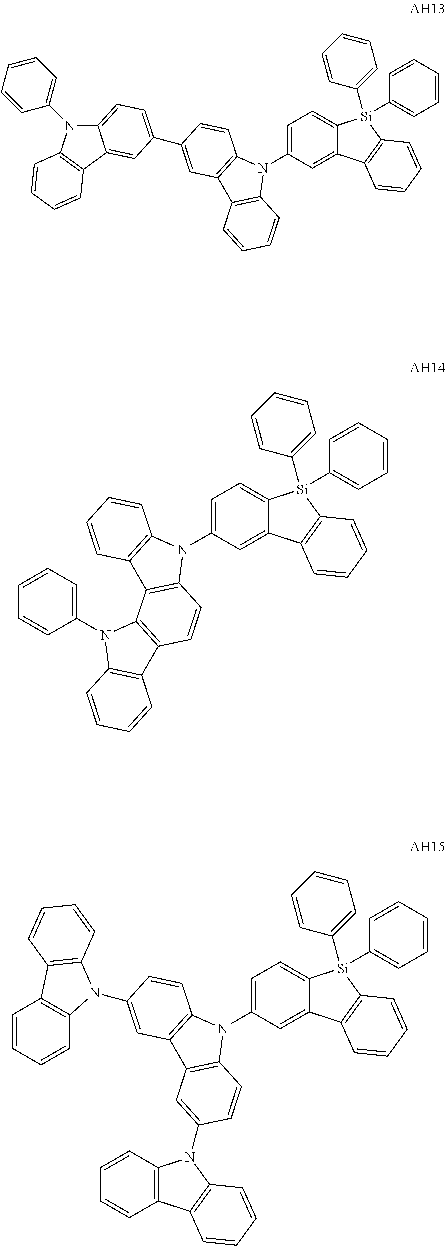 [SMILES: c1ccc(-n2c3ccccc3c3cc(-c4ccc5c(c4)c4ccccc4n5-c4ccc5c(c4)-c4ccccc4[Si]5(c4ccccc4)c4ccccc4)ccc32)cc1 ; c1ccc(-n2c3ccccc3c3ccc4c(c5ccccc5n4-c4ccc5c(c4)-c4ccccc4[Si]5(c4ccccc4)c4ccccc4)c32)cc1 ; c1ccc([Si]2(c3ccccc3)c3ccccc3-c3cc(-n4c5ccc(-n6c7ccccc7c7ccccc76)cc5c5cc(-n6c7ccccc7c7ccccc76)ccc54)ccc32)cc1]

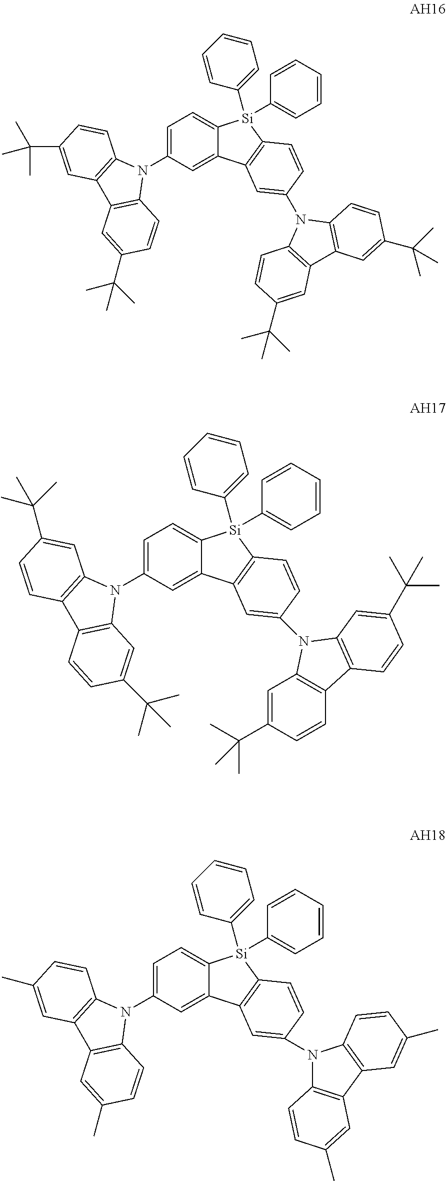

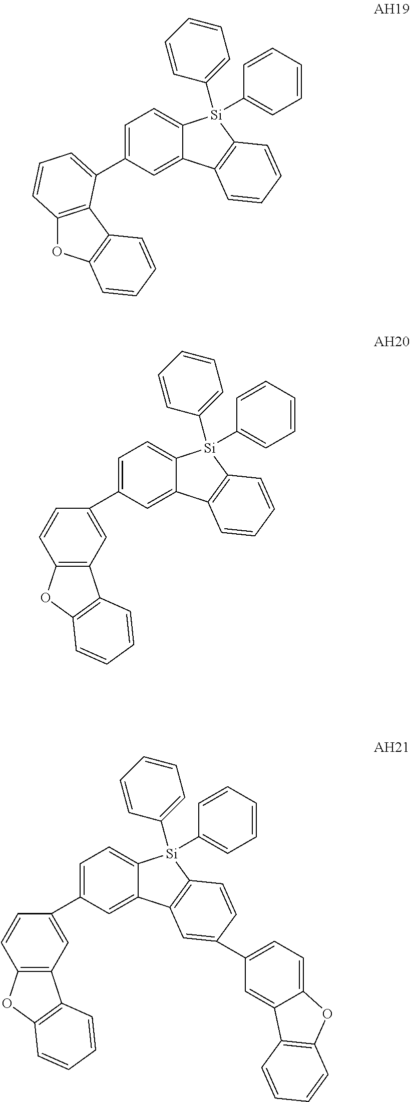 [SMILES: c1ccc([Si]2(c3ccccc3)c3ccccc3-c3cc(-c4cccc5oc6ccccc6c45)ccc32)cc1 ; c1ccc([Si]2(c3ccccc3)c3ccccc3-c3cc(-c4ccc5oc6ccccc6c5c4)ccc32)cc1 ; c1ccc([Si]2(c3ccccc3)c3ccc(-c4ccc5oc6ccccc6c5c4)cc3-c3cc(-c4ccc5oc6ccccc6c5c4)ccc32)cc1]

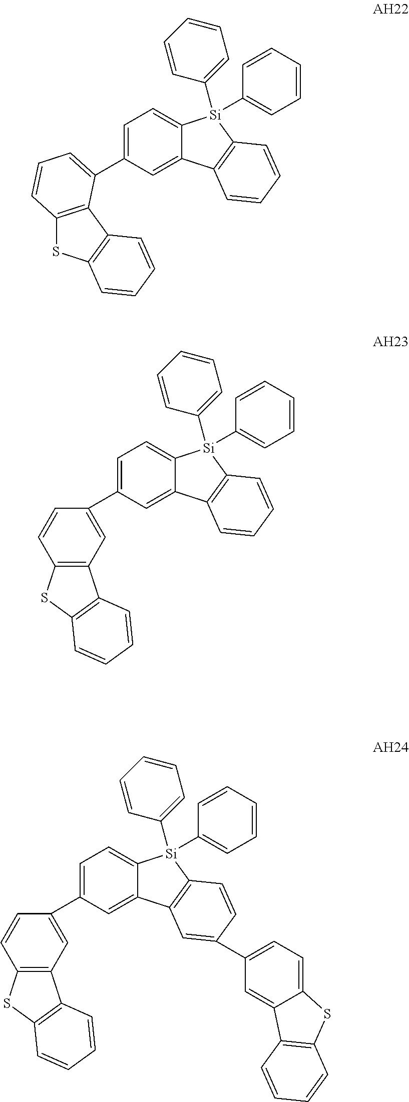 [SMILES: c1ccc([Si]2(c3ccccc3)c3ccccc3-c3cc(-c4cccc5sc6ccccc6c45)ccc32)cc1 ; c1ccc([Si]2(c3ccccc3)c3ccccc3-c3cc(-c4ccc5sc6ccccc6c5c4)ccc32)cc1 ; c1ccc([Si]2(c3ccccc3)c3ccc(-c4ccc5sc6ccccc6c5c4)cc3-c3cc(-c4ccc5sc6ccccc6c5c4)ccc32)cc1]

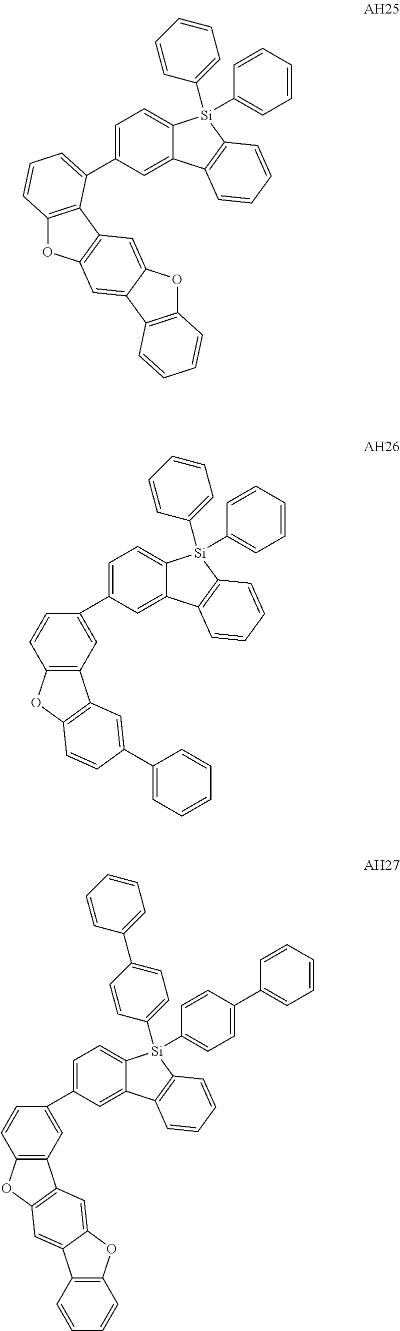 [SMILES: c1ccc([Si]2(c3ccccc3)c3ccccc3-c3cc(-c4cccc5oc6cc7c(cc6c45)oc4ccccc47)ccc32)cc1 ; c1ccc(-c2ccc3oc4ccc(-c5ccc6c(c5)-c5ccccc5[Si]6(c5ccccc5)c5ccccc5)cc4c3c2)cc1 ; c1ccc(-c2ccc([Si]3(c4ccc(-c5ccccc5)cc4)c4ccccc4-c4cc(-c5ccc6oc7cc8c(cc7c6c5)oc5ccccc58)ccc43)cc2)cc1]

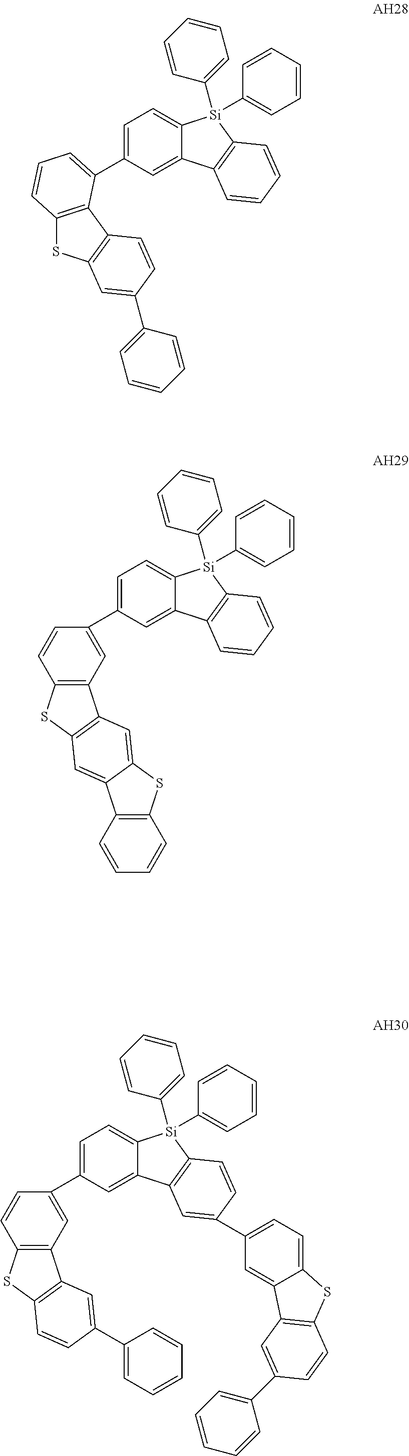 [SMILES: c1ccc(-c2ccc3c(c2)sc2cccc(-c4ccc5c(c4)-c4ccccc4[Si]5(c4ccccc4)c4ccccc4)c23)cc1 ; c1ccc([Si]2(c3ccccc3)c3ccccc3-c3cc(-c4ccc5sc6cc7c(cc6c5c4)sc4ccccc47)ccc32)cc1 ; c1ccc(-c2ccc3sc4ccc(-c5ccc6c(c5)-c5cc(-c7ccc8sc9ccc(-c%10ccccc%10)cc9c8c7)ccc5[Si]6(c5ccccc5)c5ccccc5)cc4c3c2)cc1]

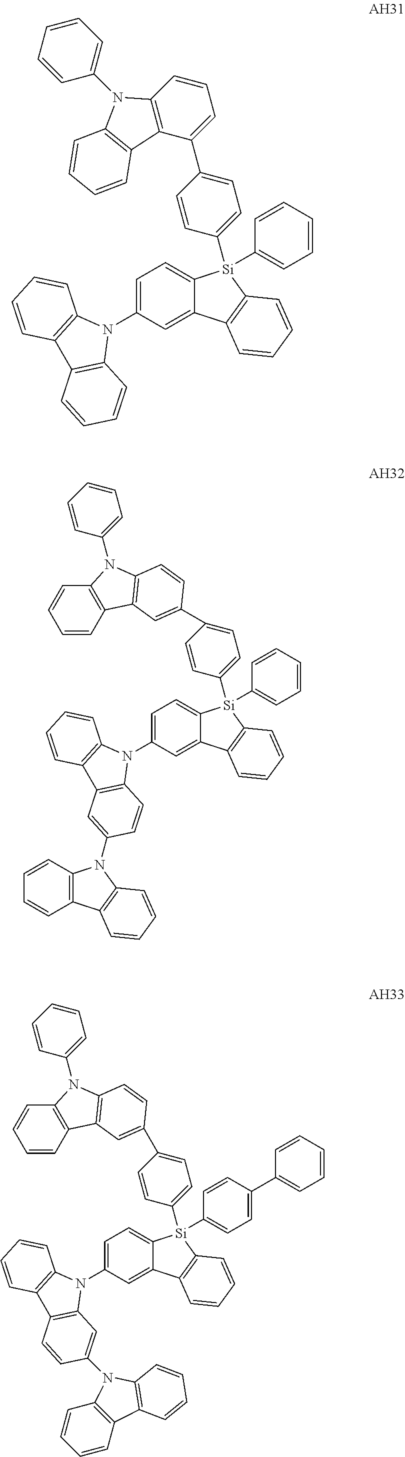 [SMILES: c1ccc(-n2c3ccccc3c3c(-c4ccc([Si]5(c6ccccc6)c6ccccc6-c6cc(-n7c8ccccc8c8ccccc87)ccc65)cc4)cccc32)cc1 ; c1ccc(-n2c3ccccc3c3cc(-c4ccc([Si]5(c6ccccc6)c6ccccc6-c6cc(-n7c8ccccc8c8cc(-n9c%10ccccc%10c%10ccccc%109)ccc87)ccc65)cc4)ccc32)cc1 ; c1ccc(-c2ccc([Si]3(c4ccc(-c5ccc6c(c5)c5ccccc5n6-c5ccccc5)cc4)c4ccccc4-c4cc(-n5c6ccccc6c6ccc(-n7c8ccccc8c8ccccc87)cc65)ccc43)cc2)cc1]

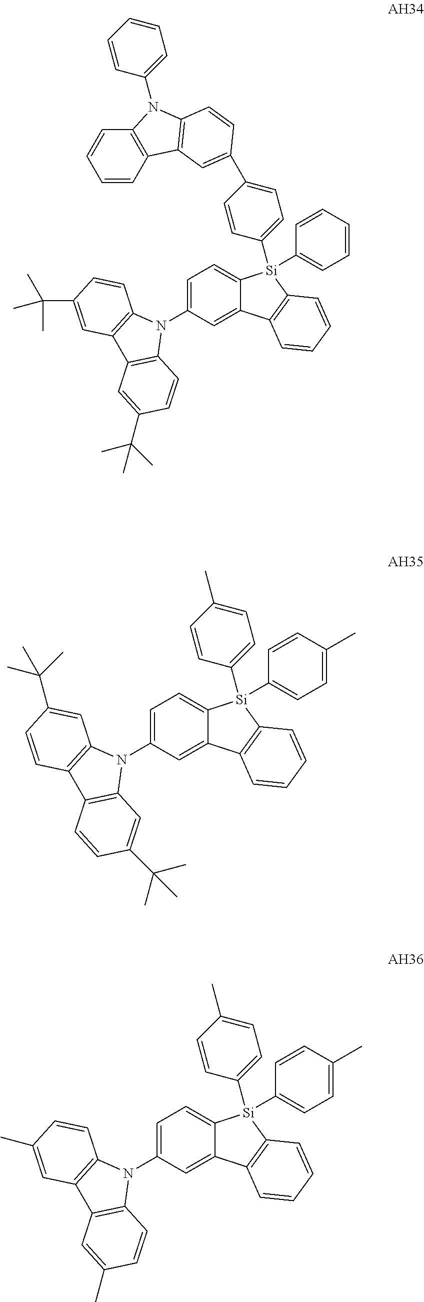

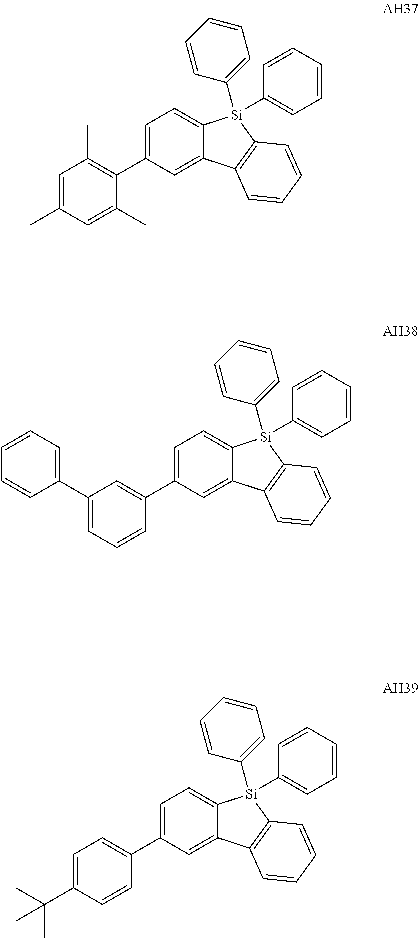 [SMILES: Cc1cc(C)c(-c2ccc3c(c2)-c2ccccc2[Si]3(c2ccccc2)c2ccccc2)c(C)c1 ; c1ccc(-c2cccc(-c3ccc4c(c3)-c3ccccc3[Si]4(c3ccccc3)c3ccccc3)c2)cc1 ; CC(C)(C)c1ccc(-c2ccc3c(c2)-c2ccccc2[Si]3(c2ccccc2)c2ccccc2)cc1]

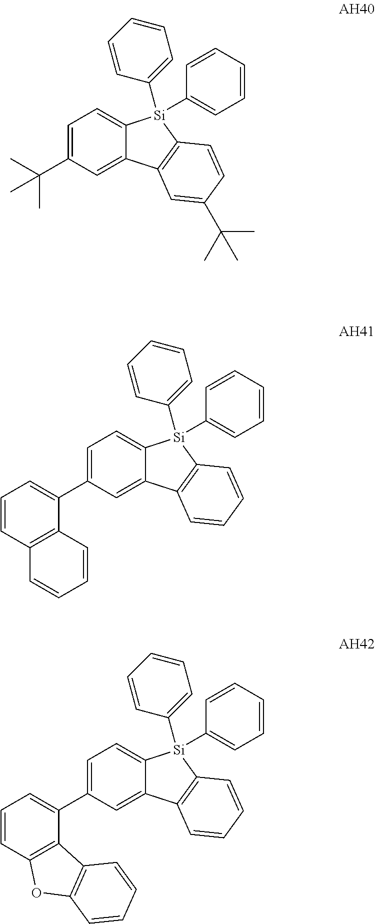 [SMILES: CC(C)(C)c1ccc2c(c1)-c1cc(C(C)(C)C)ccc1[Si]2(c1ccccc1)c1ccccc1 ; c1ccc([Si]2(c3ccccc3)c3ccccc3-c3cc(-c4cccc5ccccc45)ccc32)cc1 ; c1ccc([Si]2(c3ccccc3)c3ccccc3-c3cc(-c4cccc5oc6ccccc6c45)ccc32)cc1]

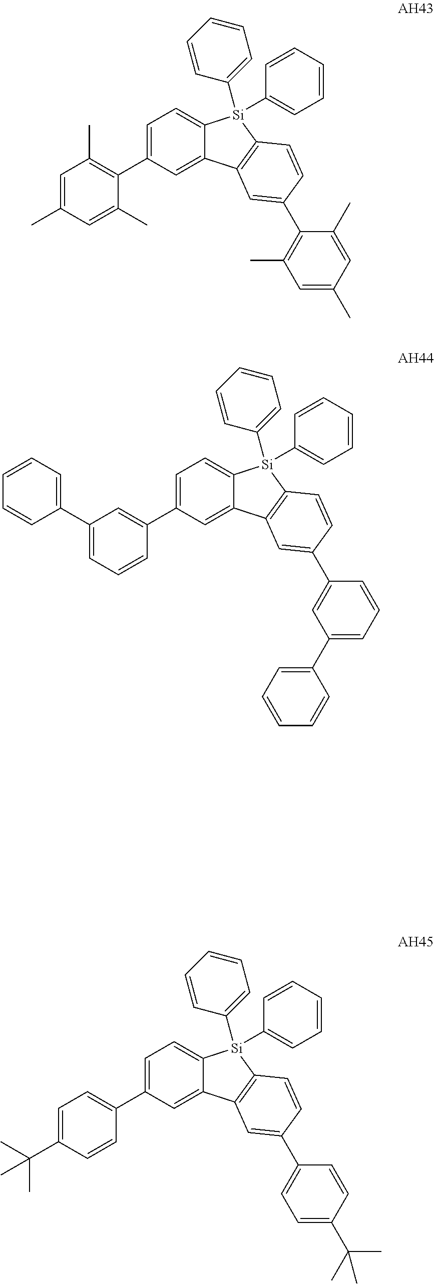

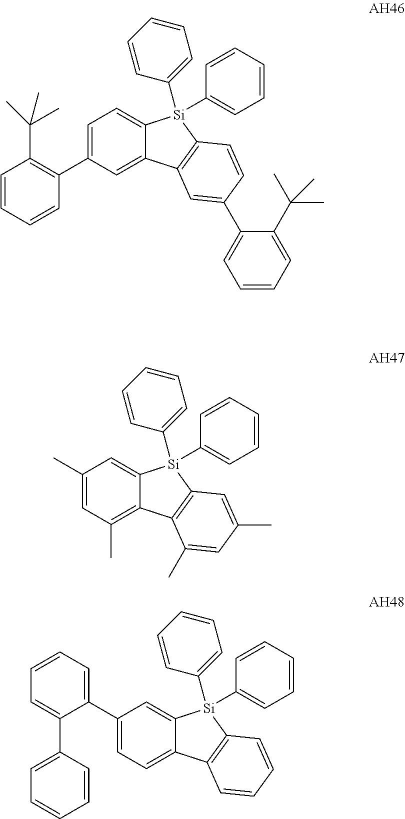

The heterocyclic compound represented by Formula 1, according to one or more embodiments, includes, as a basic skeletal structure, a dibenzosilole group containing a silicon atom as a ring-forming atom, and thus may have excellent or suitable hole transport characteristics and a high energy level of a triplet state. Therefore, if (e.g., when) the heterocyclic compound according to one or more embodiments is applied to at least one among the plurality of functional layers of the light-emitting element, and for example to the emission layer EML of the light-emitting element, high emission efficiency and long lifespan characteristics may be achieved.

The heterocyclic compound according to one or more embodiments may have a high energy level of a triplet state (T1 level). In one or more embodiments, the heterocyclic compound represented by Formula 1 may have an energy level of a triplet state of about 2.8 eV or more. For example, in one or more embodiments, the heterocyclic compound may have the energy level of the triplet state of about 2.8 eV to about 3.2 eV. When the energy level of the triplet state of the heterocyclic compound falls within the above-described range, excitons in the emission layer EML of the light-emitting element ED may be effectively trapped. For example, because the heterocyclic compound represented by Formula 1 has a relatively high energy level of the triplet state, the excitons within the light-emitting element ED may be effectively trapped. Therefore, a charge balance within the light-emitting element ED according to one or more embodiments may be improved, and thus high efficiency may be achieved.

In the light-emitting element ED according to one or more embodiments, the emission layer EML includes a host and a dopant, and the heterocyclic compound according to one or more embodiments may be contained in the emission layer EML as a host. In one or more embodiments, the emission layer EML may include a hole-transporting host and an electron-transporting host, and the hole-transporting host may include the heterocyclic compound according to one or more embodiments.

In addition, the light-emitting element ED according to one or more embodiments may include a second compound represented by Formula ET as the electron-transporting host.

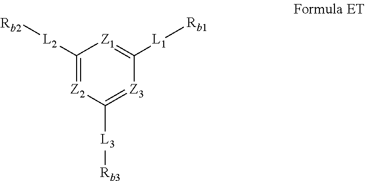

In Formula ET, at least one selected from among Z₁ to Z₃ may be N, and the rest may be CR_{b4}. For example, in one or more embodiments, any one selected from among Z₁ to Z₃ may be N, and the rest may each independently be CR_{b4}. In these embodiments, the second compound represented by Formula ET may include a pyridine moiety. In one or more embodiments, two selected from among Z₁ to Z₃ may be N, and the rest may be CR_{b4}. In these embodiments, the second compound represented by Formula ET may include a pyrimidine moiety. In one or more embodiments, Z₁ to Z₃ may all be N. In these embodiments, the second compound represented by Formula ET may include a triazine moiety.

In Formula ET, R_{b1} to R_{b3} may each independently be hydrogen, deuterium, a halogen, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R_{b1} to R_{b3} may each independently be a substituted or unsubstituted phenyl group or a substituted or unsubstituted carbazole group.

In Formula ET, R_{b4} may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

In one or more embodiments, the second compound may be any one selected from among compounds in Compound Group 2. The light-emitting element ED of one or more embodiments may include at least one selected from among the compounds in Compound Group 2.

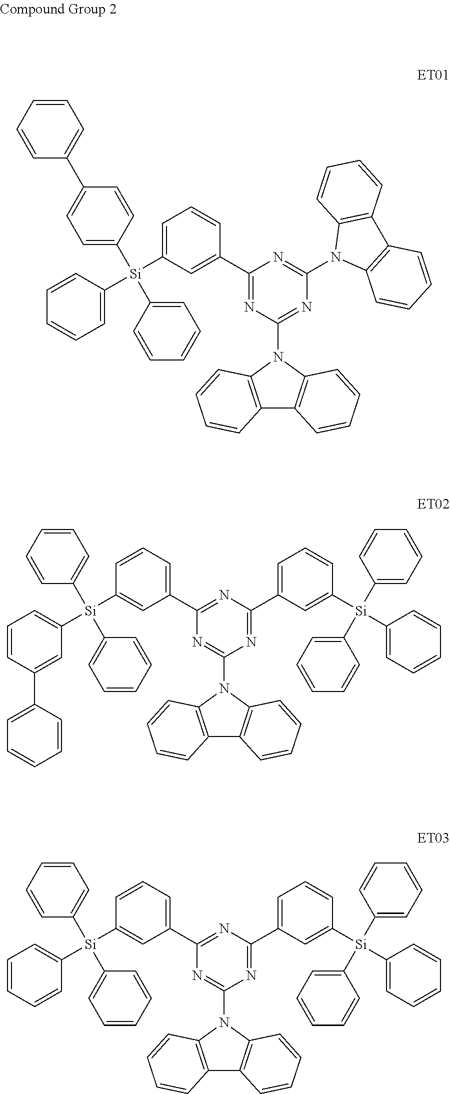 [SMILES: c1ccc(-c2ccc([Si](c3ccccc3)(c3ccccc3)c3cccc(-c4nc(-n5c6ccccc6c6ccccc65)nc(-n5c6ccccc6c6ccccc65)n4)c3)cc2)cc1 ; c1ccc(-c2cccc([Si](c3ccccc3)(c3ccccc3)c3cccc(-c4nc(-c5cccc([Si](c6ccccc6)(c6ccccc6)c6ccccc6)c5)nc(-n5c6ccccc6c6ccccc65)n4)c3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1]

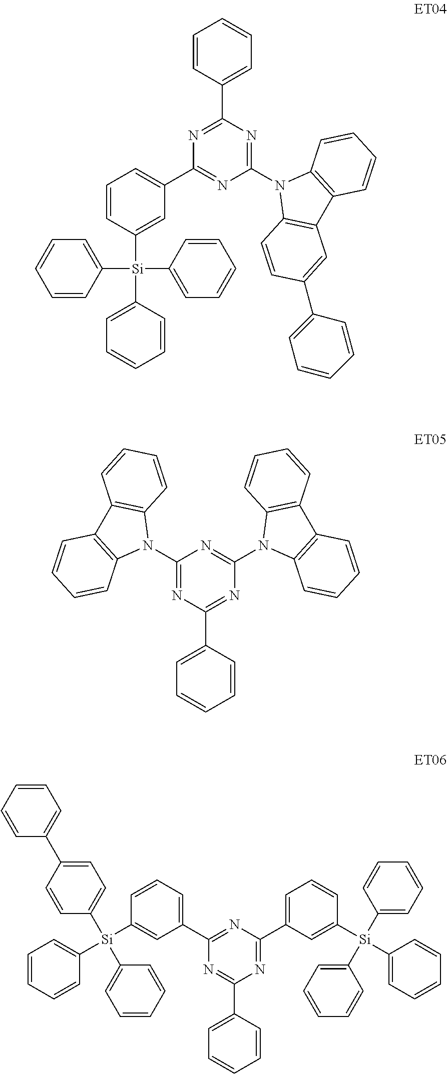 [SMILES: c1ccc(-c2ccc3c(c2)c2ccccc2n3-c2nc(-c3ccccc3)nc(-c3cccc([Si](c4ccccc4)(c4ccccc4)c4ccccc4)c3)n2)cc1 ; c1ccc(-c2nc(-n3c4ccccc4c4ccccc43)nc(-n3c4ccccc4c4ccccc43)n2)cc1 ; c1ccc(-c2ccc([Si](c3ccccc3)(c3ccccc3)c3cccc(-c4nc(-c5ccccc5)nc(-c5cccc([Si](c6ccccc6)(c6ccccc6)c6ccccc6)c5)n4)c3)cc2)cc1]

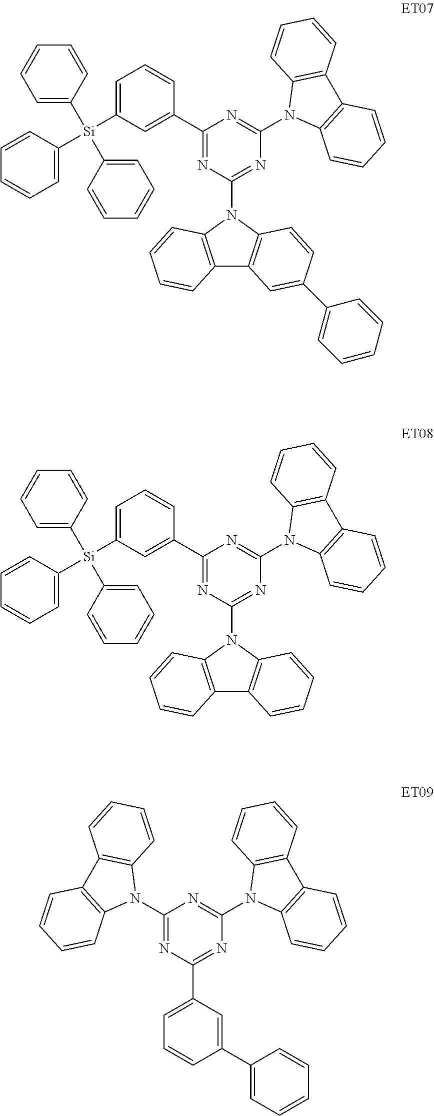 [SMILES: c1ccc(-c2ccc3c(c2)c2ccccc2n3-c2nc(-c3cccc([Si](c4ccccc4)(c4ccccc4)c4ccccc4)c3)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2cccc(-c3nc(-n4c5ccccc5c5ccccc54)nc(-n4c5ccccc5c5ccccc54)n3)c2)cc1]

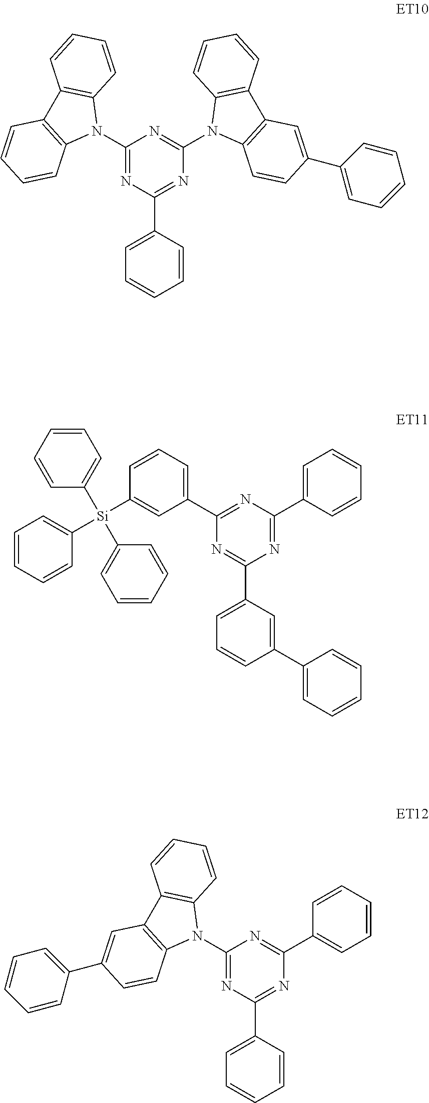 [SMILES: c1ccc(-c2ccc3c(c2)c2ccccc2n3-c2nc(-c3ccccc3)nc(-n3c4ccccc4c4ccccc43)n2)cc1 ; c1ccc(-c2cccc(-c3nc(-c4ccccc4)nc(-c4cccc([Si](c5ccccc5)(c5ccccc5)c5ccccc5)c4)n3)c2)cc1 ; c1ccc(-c2ccc3c(c2)c2ccccc2n3-c2nc(-c3ccccc3)nc(-c3ccccc3)n2)cc1]

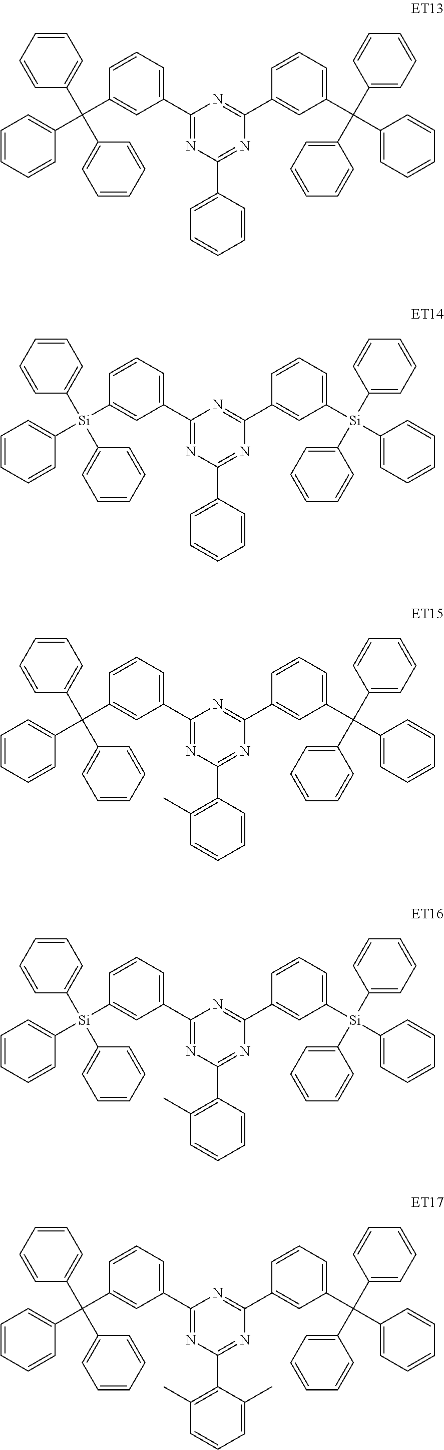

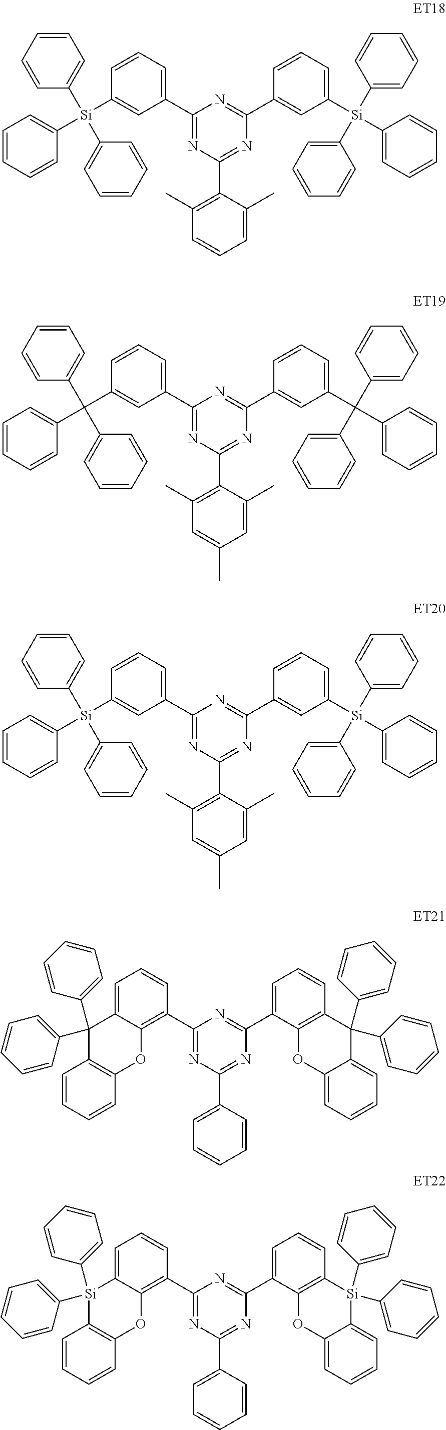

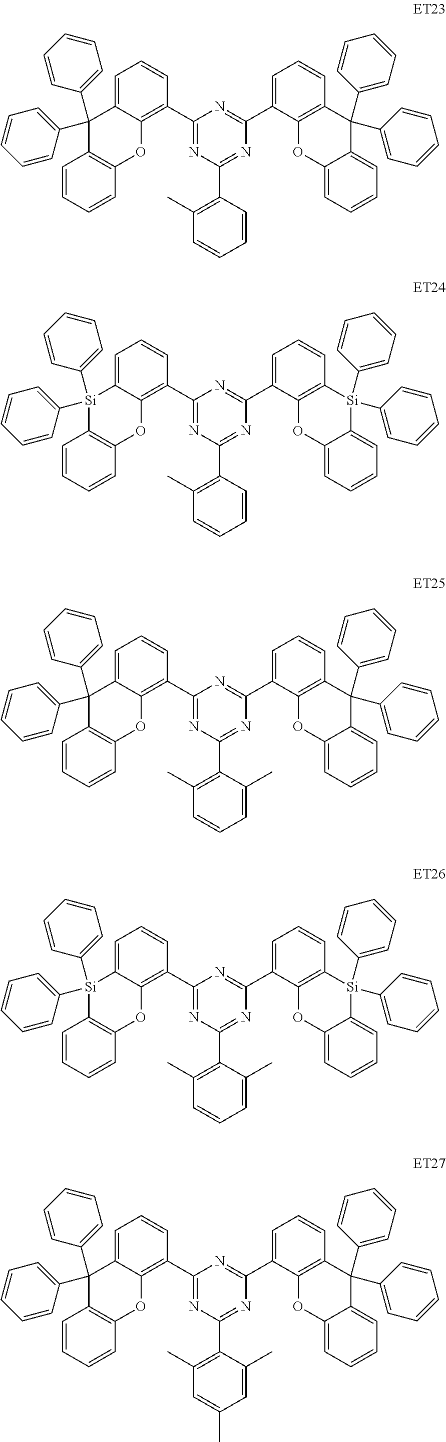

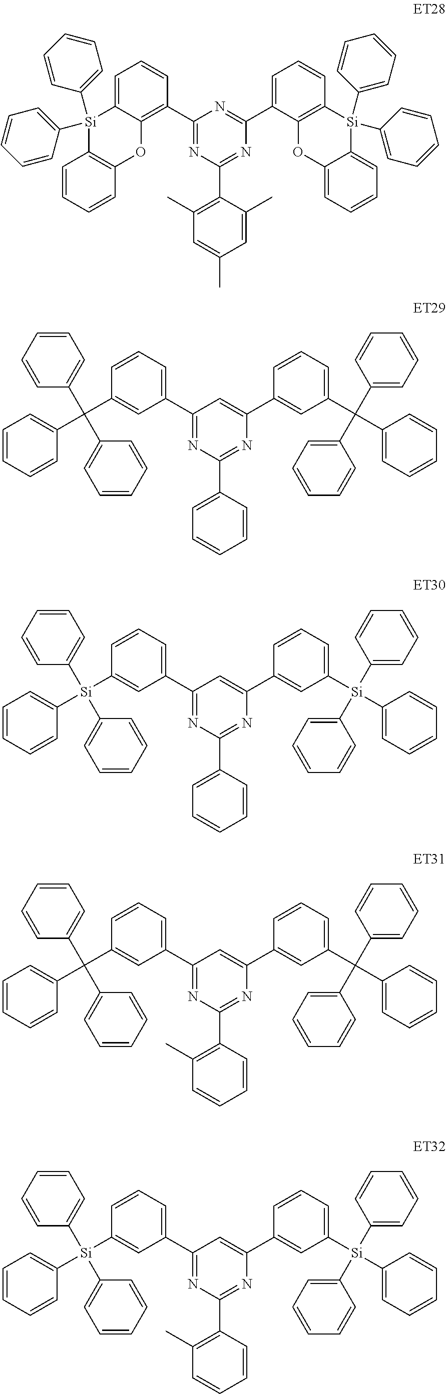

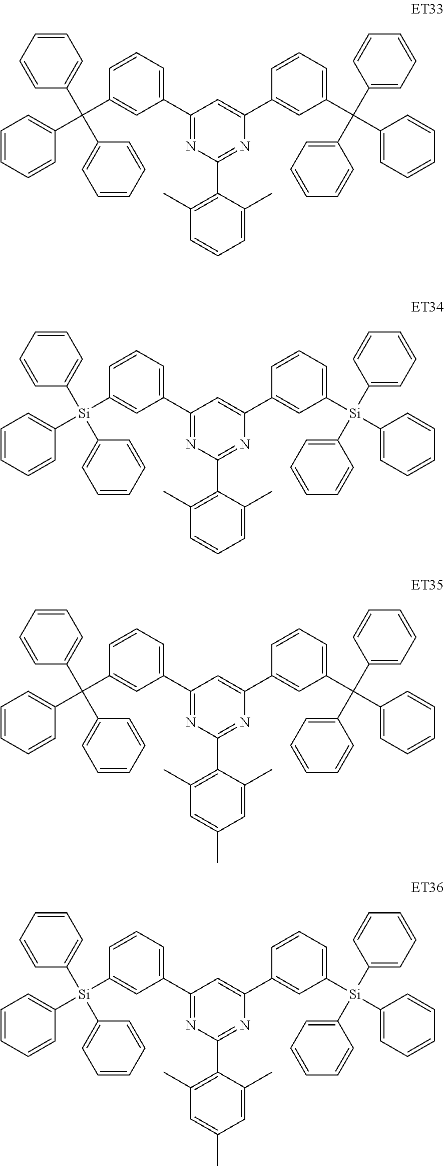 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

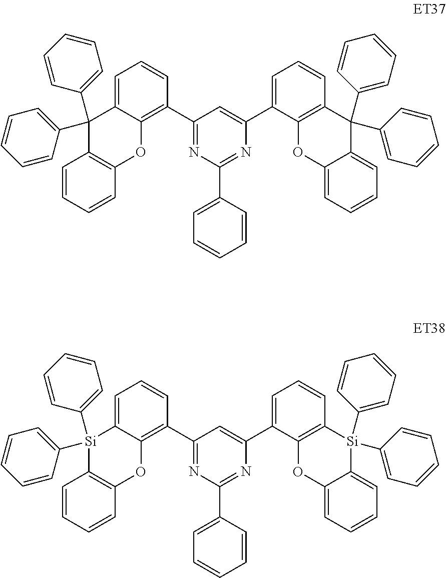 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1]

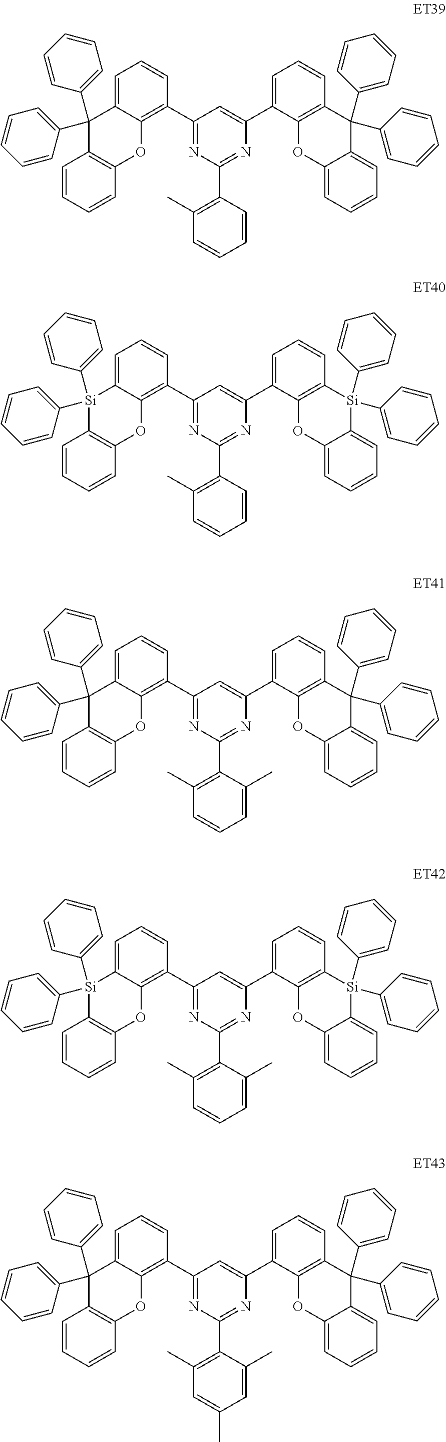

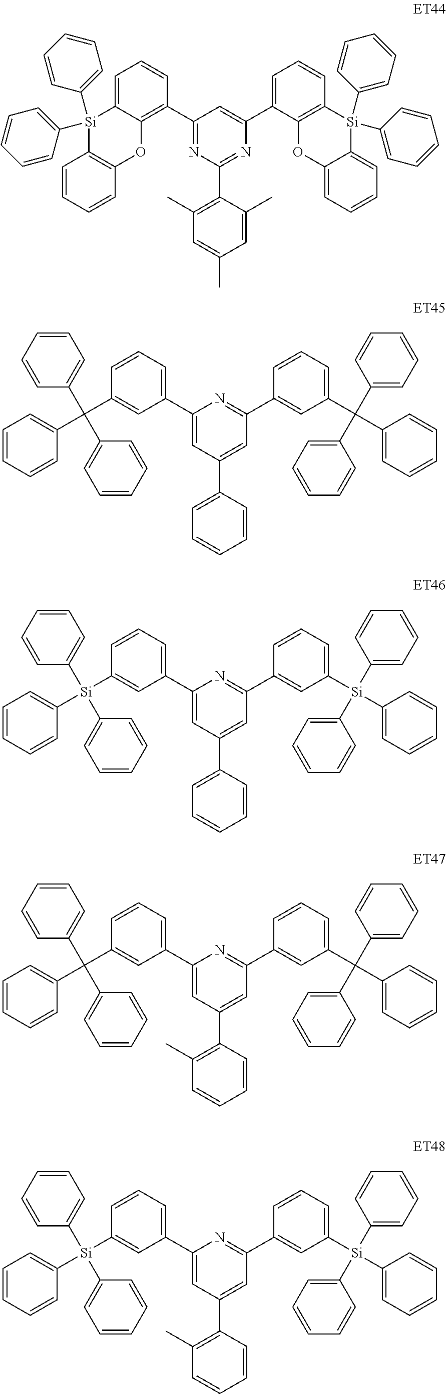

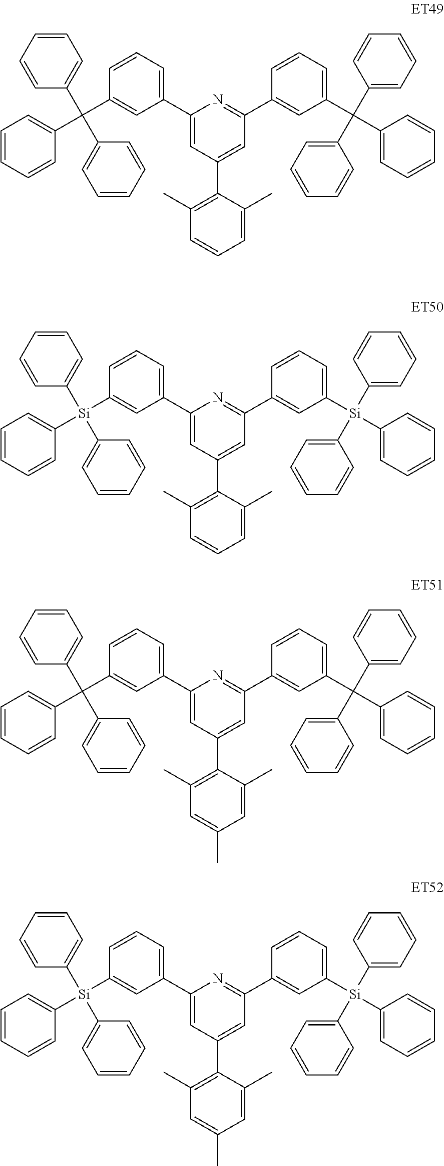 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

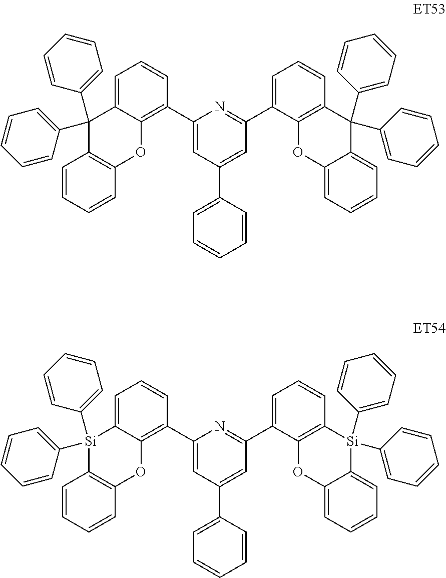 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1]

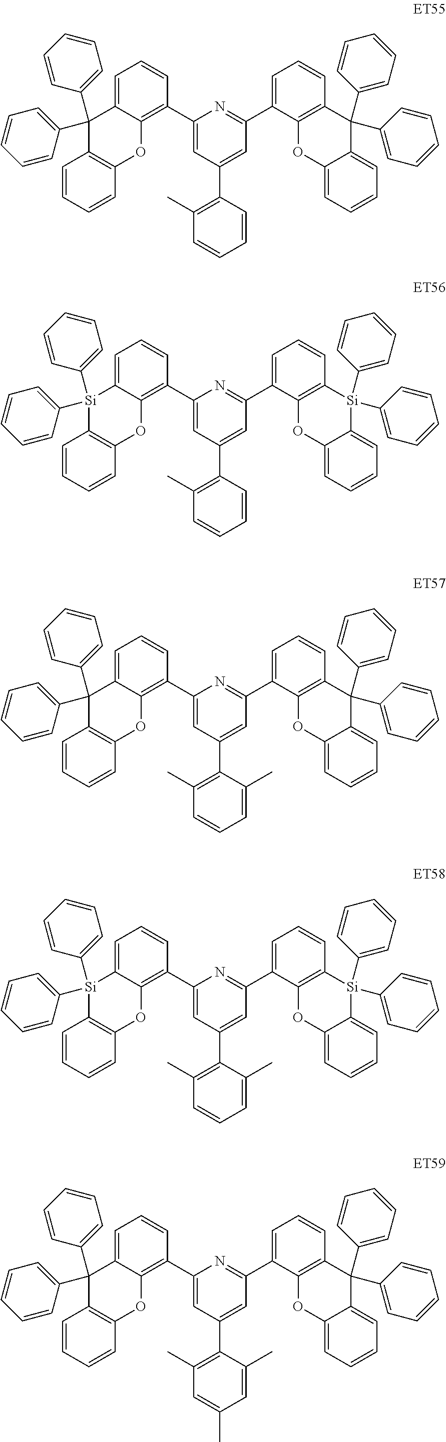

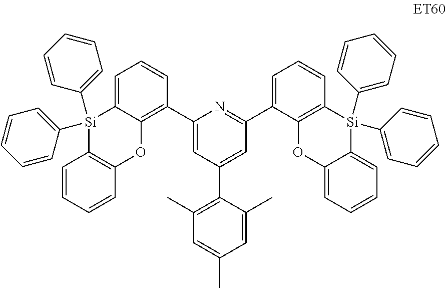 [SMILES: Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

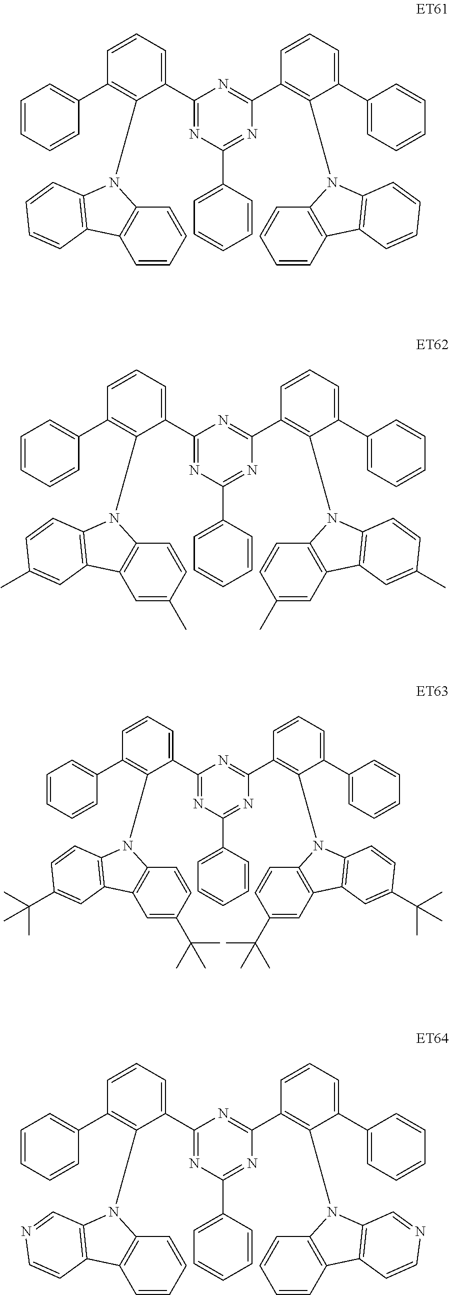

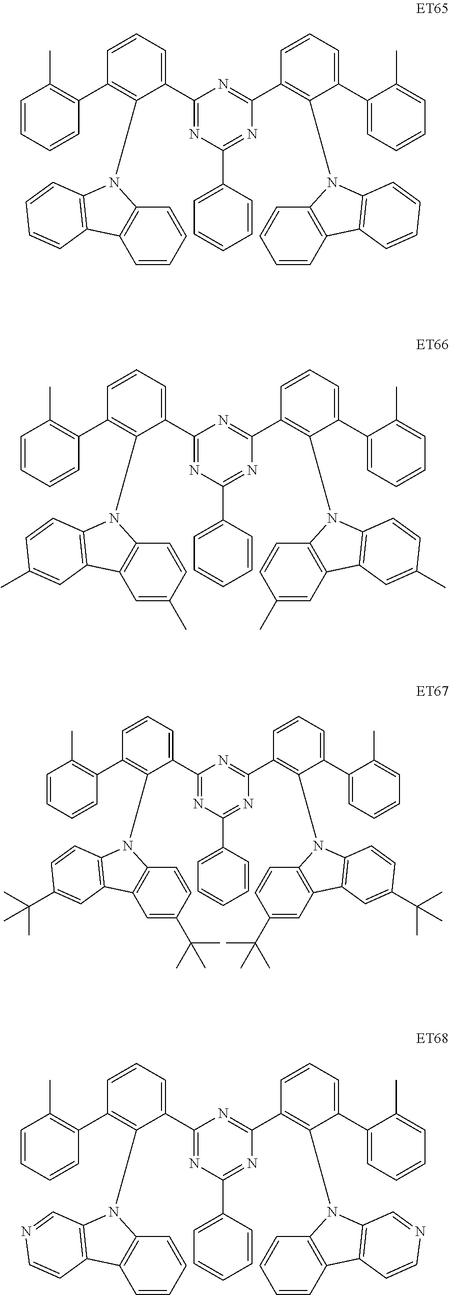

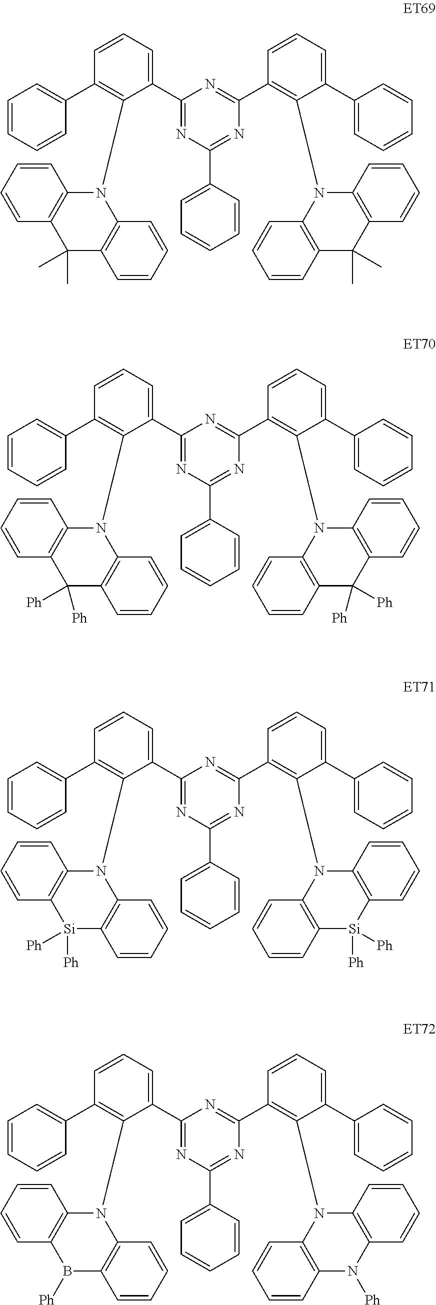

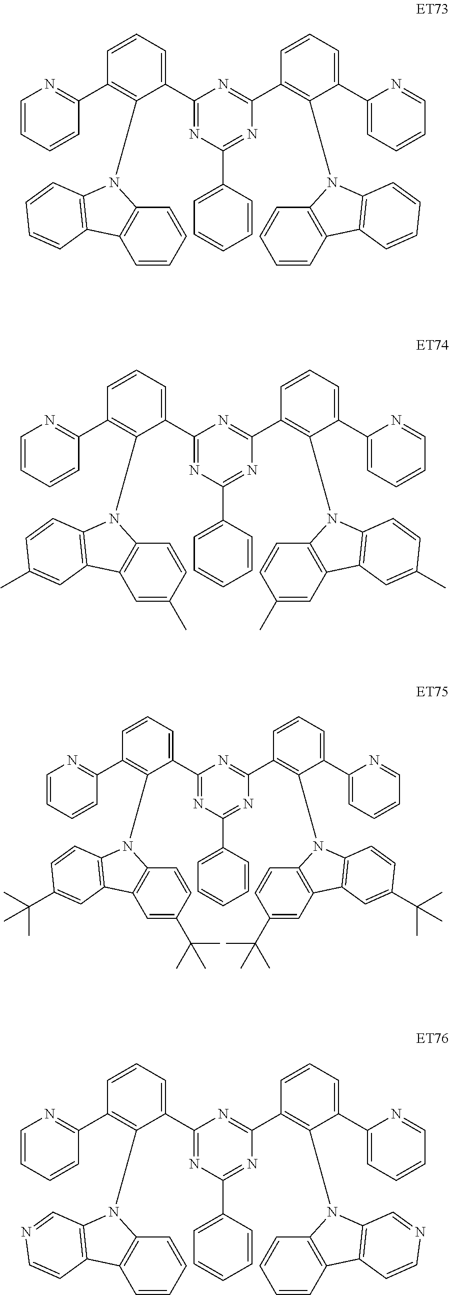

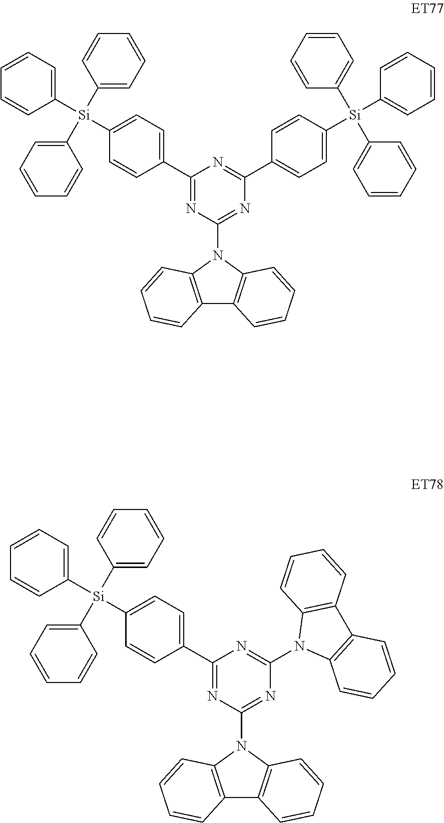 [SMILES: c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

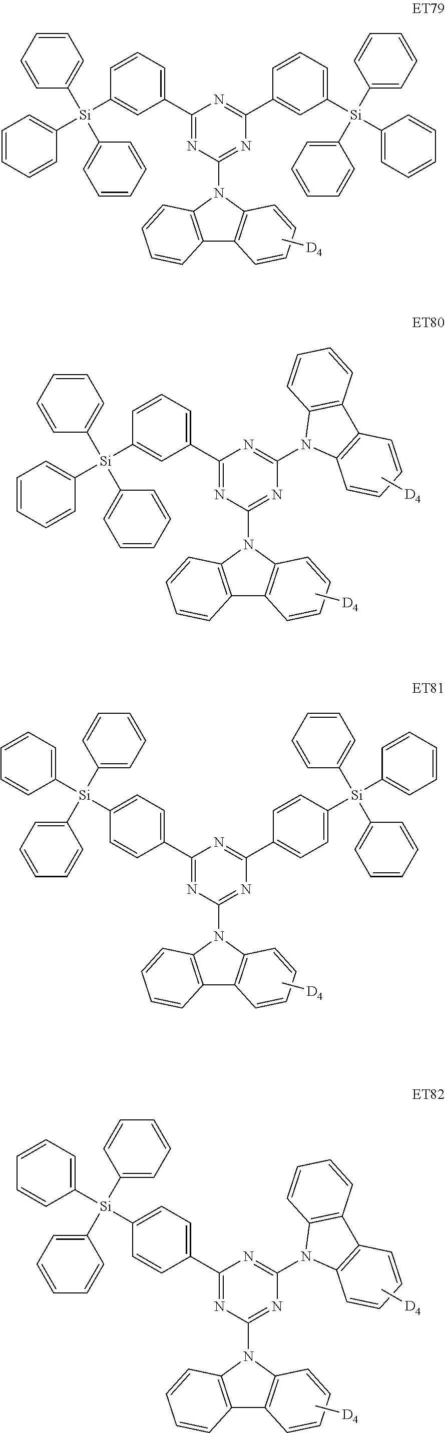

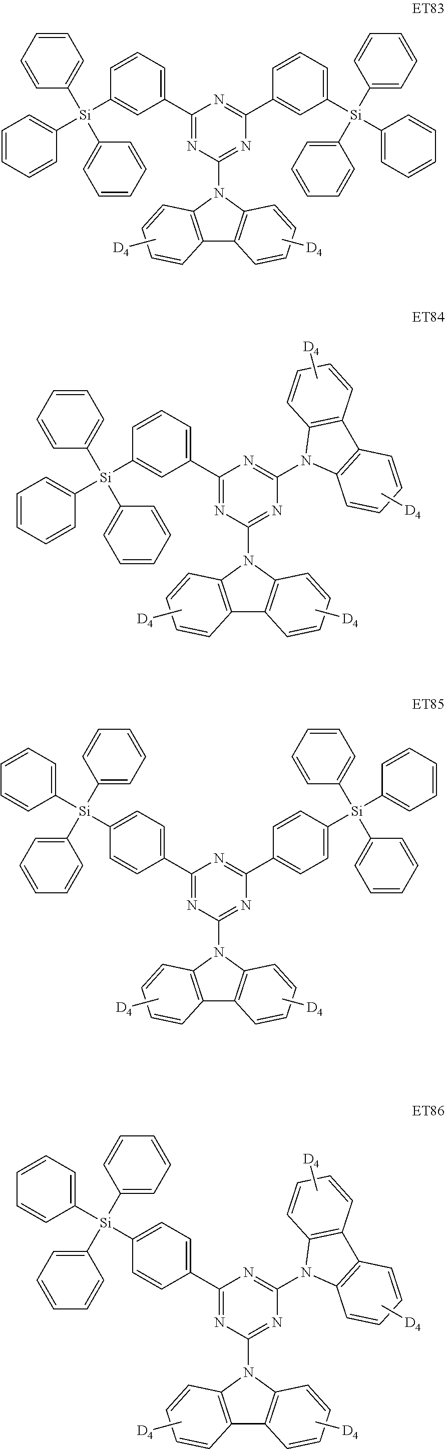

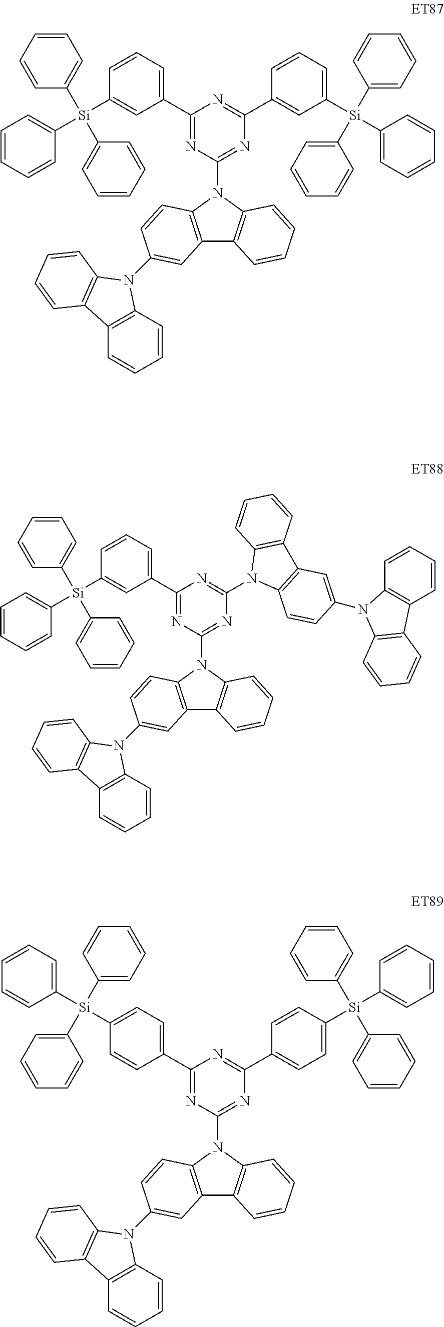 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

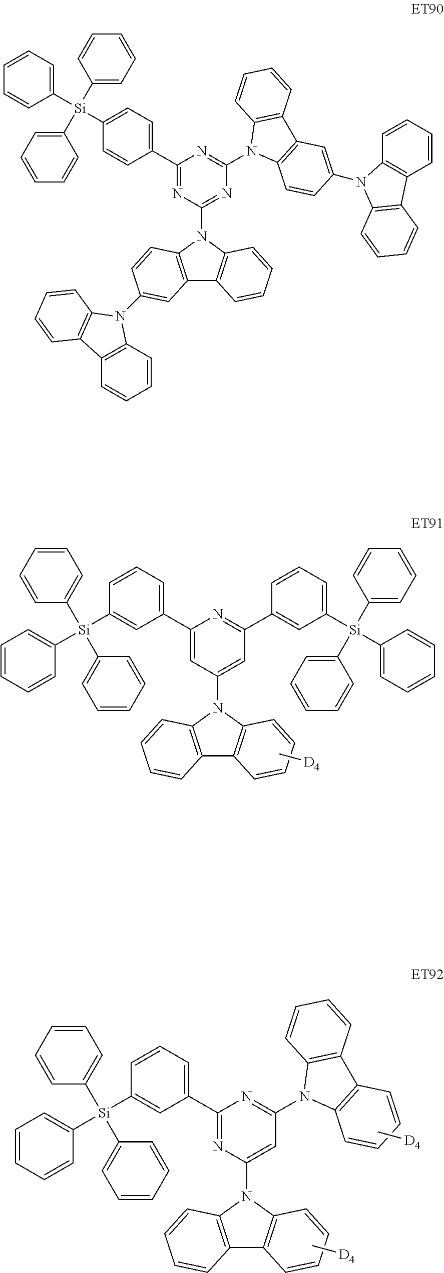

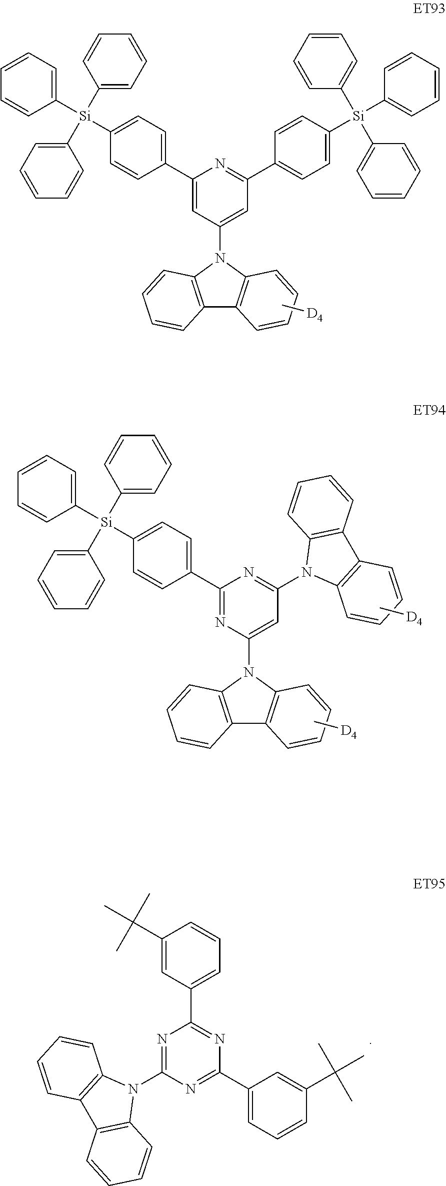

In the embodiment compounds presented in Compound Group 2, “D” refers to deuterium and “Ph” refers to an unsubstituted phenyl group.

In one or more embodiments, the third compound may be represented by Formula F-1. At least one functional layer among the plurality of functional layers of the light-emitting element ED may include a third compound represented by Formula F-1. For example, the third compound may be a dopant material of the emission layer EML of the light-emitting element ED.

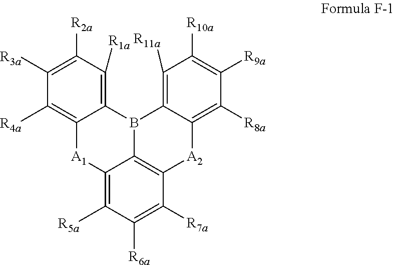

In Formula F-1, A₁ and A₂ may each independently be NRₘ or O. For example, in one or more embodiments, both (e.g., simultaneously) A₁ and A₂ may be NRₘ. In one or more embodiments, both (e.g., simultaneously) A₁ and A₂ may be O.

In Formula F-1, Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula F-1, R₁ₐ to R₁₁ₐ may each independently be hydrogen, deuterium, a halogen, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or may be bonded with an adjacent group to form a ring.

For example, in one or more embodiments, R₁ₐ to R₁₁ₐ may each independently be a substituted or unsubstituted methyl group, a substituted or unsubstituted t-butyl group, a substituted or unsubstituted phenyl group, a substituted or unsubstituted diphenylamine group, or a substituted or unsubstituted carbazole group. In one or more embodiments, for example, R₂ₐ and R₃ₐ, and R₉ₐ and R₁₀ₐ, which are adjacent groups, may be bonded with each other to form a ring, each via an amine group, a boron group, an oxy group, or a thio group, and/or the like.

In one or more embodiments, in Formula F-1, A₁ and A₂ may each independently be bonded with substituents of a neighboring ring to form a fused ring. For example, if A₁ and A₂ may each independently be NRₘ, A₁ may be bonded with R₄ₐ or R₅ₐ to form a ring. In addition, A₂ may be bonded with R₇ₐ or R₈ₐ to form a ring.

For example, in one or more embodiments, the third compound represented by Formula F-1 may be contained in the emission layer EML as a dopant. In one or more embodiments, the third compound represented by Formula F-1 may be a thermally activated delayed fluorescent dopant.

The third compound may be any one selected from among compounds in Compound Group 3.

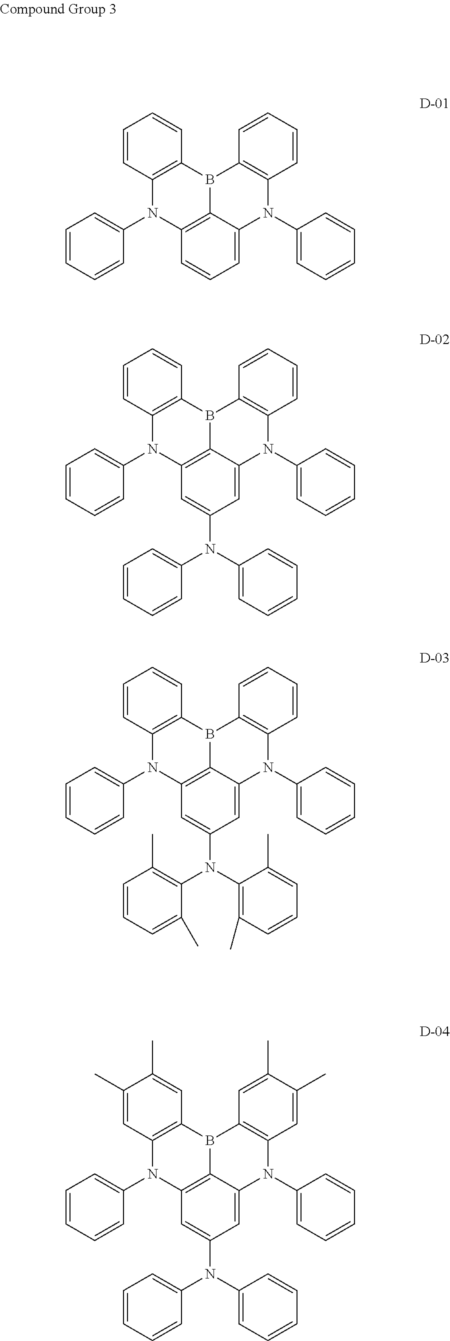 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; Cc1cccc(C)c1N(c1cc2c3c(c1)N(c1ccccc1)c1ccccc1B3c1ccccc1N2c1ccccc1)c1c(C)cccc1C ; Cc1cc2c(cc1C)N(c1ccccc1)c1cc(N(c3ccccc3)c3ccccc3)cc3c1B2c1cc(C)c(C)cc1N3c1ccccc1]

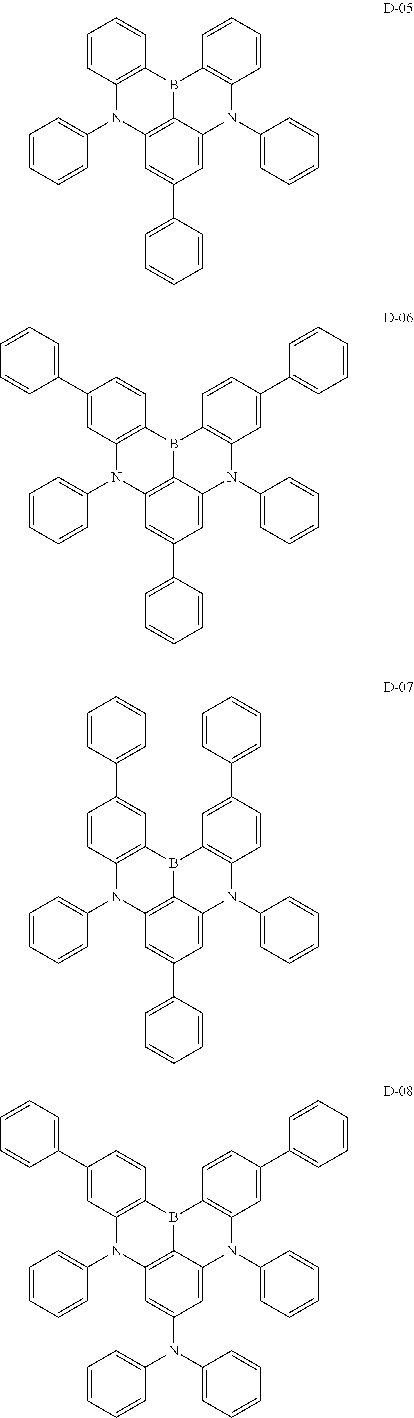 [SMILES: c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1]

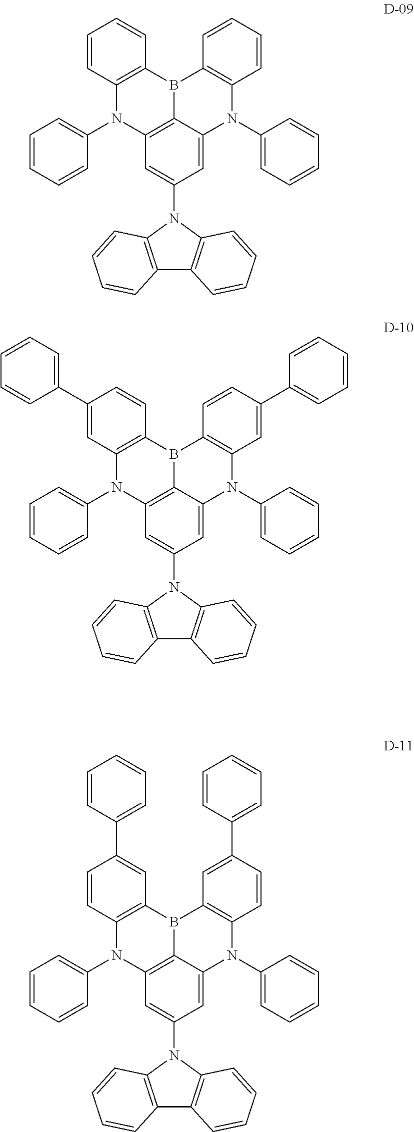 [SMILES: c1ccc(N2c3ccccc3B3c4ccccc4N(c4ccccc4)c4cc(-n5c6ccccc6c6ccccc65)cc2c43)cc1 ; c1ccc(-c2ccc3c(c2)N(c2ccccc2)c2cc(-n4c5ccccc5c5ccccc54)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1]

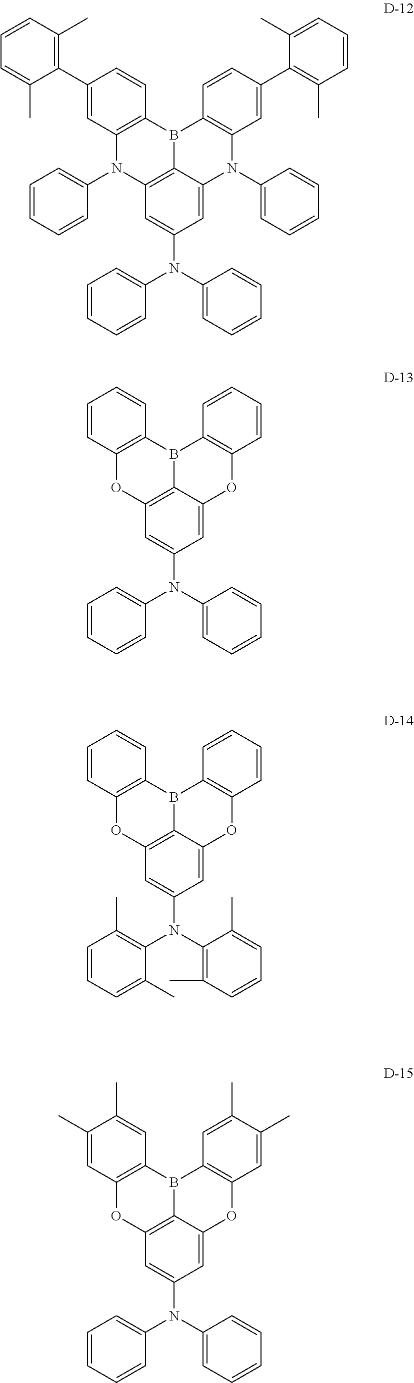

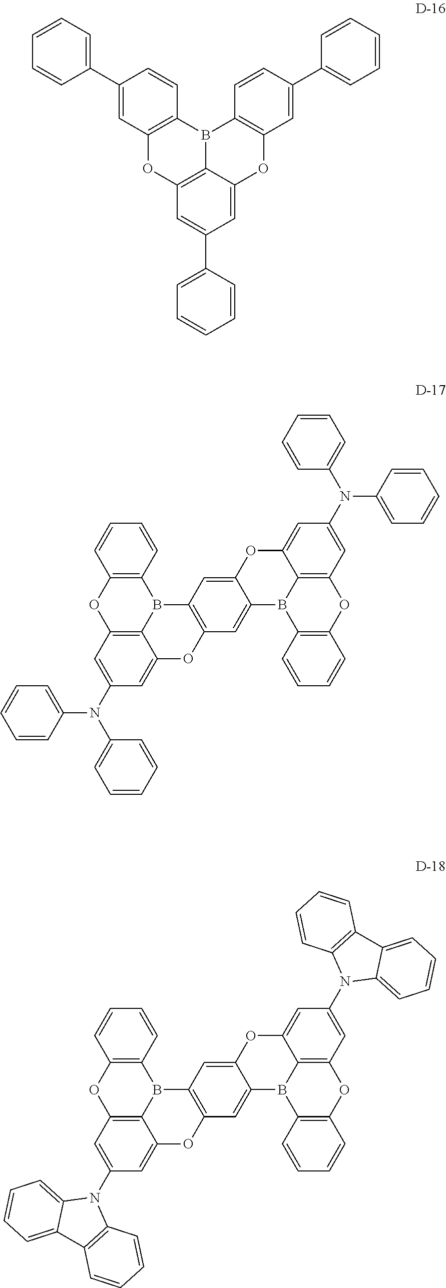 [SMILES: c1ccc(-c2ccc3c(c2)Oc2cc(-c4ccccc4)cc4c2B3c2ccc(-c3ccccc3)cc2O4)cc1 ; c1ccc(N(c2ccccc2)c2cc3c4c(c2)Oc2cc5c(cc2B4c2ccccc2O3)Oc2cc(N(c3ccccc3)c3ccccc3)cc3c2B5c2ccccc2O3)cc1 ; c1ccc2c(c1)Oc1cc(-n3c4ccccc4c4ccccc43)cc3c1B2c1cc2c(cc1O3)B1c3ccccc3Oc3cc(-n4c5ccccc5c5ccccc54)cc(c31)O2]

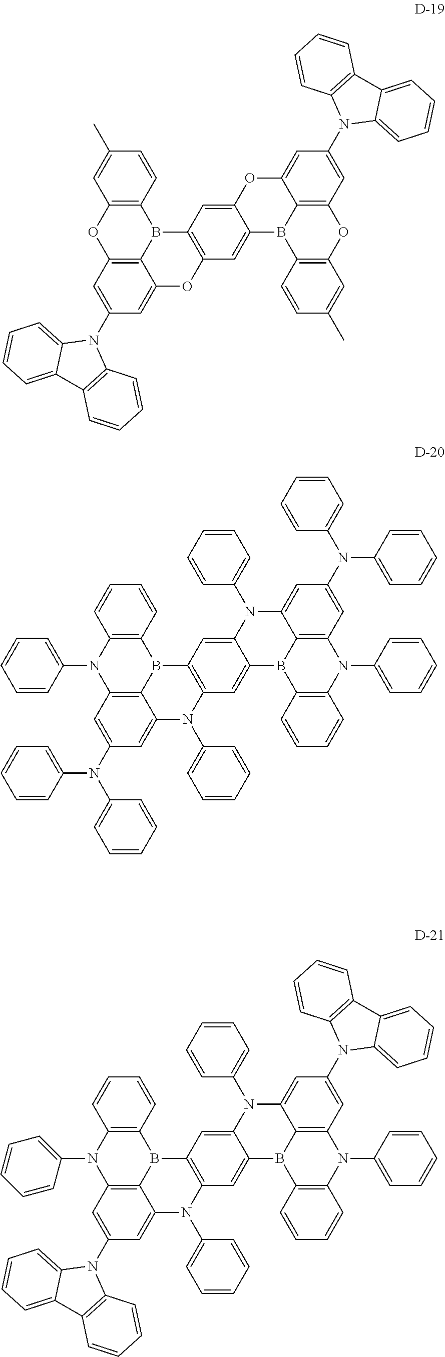 [SMILES: Cc1ccc2c(c1)Oc1cc(-n3c4ccccc4c4ccccc43)cc3c1B2c1cc2c(cc1O3)B1c3ccc(C)cc3Oc3cc(-n4c5ccccc5c5ccccc54)cc(c31)O2 ; c1ccc(N(c2ccccc2)c2cc3c4c(c2)N(c2ccccc2)c2cc5c(cc2B4c2ccccc2N3c2ccccc2)N(c2ccccc2)c2cc(N(c3ccccc3)c3ccccc3)cc3c2B5c2ccccc2N3c2ccccc2)cc1 ; c1ccc(N2c3ccccc3B3c4cc5c(cc4N(c4ccccc4)c4cc(-n6c7ccccc7c7ccccc76)cc2c43)B2c3ccccc3N(c3ccccc3)c3cc(-n4c6ccccc6c6ccccc64)cc(c32)N5c2ccccc2)cc1]

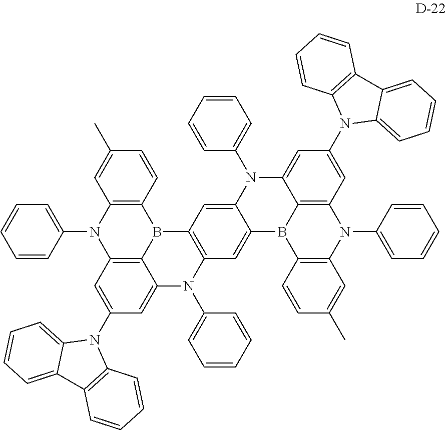 [SMILES: Cc1ccc2c(c1)N(c1ccccc1)c1cc(-n3c4ccccc4c4ccccc43)cc3c1B2c1cc2c(cc1N3c1ccccc1)B1c3ccc(C)cc3N(c3ccccc3)c3cc(-n4c5ccccc5c5ccccc54)cc(c31)N2c1ccccc1]

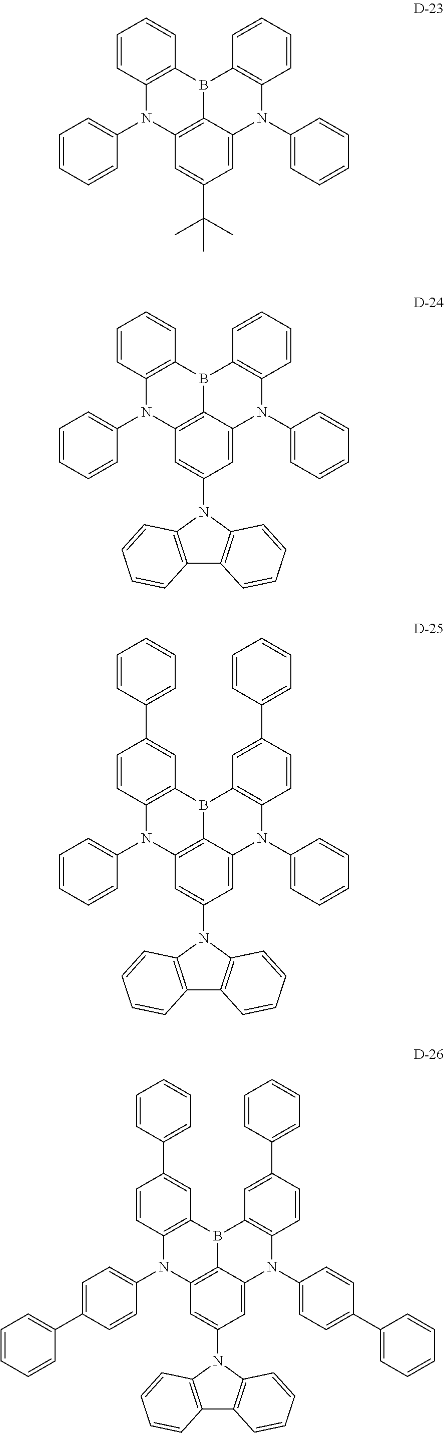 [SMILES: CC(C)(C)c1cc2c3c(c1)N(c1ccccc1)c1ccccc1B3c1ccccc1N2c1ccccc1 ; c1ccc(N2c3ccccc3B3c4ccccc4N(c4ccccc4)c4cc(-n5c6ccccc6c6ccccc65)cc2c43)cc1 ; c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1]

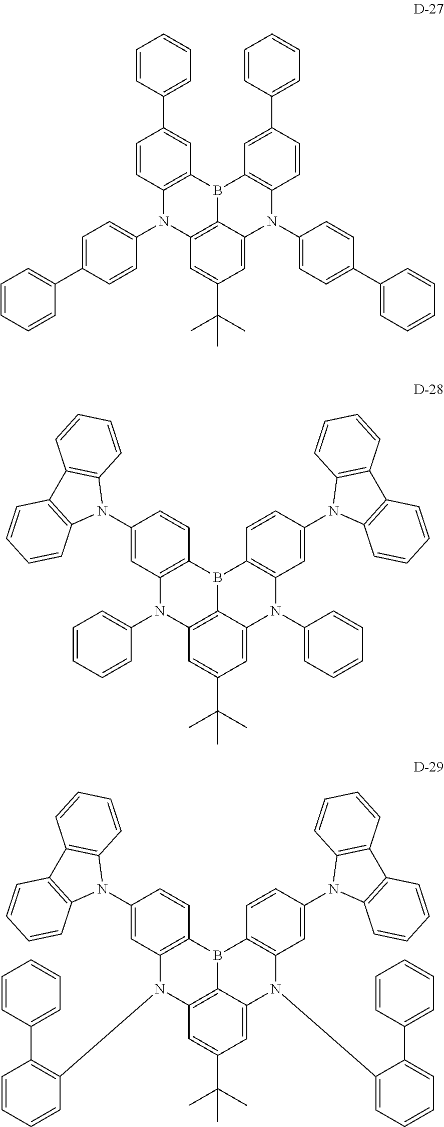 [SMILES: CC(C)(C)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(C)(C)c1cc2c3c(c1)N(c1ccccc1)c1cc(-n4c5ccccc5c5ccccc54)ccc1B3c1ccc(-n3c4ccccc4c4ccccc43)cc1N2c1ccccc1 ; CC(C)(C)c1cc2c3c(c1)N(c1ccccc1-c1ccccc1)c1cc(-n4c5ccccc5c5ccccc54)ccc1B3c1ccc(-n3c4ccccc4c4ccccc43)cc1N2c1ccccc1-c1ccccc1]

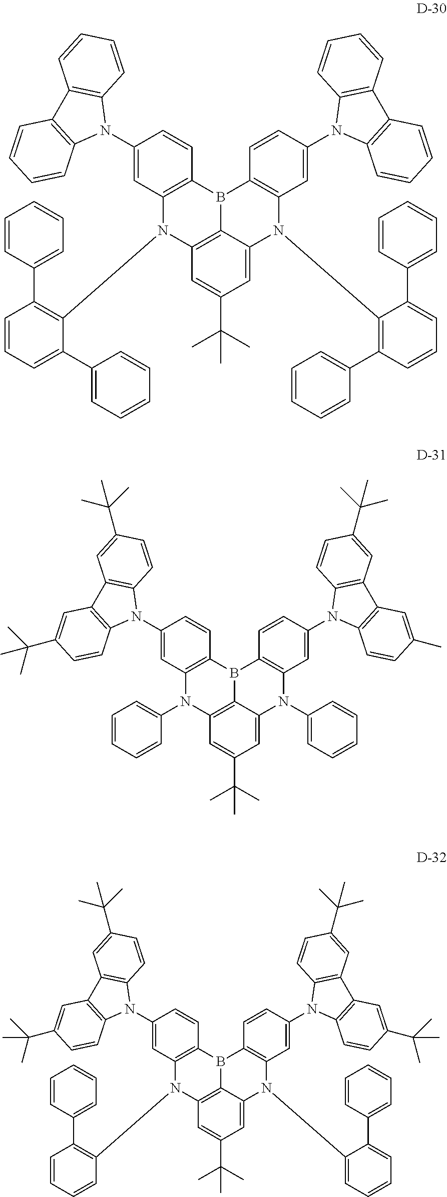

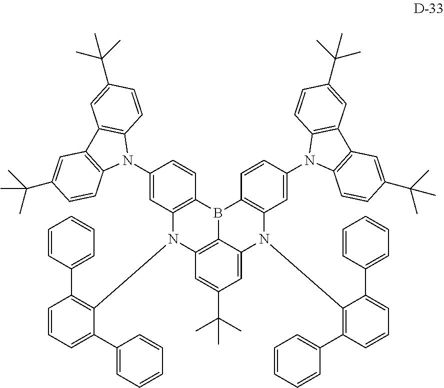 [SMILES: CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1ccccc1]

In one or more embodiments, at least one functional layer among the plurality of functional layers included in the light-emitting element ED may further include a fourth compound represented by Formula D-1. For example, at least one layer selected from among the hole transport region HTR, the emission layer EML, and the electron transport region ETR may further contain the fourth compound in addition to the first compound, the second compound, and the third compound. In one or more embodiments, the emission layer EML may contain the fourth compound in addition to the above-described first to the third compounds.

The fourth compound may be an organic metallic complex containing platinum (Pt) as a core metal atom and containing ligands bonded to the core metal atom. In one or more embodiments, the fourth compound may be represented by Formula D-1.

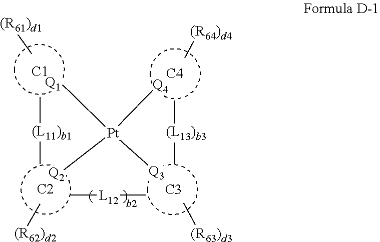

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

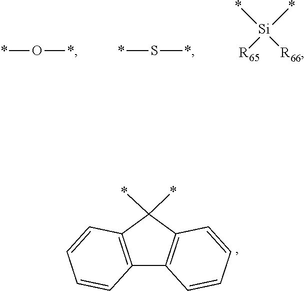

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” refers to a part linked to C1 to C4.

In Formula D-1, b1 to b3 may each independently be 0 or 1. If b1 is 0, C1 and C2 may not be linked to each other. If b2 is 0, C2 and C3 may not be linked to each other. If b3 is 0, C3 and C4 may not be linked to each other.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among (e.g., each of) R₆₁ to R₆₆ may be independently bonded to an adjacent group to form a ring. In one or more embodiments, R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if each of d1 to d4 is 0, the fourth compound may not be substituted with each of R₆₁ to R₆₄. The embodiment in which each of d1 to d4 is 4 and R₆₁'s to R₆₄'s are each hydrogen may be the same as the embodiment in which each of d1 to d4 is 0. When each of d1 to d4 is an integer of 2 or more, a plurality of R₆₁'s to R₆₄'s may each be the same or at least one selected from among the plurality of R₆₁'s to R₆₄'s may be different from the others.

In Formula D-1, C₁ to C₄ may each independently be a substituted or unsubstituted hydrocarbon ring or a substituted or unsubstituted heterocycle represented by any one selected from among C-1 to C-4:

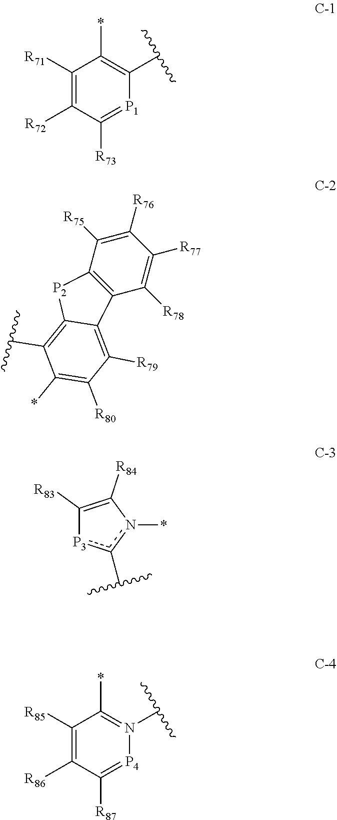

In C-1 to C-4, P₁ may be C—* or CR₇₄, P2 may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In addition, in C-1 to C-4,

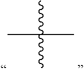

corresponds to a part linked to Pt that is the core metal atom, and “ [symbol] ” corresponds to a part linked to a neighboring cyclic group (C1 to C4) or a linker (L₁₁ to L₁₃).

In one or more embodiments, the fourth compound represented by Formula D-1 may be any one selected from among compounds represented by Compound Group 4. The emission layer EML may include at least one selected from among the compounds represented by Compound Group 4 as a sensitizer material.

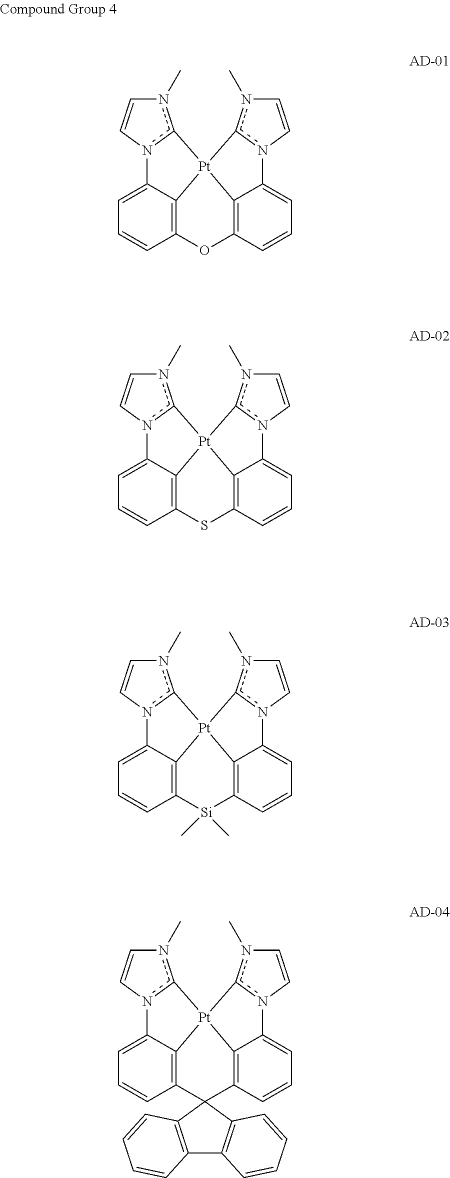

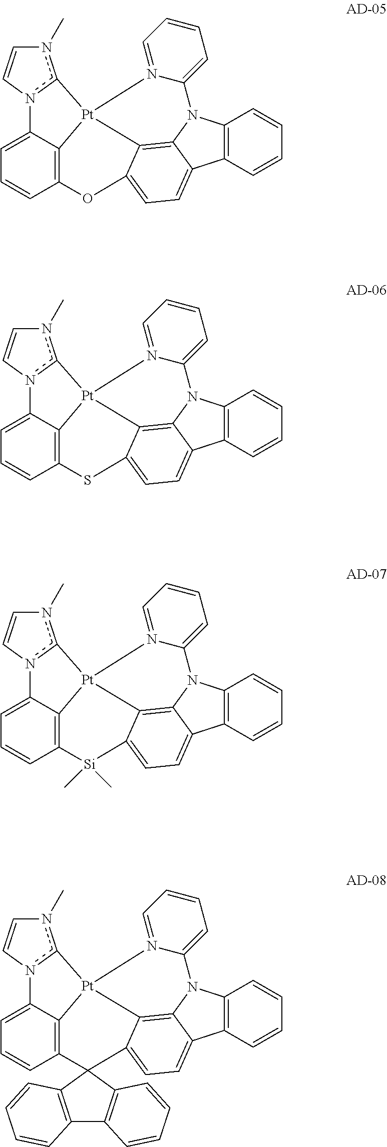

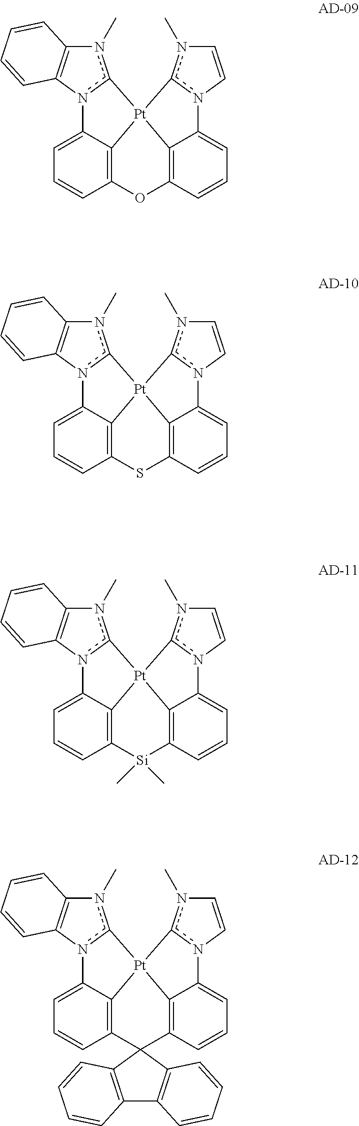

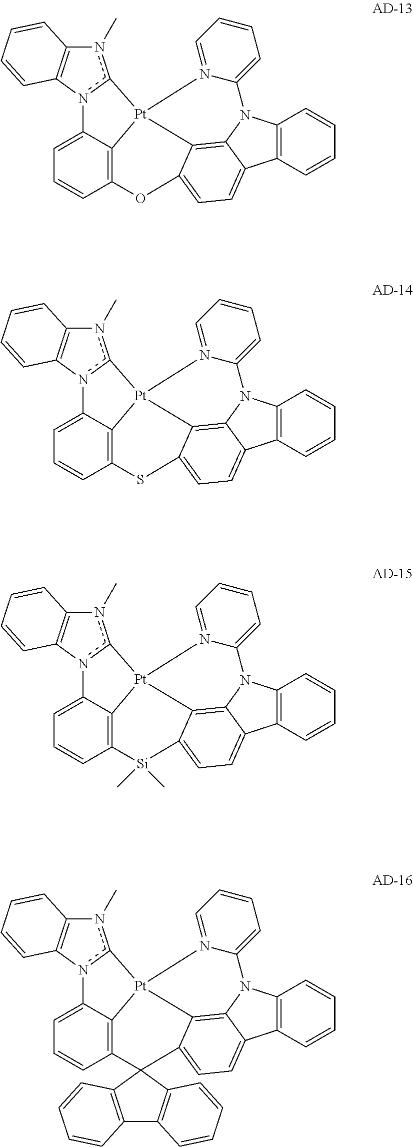

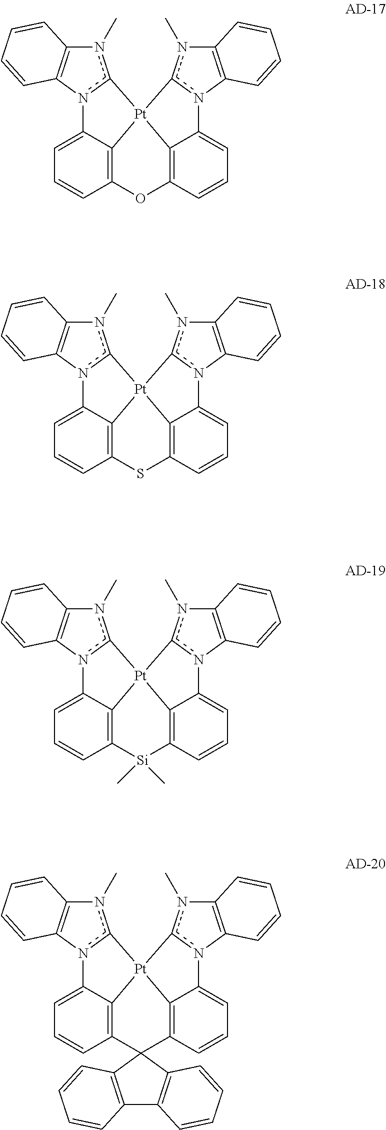

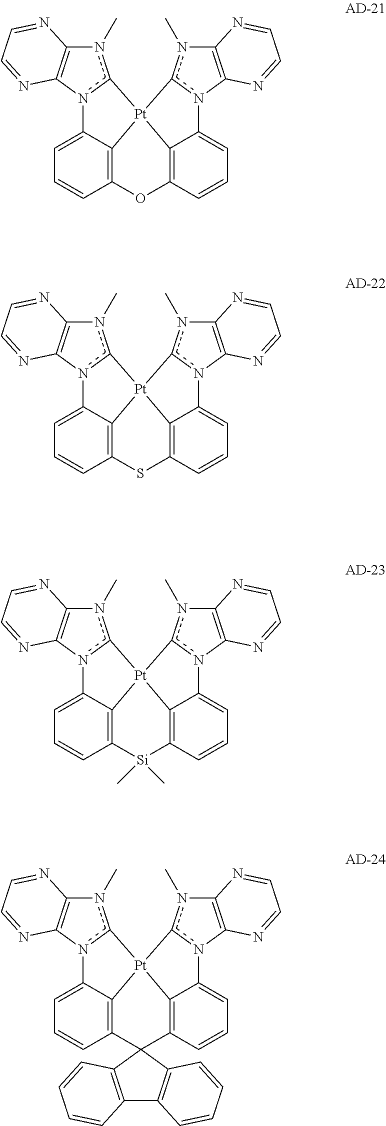

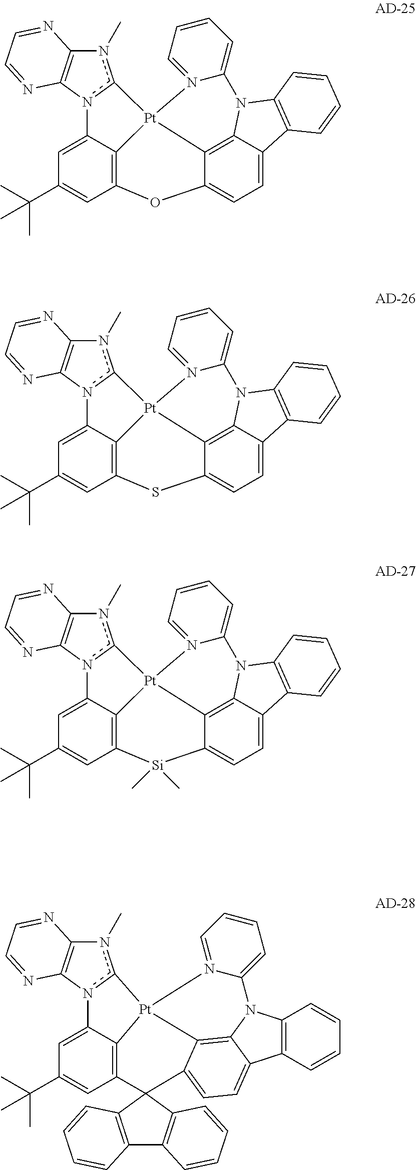

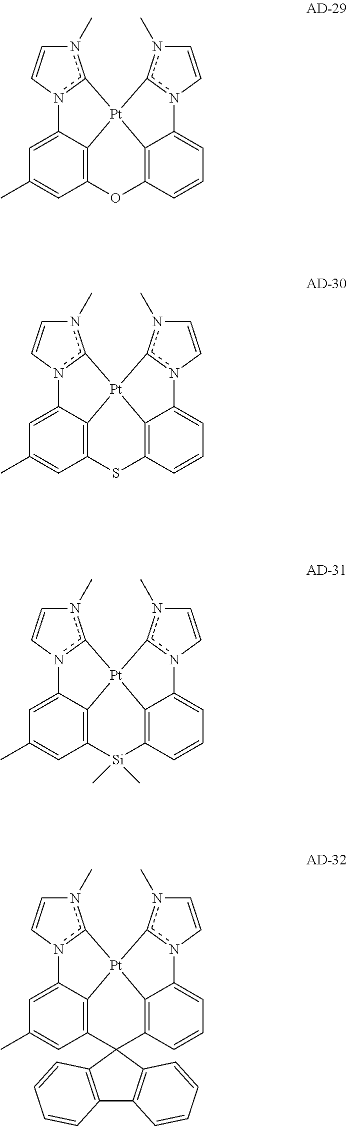

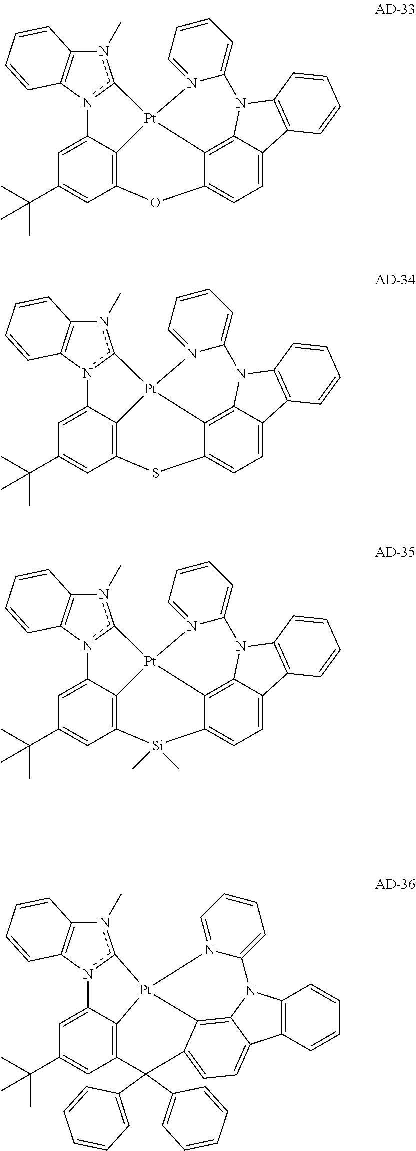

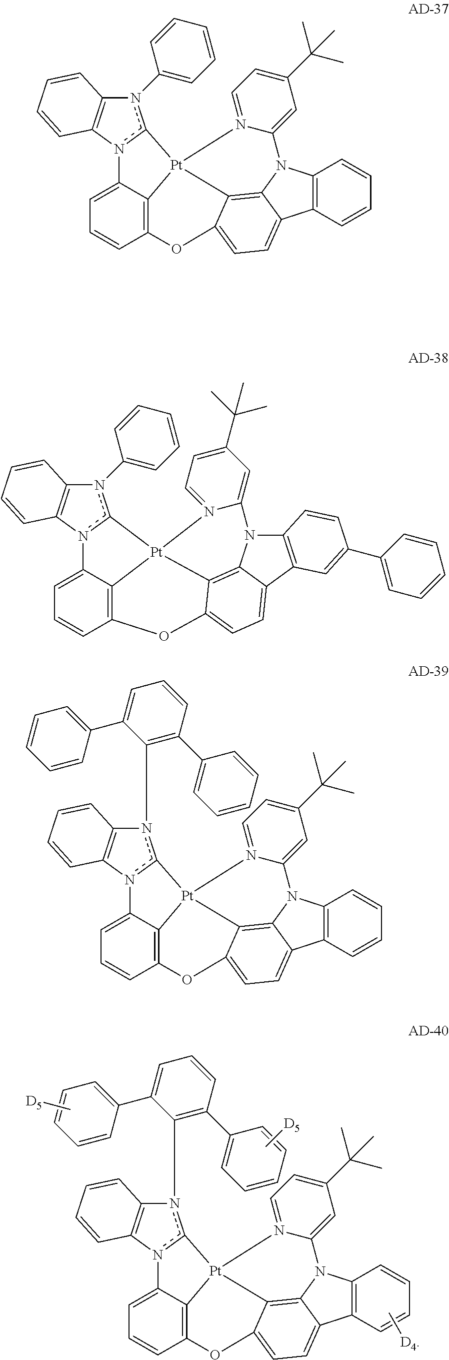

In one or more embodiments, the emission layer EML may further contain the second compound in addition to the first compound, which is a heterocyclic compound according to one or more embodiments.

The first compound and the second compound may form an exciplex. In the emission layer EML, an exciplex may be formed by a hole transporting host and an electron transporting host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, in one or more embodiments, an absolute value of the triplet energy (T1) of the exciplex formed by the hole transporting host and the electron transporting host may be about 2.4 eV to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In addition, the emission layer EML according to one or more embodiments may further contain the third compound and/or the fourth compound. For example, in one or more embodiments, the emission layer EML may include the first compound, the second compound, and the third compound. In the emission layer EML, the first compound and the second compound may form an exciplex, and energy may be transferred from the exciplex to the third compound to thereby cause light to be emitted.

In one or more embodiments, the emission layer EML may include the first compound, the second compound, the third compound, and the fourth compound. In the emission layer EML, the first compound and the second compound may form an exciplex, and energy may be transferred from the exciplex to the third compound and the fourth compound to thereby cause light to be emitted. In one or more embodiments, the fourth compound may be a sensitizer. In the light-emitting element ED according to one or more embodiments, the fourth compound contained in the emission layer EML functions as a sensitizer, and may serve to transfer energy from a host to the third compound which is an emission dopant. For example, the fourth compound that serves as an auxiliary dopant accelerates energy transfer to the third compound which is the emission dopant, and thus may increase an emission rate of the third compound. Therefore, the emission layer EML according to one or more embodiments may have improved emission efficiency. In addition, if (e.g., when) the energy transfer to the third compound increases, the exciton formed in the emission layer EML rapidly emits light without being accumulated inside the emission layer EML, and thus deterioration of the light-emitting element may decrease or be ameliorated. Therefore, the light-emitting element ED according to one or more embodiments may have an improved lifespan.

The light-emitting element ED according to one or more embodiments includes all the first compound, the second compound, the third compound, and the fourth compound, and thus the emission layer EML may include a combination of two host materials and two dopant materials. In the light-emitting element ED according to one or more embodiments, the emission layer EML may include the first compound and the second compound which are two different hosts, the third compound which emits delayed fluorescence, and the fourth compound which contains an organic metal complex, at the same time, thereby exhibiting excellent or suitable emission efficiency characteristics.

In the light emitting element ED, if (e.g., when) the light emitting layer EML includes the above-described the first compound, the second compound, and the third compound, (then) based on the total weight of the first compound, second compound, and third compound, the contents of the first compound and the second compound may be about 65 wt % to about 95 wt %.

In the total weight of the first compound and the second compound, a weight ratio of the second compound and the third compound may be about 3:7 to about 7:3. When the contents of the first compound and the second compound satisfy the above-described ratio, a charge balance characteristic in the emission layer EML are improved, and thus the luminous efficiency and device service life may increase. When the contents of the first compound and the second compound deviate from the above-described ratio range, a charge balance in the emission layer EML is broken, and thus the luminous efficiency may be reduced and the device may be easily deteriorated.

The emission layer EML may be provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

According to one or more embodiments, in the light-emitting element ED illustrated in FIG. 3 to FIG. 7, the emission layer EML may include the above-described heterocyclic compound according to one or more embodiments as a host. According to one or more embodiments, in the light-emitting element ED illustrated in FIG. 3 to FIG. 7, the emission layer EML may include the first compound which is the heterocyclic compound according to one or more embodiments, the second compound which is represented by Formula ET, and the third compound which is represented by Formula F-1. According to one or more embodiments, in the light-emitting element ED illustrated in FIG. 3 to FIG. 7, the emission layer EML may include the first compound which is the heterocyclic compound according to one or more embodiments, the second compound which is represented by Formula ET, the third compound which is represented by Formula F-1, and the fourth compound which is represented by Formula D-1.

In one or more embodiments, in the light-emitting element ED the emission layer EML may include an anthracene derivative, a pyrene derivative, a fluoranthene derivative, a chrysene derivative, a dihydrobenzanthracene derivative, or a triphenylene derivative. For example, in some embodiments, the emission layer EML may include one or more anthracene derivatives and/or one or more pyrene derivatives.

In each light-emitting element ED of embodiments illustrated in FIGS. 3 to 7, the emission layer EML may further include a suitable host and/or a suitable dopant besides the above-described host and dopant, and for example, in some embodiments, the emission layer EML may include a compound represented by Formula E-1. The compound represented by Formula E-1 may be utilized as a fluorescent host material.

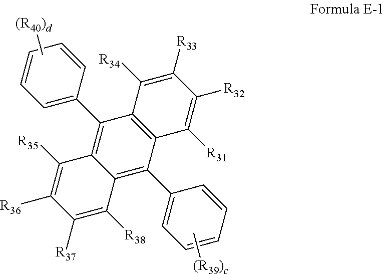

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among R₃₁ to R₄₀ may each independently be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among Compound E1 to Compound E19:

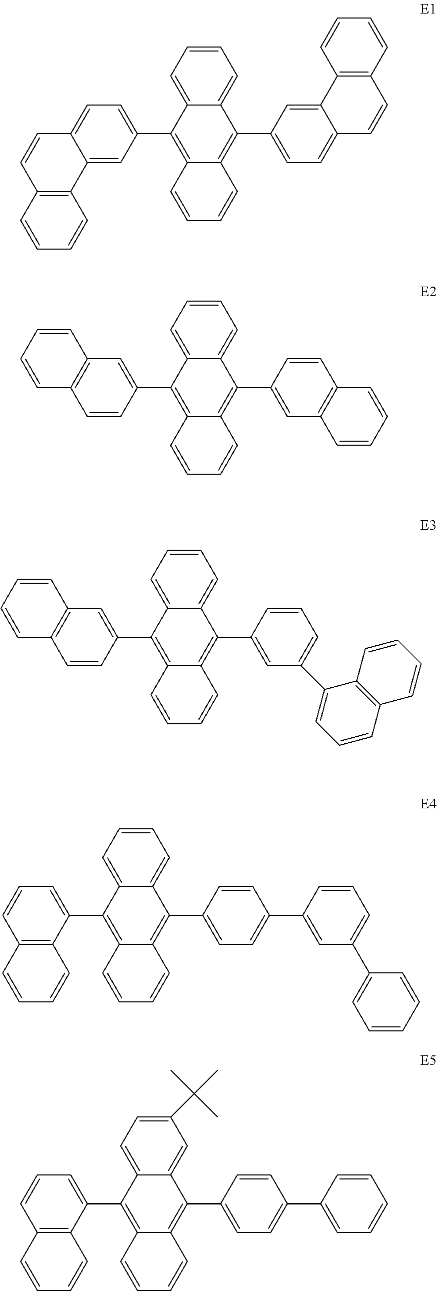

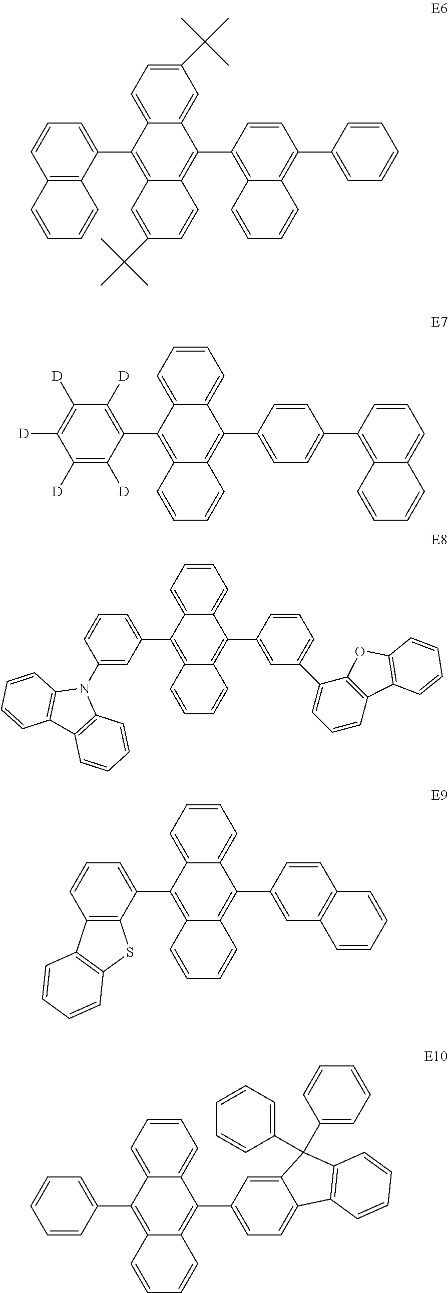

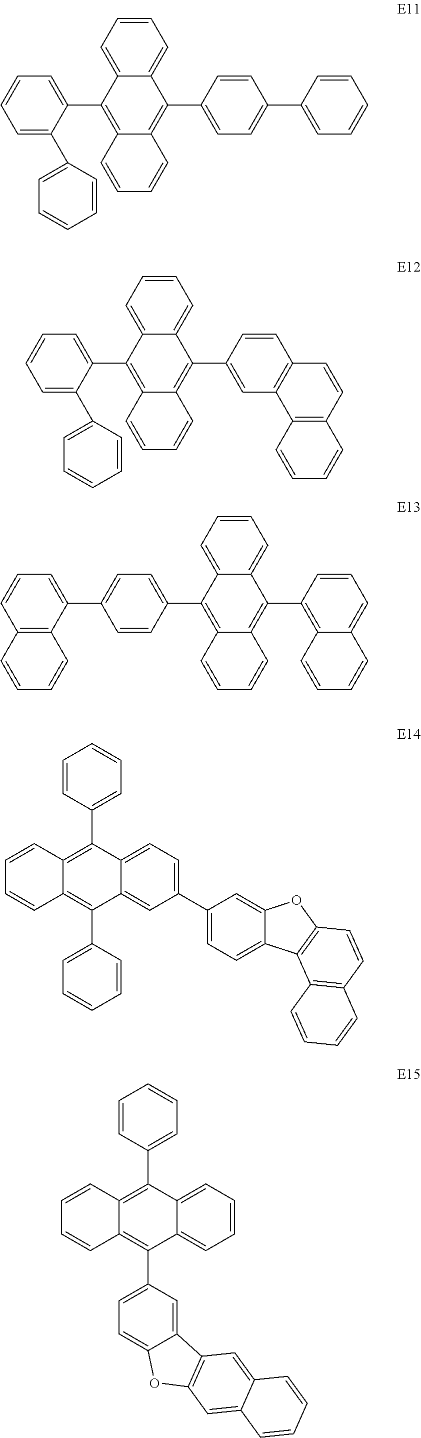

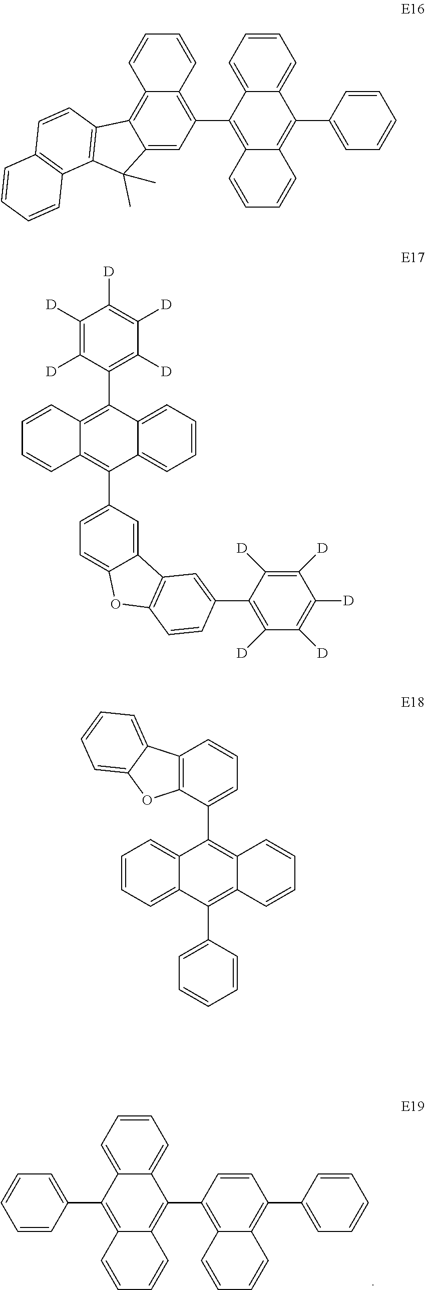

In one or more embodiments, the emission layer EML may include a compound represented by Formula E-2a or Formula E-2b. The compound represented by Formula E-2a or Formula E-2b may be utilized as a host material for a phosphorescent light-emitting element.

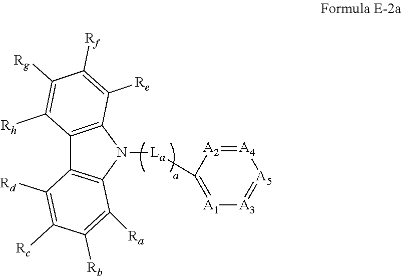

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of La's may each independently be a substituted or unsubstituted arylene group having 6 to 30 ring-forming carbon atoms or a substituted or unsubstituted heteroarylene group having 2 to 30 ring-forming carbon atoms.

In one or more embodiments, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRᵢ.

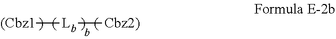

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, b may be an integer of 0 to 10, and if (e.g., when) b is an integer of 2 or more, a plurality of L_{b}'s may each independently be a substituted or unsubstituted arylene group having 6 to 30 ring-forming carbon atoms or be a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are only examples, and the compound represented by Formula E-2a or Formula E-2b is not limited to those represented in Compound Group E-2.

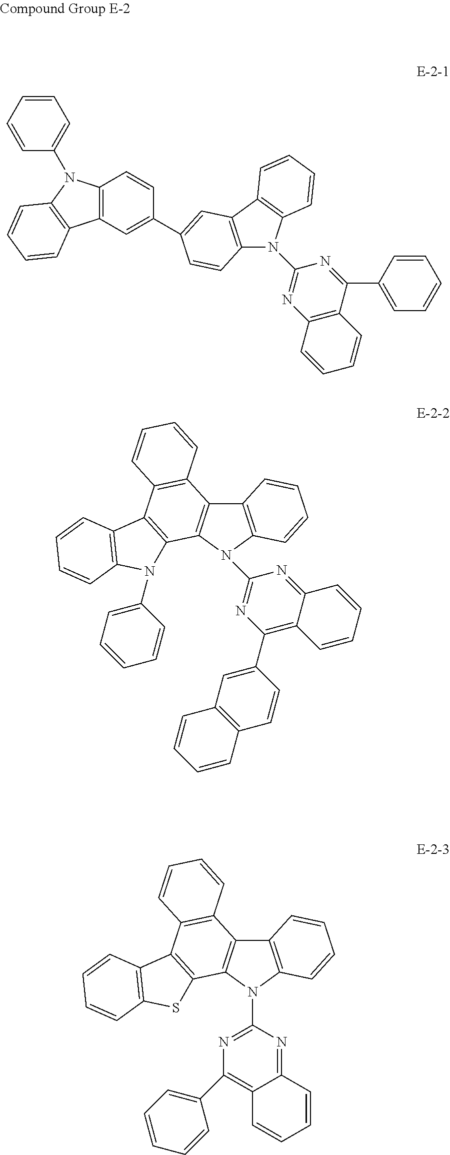 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

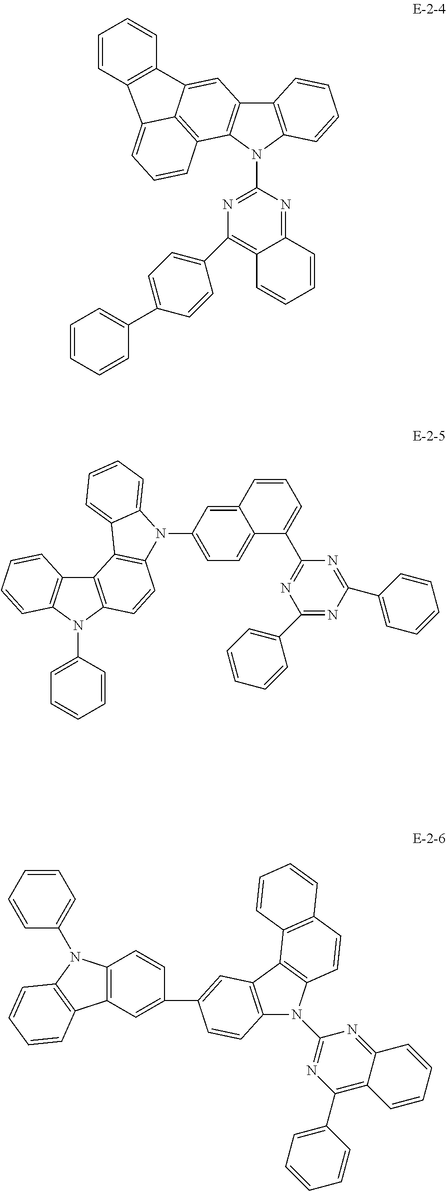 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

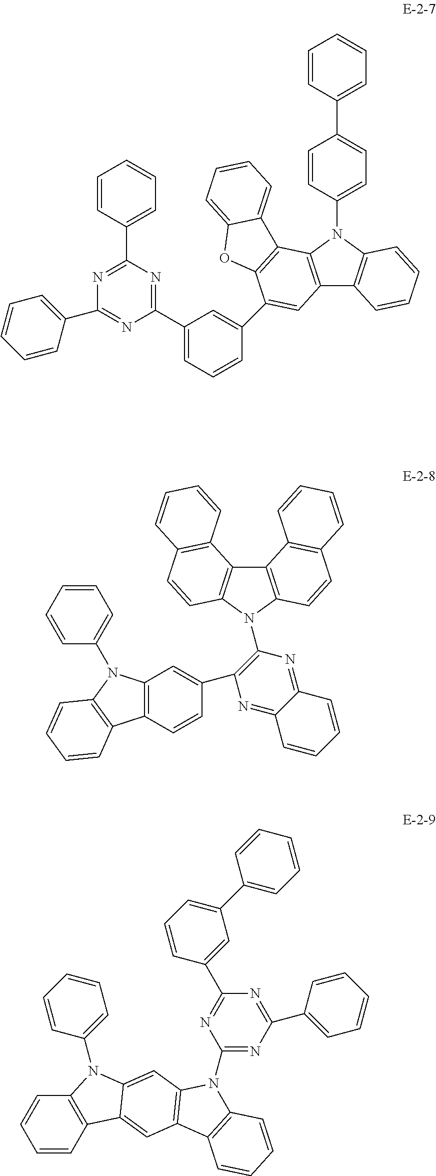 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

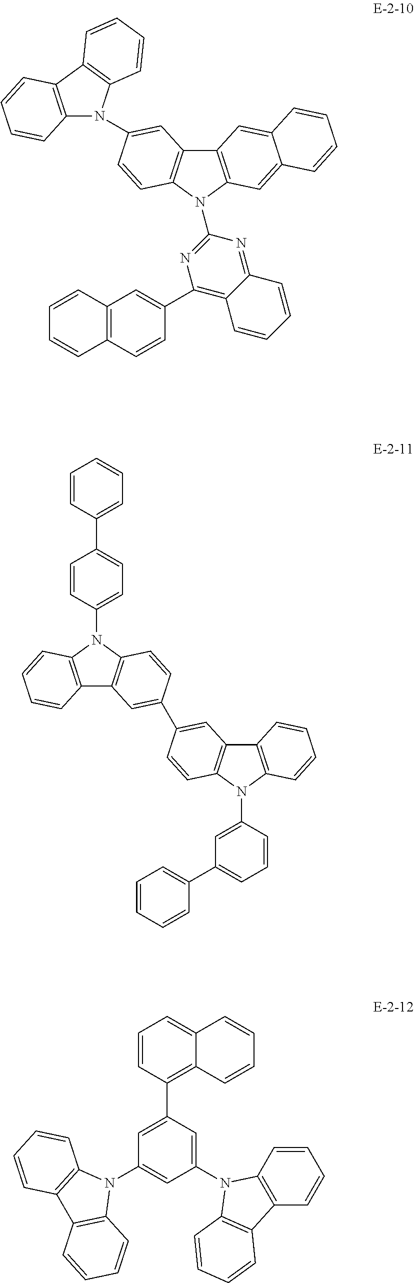 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

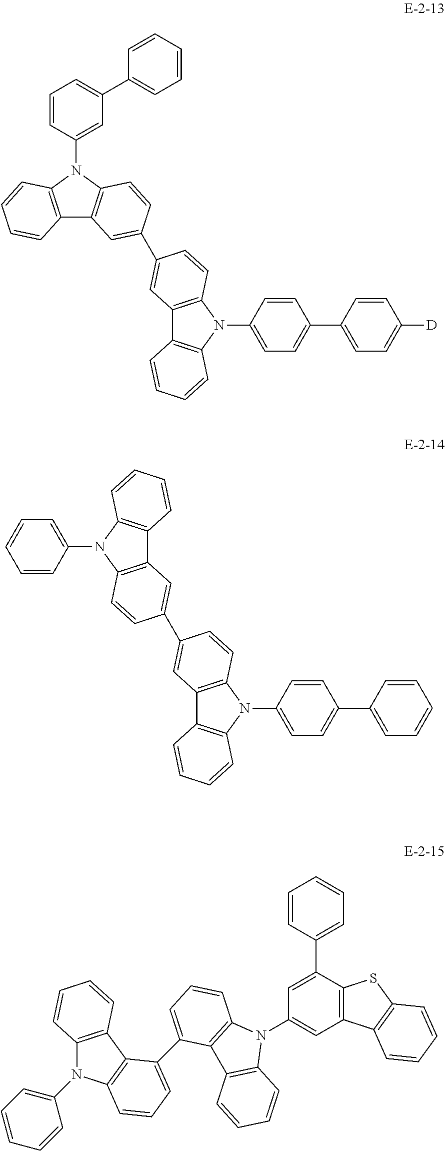 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

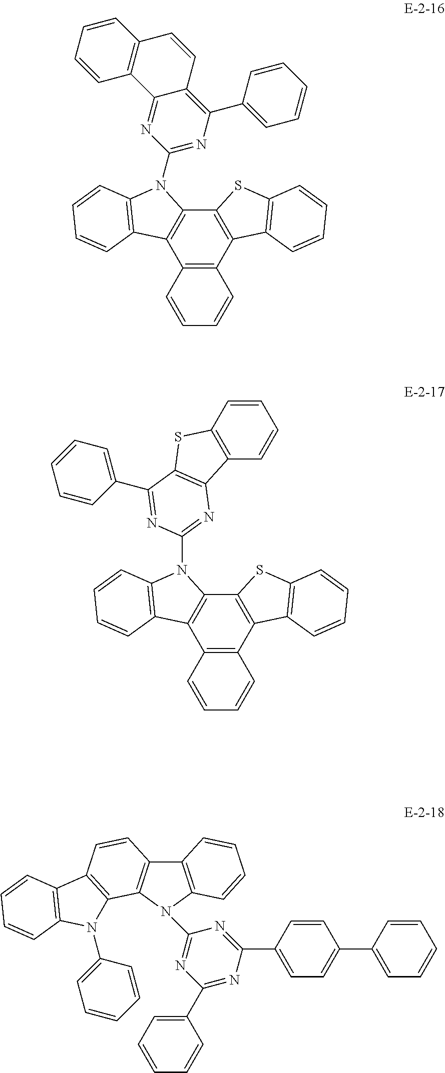 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

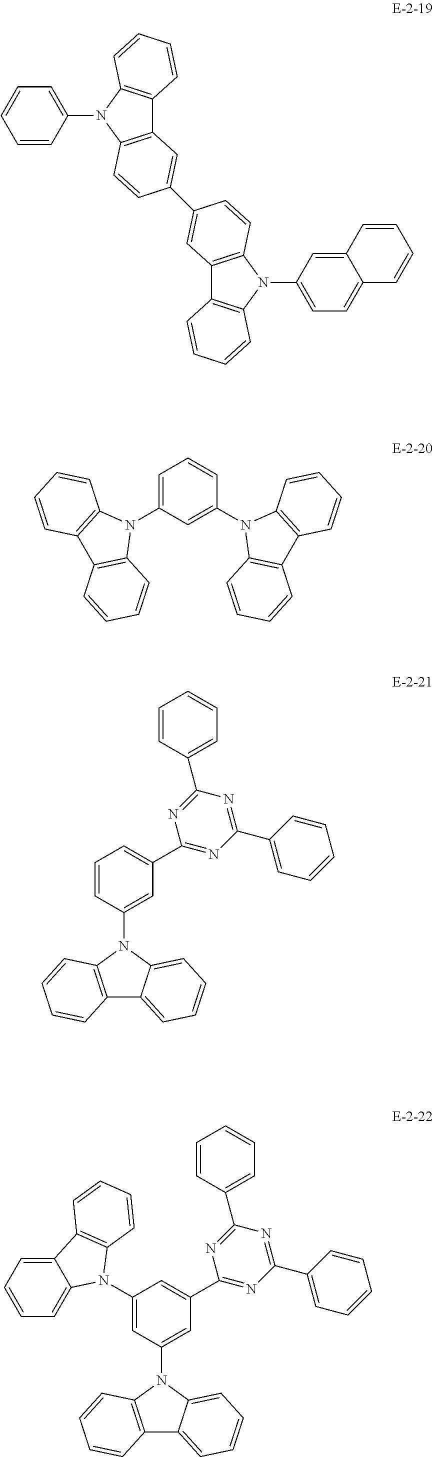 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

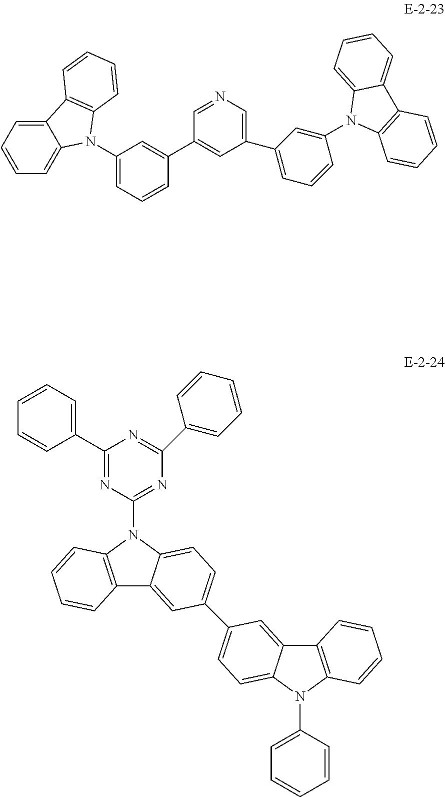 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may include a compound represented by Formula M-a. The compound represented by Formula M-a may be utilized as a phosphorescent dopant material.

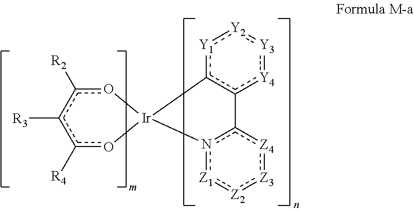

In Formula M-a, Y₁ to Y₄ and Z₁ to Z₄ may each independently be CR₁ or N, R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be utilized as a phosphorescent dopant.

The compound represented by Formula M-a may be any one selected from among Compound M-a1 to Compound M-a25. However, Compounds M-a1 to M-a25 are mere examples, and the compound represented by Formula M-a is not limited to those represented by Compounds M-a1 to M-a25.

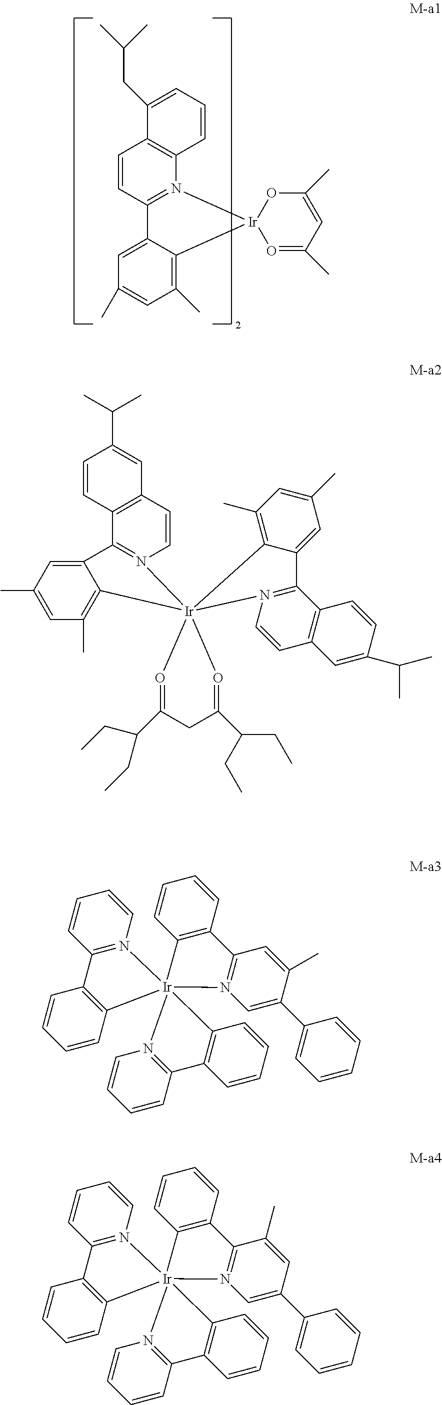

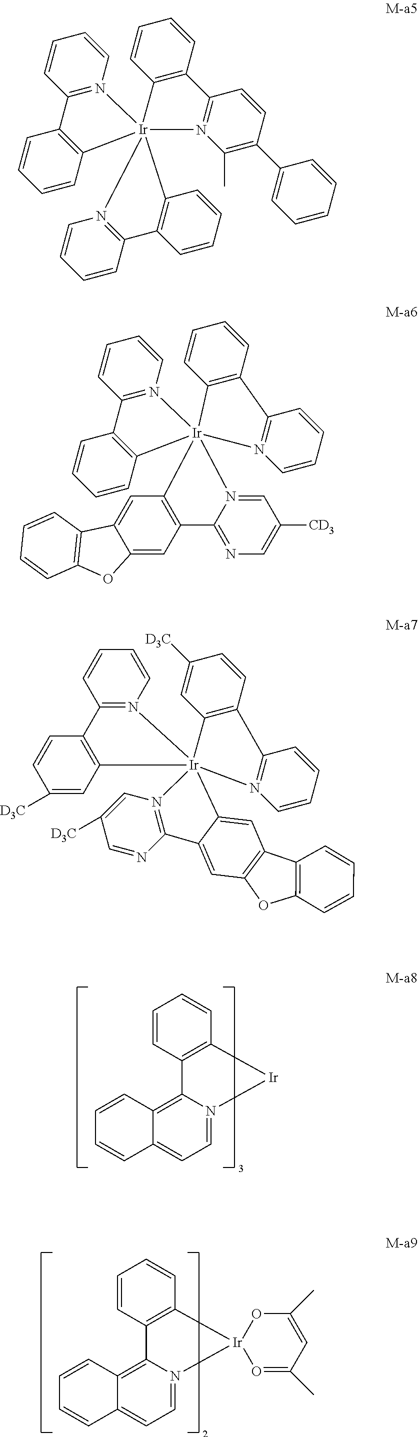

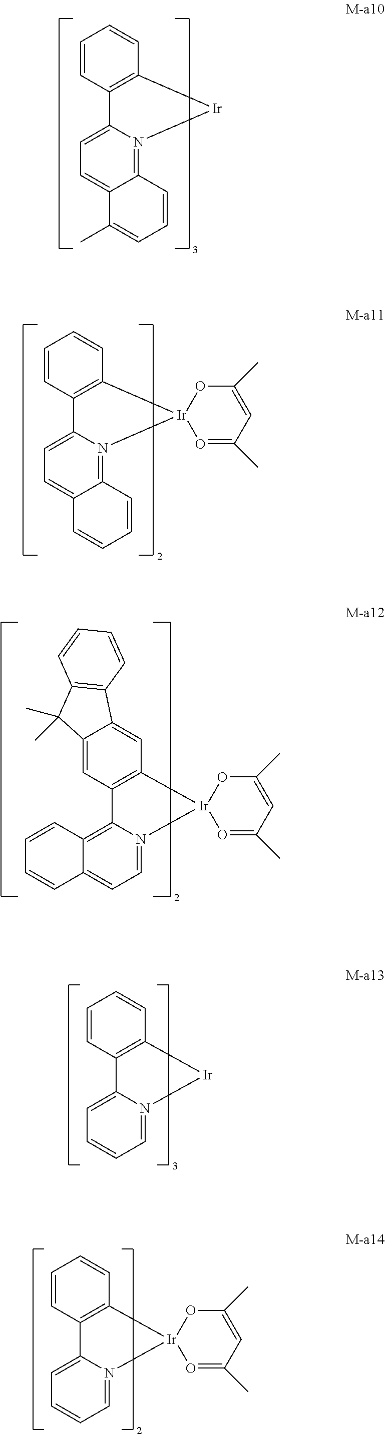

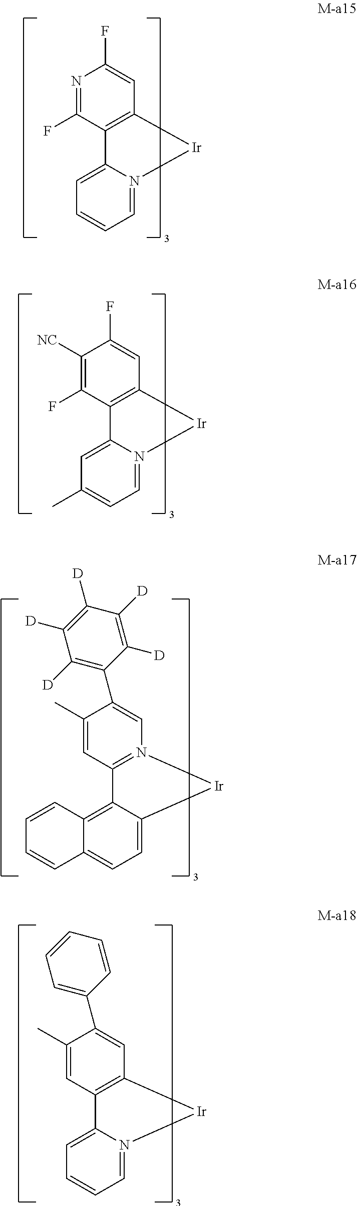

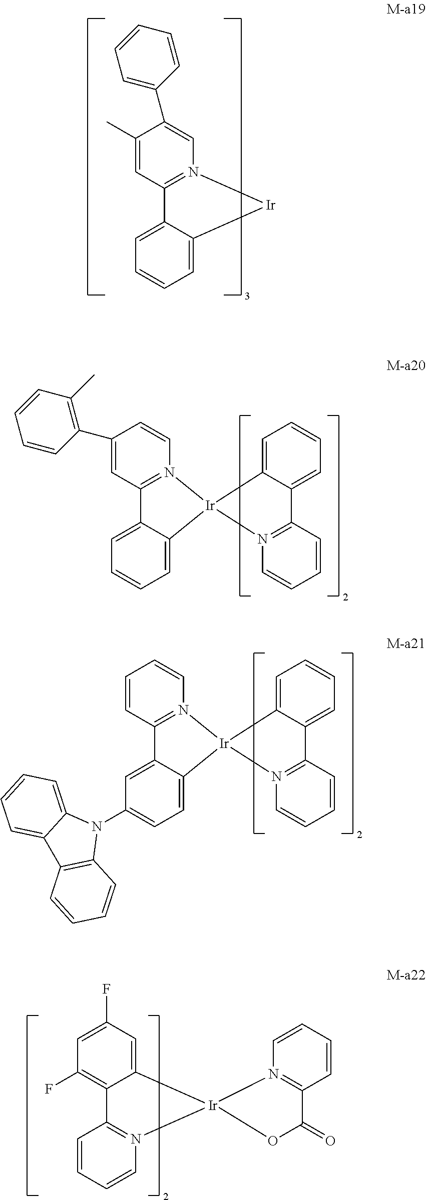

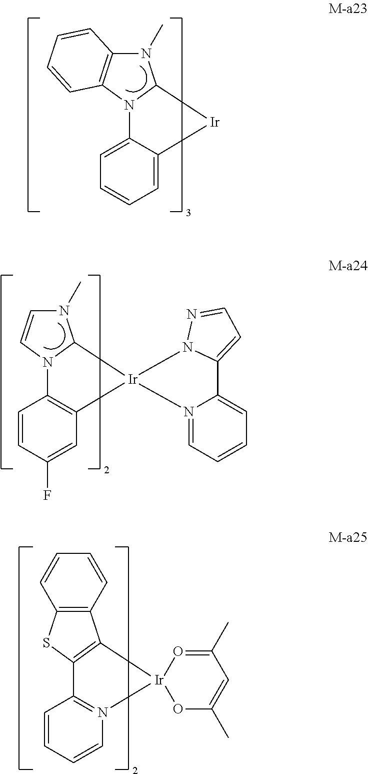

In one or more embodiments, the emission layer EML may include a compound represented by any one selected from among Formula F-a and Formula F-b. The compound represented by Formula F-a or Formula F-b may be utilized as a fluorescence dopant material.

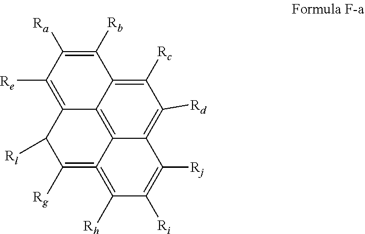

In Formula F-a, two selected from among Rₐ to Rⱼ may each independently be substituted with *—NAr₁Ar₂. The others, which are not substituted with *—NAr₁Ar₂, among Rₐ to Rⱼ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in some embodiments, at least one of Ar₁ or Ar₂ may be a heteroaryl group containing O or S as a ring-forming atom.

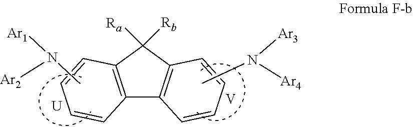

In Formula F-b, Rₐ and Rb may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In one or more embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a part of a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring in Formula F-b may be a cyclic compound having three rings. In one or more embodiments, if (e.g., when) each number of U and V is 1, the fused ring having a fluorene core in Formula F-b may be a cyclic compound having five rings.

In one or more embodiments, the emission layer EML may further include, as a suitable dopant material, one or more selected from among styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and/or the like.

In one or more embodiments, the emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium(III) bis(4,6-difluorophenylpyridinato-N,C2) (Flrpic), bis(2,4-difluorophenylpyridinato)-tetrakis(1-pyrazolyl)borate iridium(III) (Fir6), or platinum octaethyl porphyrin (PtOEP) may be utilized as a phosphorescent dopant. However, embodiments of the disclosure are not limited thereto.

In one or more embodiments, the emission layer EML may include a quantum dot material. In one or more embodiments, the quantum dot material may have a core/shell structure. The core of the quantum dot may be selected from among a Group II-VI compound, a Group III-VI compound, a Group 1-III-IV compound, a Group III-V compound, a Group III-II-V compound, a Group IV-VI compound, a Group IV element, a Group IV compound, and/or a (e.g., any suitable) combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a (e.g., any suitable) mixture (e.g., combination) thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a (e.g., any suitable) mixture thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a (e.g., any suitable) mixture thereof, and a (e.g., any suitable) mixture thereof.

The Group III-VI compound may include a binary compound such as In₂S₃ and/or In₂Se3, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a (e.g., any suitable) mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a (e.g., any suitable) mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a (e.g., any suitable) mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a (e.g., any suitable) mixture thereof, and a (e.g., any suitable) mixture thereof. In one or more embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a (e.g., any suitable) mixture thereof, a ternary compound selected from the group consisting of SnSeS, SnSeTe, SnSTe, PbSeS, PbSeTe, PbSTe, SnPbS, SnPbSe, SnPbTe, a (e.g., any suitable) mixture thereof, and a quaternary compound selected from the group consisting of SnPbSSe, SnPbSeTe, SnPbSTe, and a (e.g., any suitable) mixture thereof, and a (e.g., any suitable) mixture thereof. The Group IV element may be selected from the group consisting of Si, Ge, and a (e.g., any suitable) mixture thereof. The Group IV compound may be a binary compound selected from the group consisting of SiC, SiGe, and a (e.g., any suitable) mixture thereof.

Each element included in a polynary compound such as the binary compound, the ternary compound, or the quaternary compound may be present in a particle with a substantially uniform or non-uniform concentration distribution. For example, the formulae refer to the types (kinds) of elements included in the compounds, and elemental ratios in the compound may be different. For example, AgInGaS₂ may refer to AgInₓGa₁₋ₓS₂ (where x is a real number of 0 to 1).

In one or more embodiments, the quantum dot may have a single structure or a double structure of core-shell in which the concentration of each element included in the quantum dot is substantially uniform. For example, a material included in the core may be different from a material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

In one or more embodiments, the shell of the quantum dots may include a metal or non-metal oxide, a semiconductor compound, and/or a (e.g., any suitable) combination thereof. For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but embodiments of the disclosure are not limited thereto.

Also, examples of the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the disclosure are not limited thereto.

Each element included in a polynary compound such as the binary compound or the ternary compound may be present in a particle with a substantially uniform or non-uniform concentration distribution. For example, the formulae refer to the types (kinds) of elements included in the compounds, and elemental ratios in the compound may be different.

The quantum dot may have a full width at half maximum (FWHM) of an emission spectrum of about 45 nm or less, about 40 nm or less, or about 30 nm or less, and the color purity or color reproducibility of the quantum dot may be improved in the above range. In addition, light emitted through such quantum dot is emitted in all directions so that a wide viewing angle may be improved.

In one or more embodiments, although the form of the quantum dot is not particularly limited as long as it is a form commonly utilized in the art, in some embodiments, the quantum dot in the form of spherical nanoparticles, pyramidal nanoparticles, multi-arm nanoparticles, or cubic nanoparticles, nanotubes, nanowires, nanofibers, nanoplate particles, or the like, may be utilized.

As the size of the quantum dot is adjusted or the elemental ratio in the quantum dot compound is adjusted, it may control the energy band gap, and thus light in one or more suitable wavelength ranges may be obtained in a quantum dot emission layer. Therefore, the quantum dots as described above (utilizing different sizes of quantum dots or different elemental ratios in the quantum dot compound) may be utilized, and thus the light-emitting element, which emits light in one or more suitable wavelengths, may be implemented. For example, the adjustment of the size of the quantum dot or the elemental ratio in the quantum dot compound may enable the quantum dots to emit red, green, and/or blue light. In one or more embodiments, the quantum dots may be configured to emit white light by combining one or more suitable colors of light.

In each of the light-emitting elements ED of embodiments illustrated in FIGS. 3 to 7, the electron transport region ETR may be provided on the emission layer EML. The electron transport region ETR may include at least one of a hole blocking layer HBL, an electron transport layer ETL, or an electron injection layer EIL, but embodiments of the disclosure are not limited thereto.

The electron transport region ETR may have a single layer formed of a single material, a single layer formed of a plurality of different materials, or a multilayer structure including a plurality of layers formed of a plurality of different materials.

For example, in one or more embodiments, the electron transport region ETR may have a single layer structure of an electron injection layer EIL or an electron transport layer ETL, or may have a single layer structure formed of an electron injection material and an electron transport material. In one or more embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order (e.g., in the stated order) from the emission layer EML, but embodiments of the disclosure are not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The electron transport region ETR may include a compound represented by Formula ET-1.

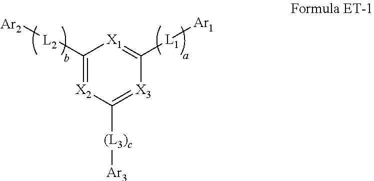

In Formula ET-1, at least one selected from among X₁ to X₃ may be N, and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of (e.g., selected from among) 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c may each independently be an integer of 2 or more, L₁(s) to L₃(s) may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the disclosure are not limited thereto, for example, in some embodiments, the electron transport region ETR may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N 1,O8)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), and/or a (e.g., any suitable) mixture thereof.

In one or more embodiments, the electron transport region ETR may include at least one selected from among Compound ET1 to Compound ET36:

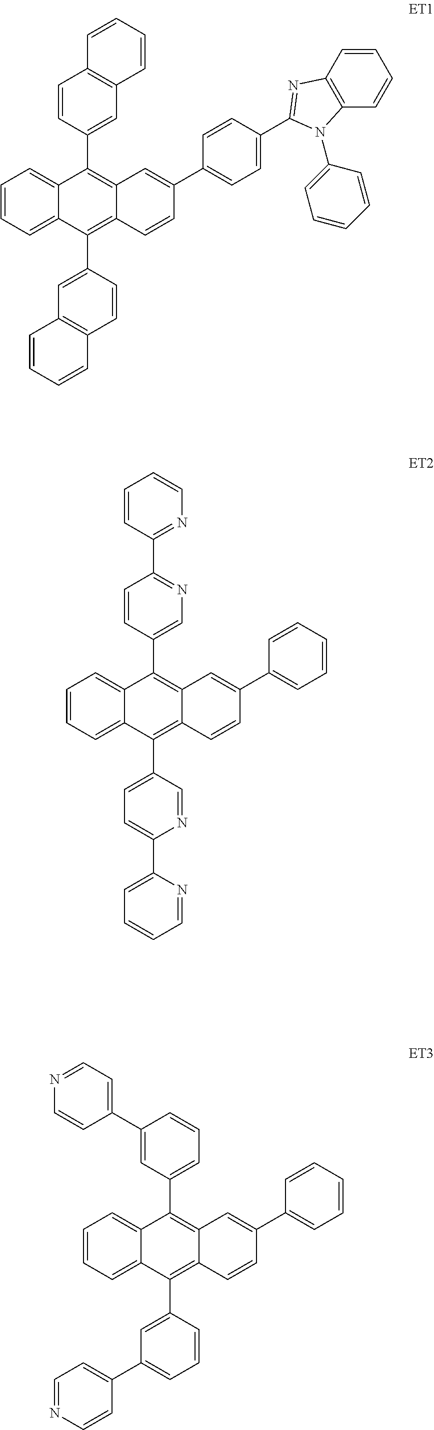 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

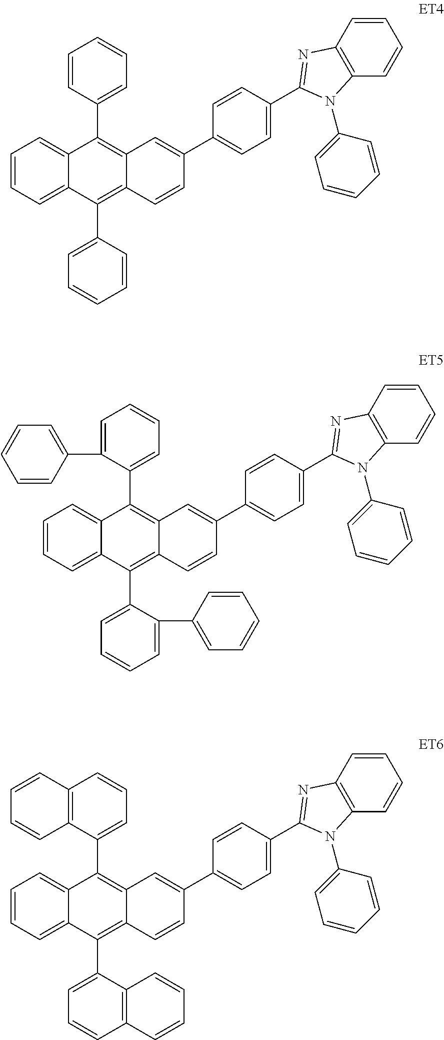 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

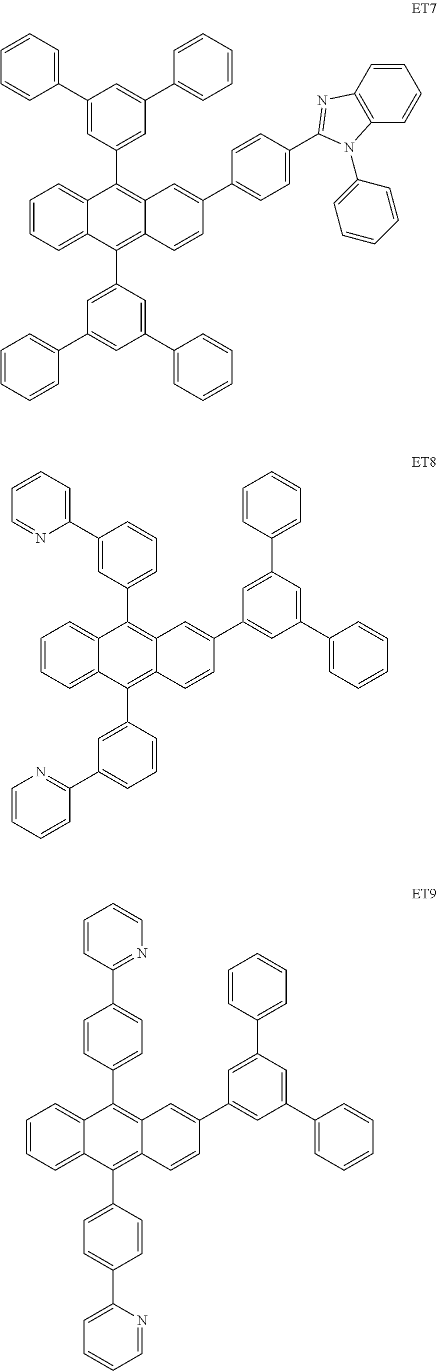 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

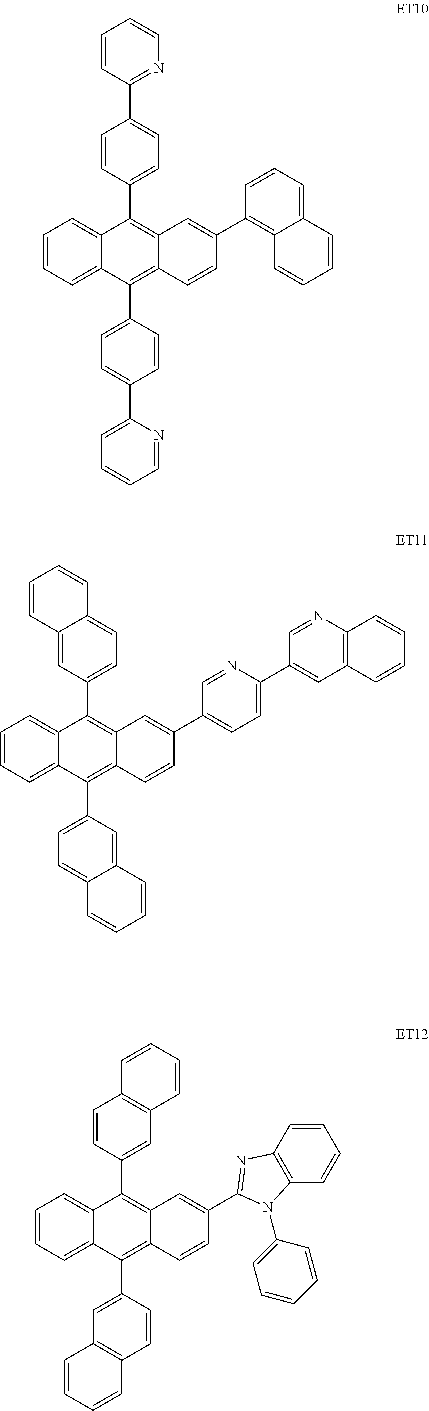 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

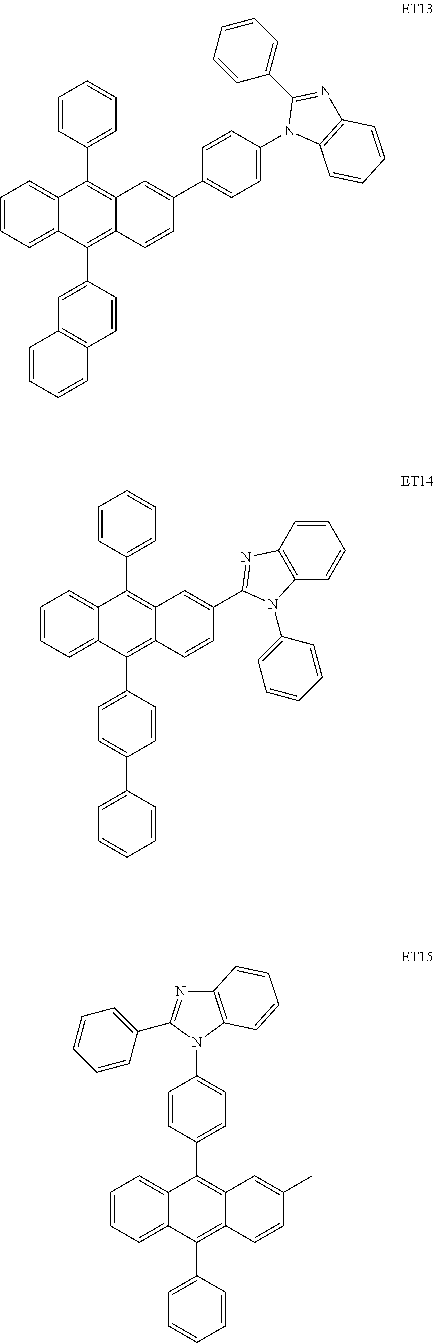 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

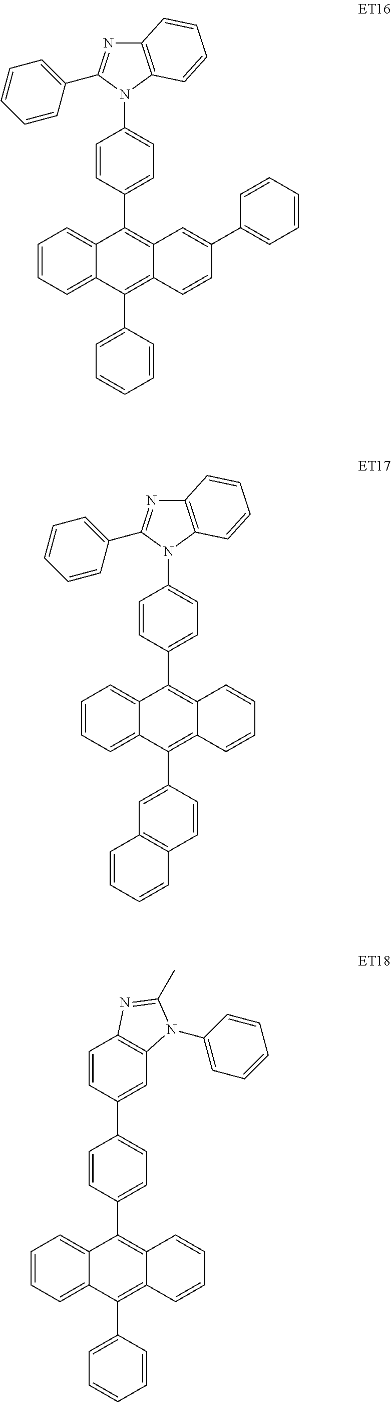 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

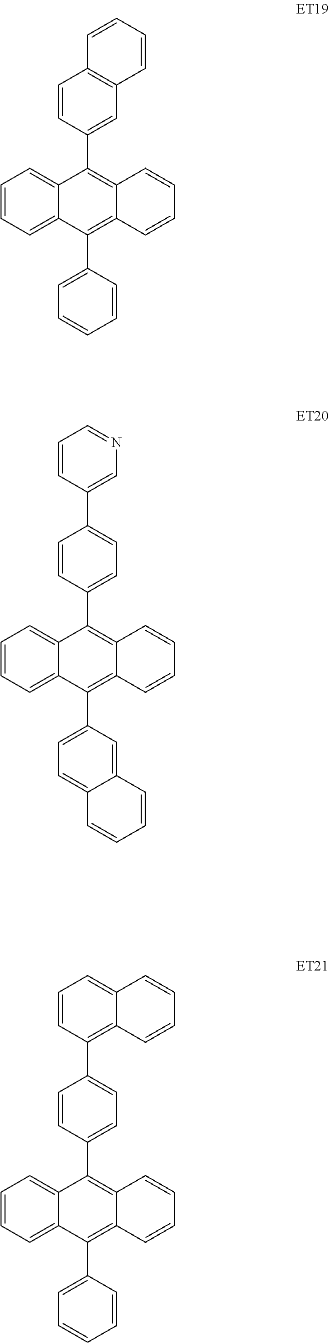

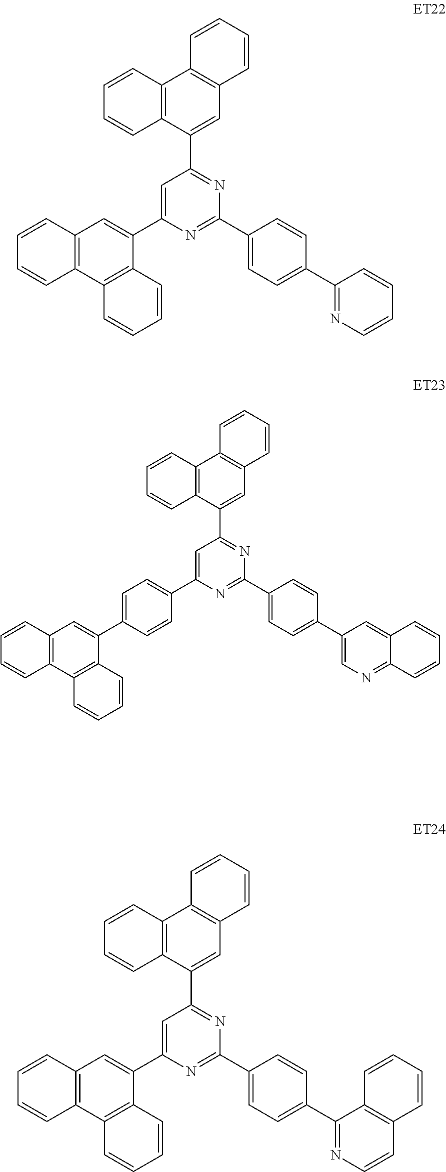 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

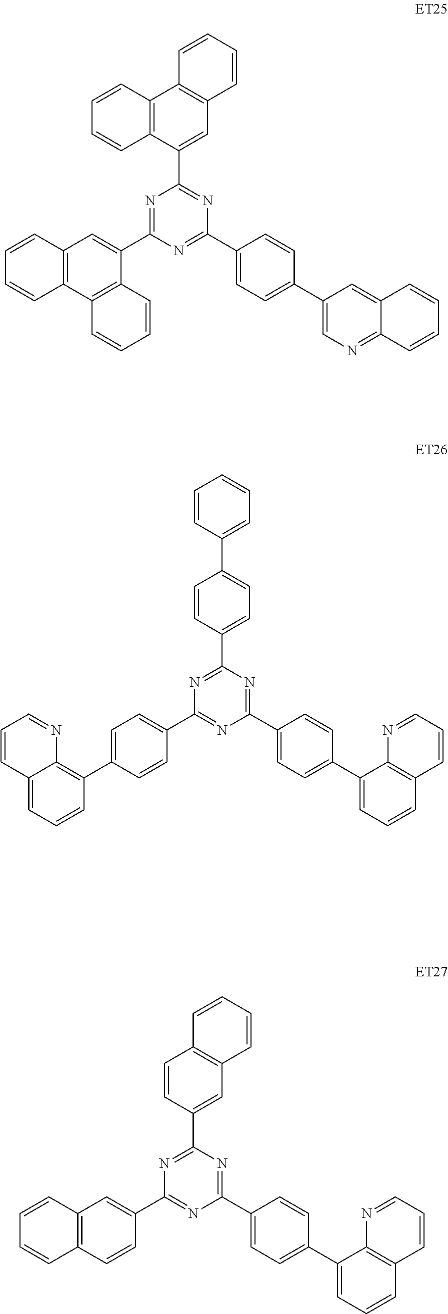 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

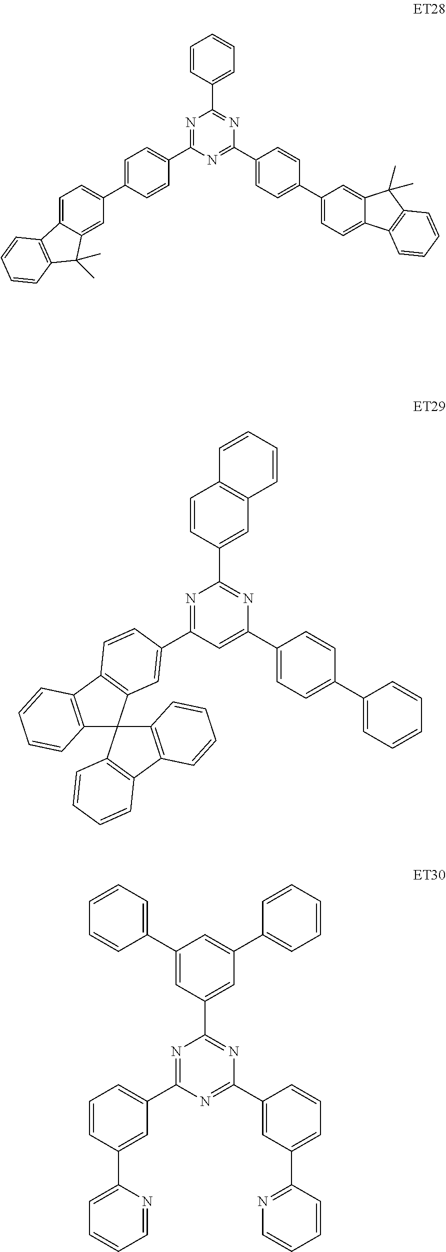 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

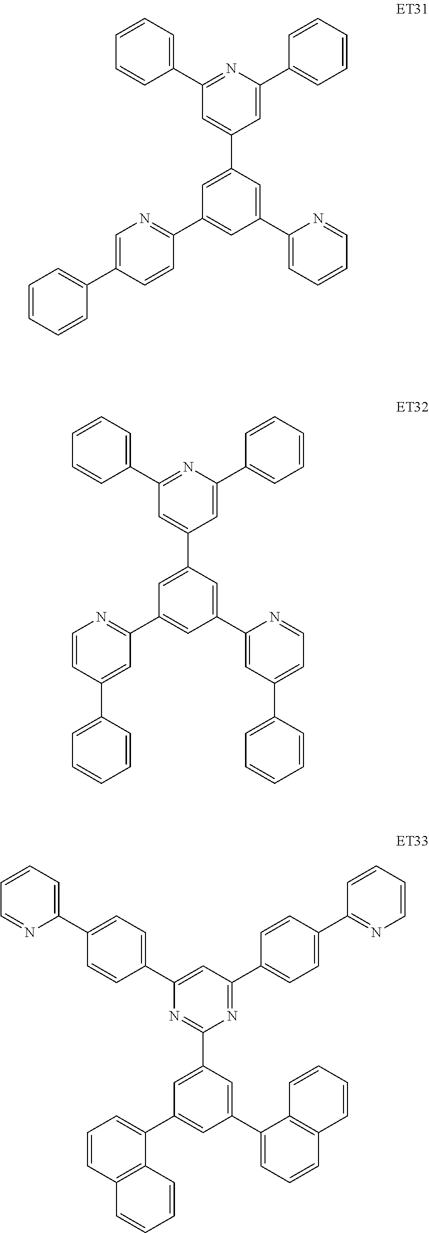 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

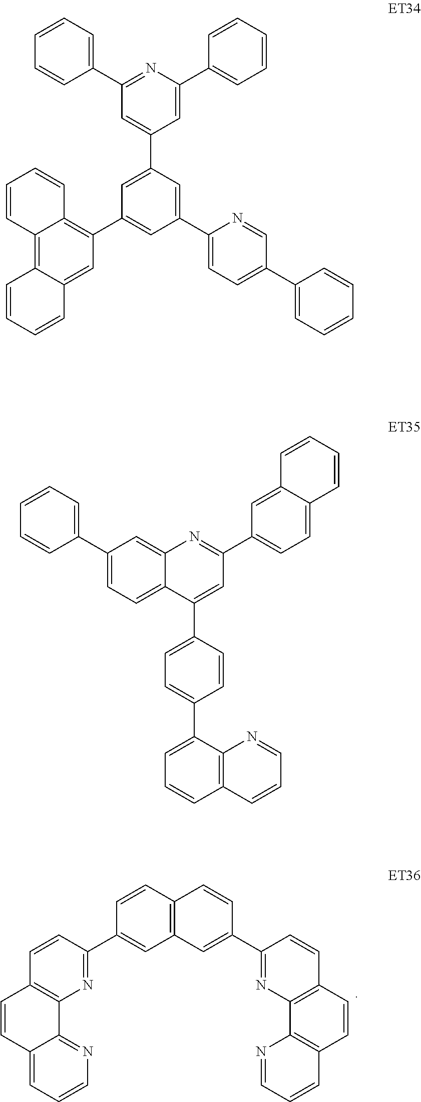 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include a metal halide such as LiF, NaCl, CsF, RbCI, RbCl, CuI, and/or KI, a lanthanide metal such as Yb, or a co-deposited material of the metal halide and the lanthanide metal. For example, in one or more embodiments, the electron transport region ETR may include KI:Yb, RbI:Yb, LiF:Yb, and/or the like, as a co-deposited material. In one or more embodiments, the electron transport region ETR may be formed utilizing a metal oxide such as Li₂O and/or BaO, or 8-hydroxyl-lithium quinolate (Liq), and/or the like, but embodiments of the disclosure are not limited thereto. In one or more embodiments, the electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the above-described materials, but embodiments of the disclosure are not limited thereto.

The electron transport region ETR may include one or more of the above-described compounds of the electron transport region in at least one of an electron injection layer EIL, an electron transport layer ETL, or a hole blocking layer HBL.

When the electron transport region ETR includes an electron transport layer ETL, the electron transport layer ETL may have a thickness of about 100 Å to about 1,000 Å, for example, about 150 Å to about 500 Å. If the thickness of the electron transport layer ETL satisfies the aforementioned range, satisfactory electron transport characteristics may be obtained without a substantial increase in driving voltage. When the electron transport region ETR includes an electron injection layer EIL, the electron injection layer EIL may have a thickness of about 1 Å to about 100 Å, for example, about 3 Å to about 90 Å. If the thickness of the electron injection layer EIL satisfies the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments of the disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, a compound thereof, or a mixture thereof (e.g., AgMg, AgYb, or MgYb). In one or more embodiments, the second electrode EL2 may have a multilayer structure including a reflective film or a transflective film formed of one or more selected from among the above-described materials, and a transparent conductive film formed of ITO, IZO, ZnO, ITZO, and/or the like. For example, the second electrode EL2 may include one of the above-described metal materials, one or more combinations of at least two metal materials selected from among the above-described metal materials, one or more oxides of the above-described metal materials, and/or the like.

In one or more embodiments, the second electrode EL2 may be connected with an auxiliary electrode. If the second electrode EL2 is connected with the auxiliary electrode, the resistance of the second electrode EL2 may be decreased.

In one or more embodiments, a capping layer CPL may further be arranged on the second electrode EL2 of the light-emitting element ED. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), SiON, SiNₓ, SiO_{y}, and/or the like.

For example, in some embodiments, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, embodiments of the disclosure are not limited thereto, for example, in one or more embodiments, the capping layer CPL may include at least one selected from among Compounds P1 to P5:

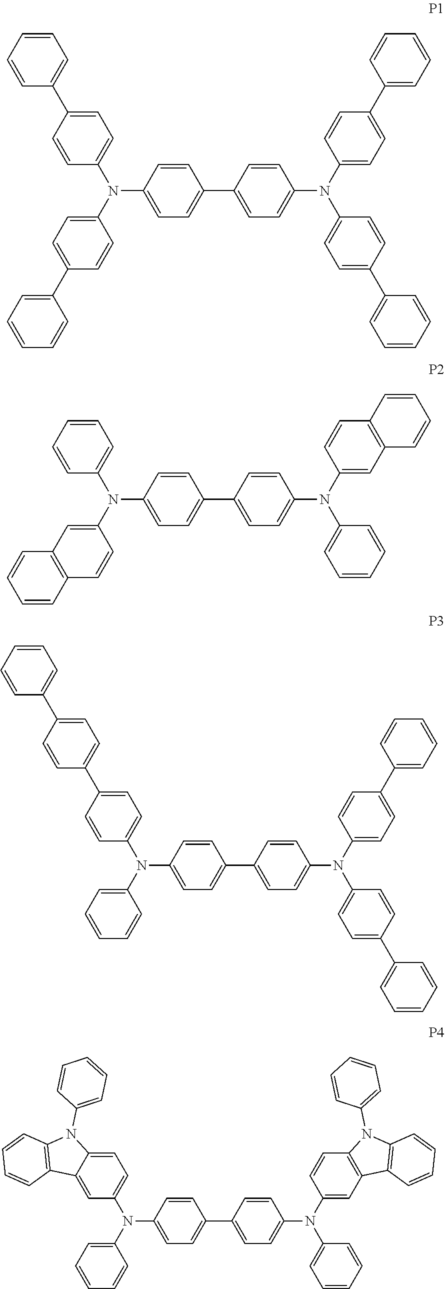 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

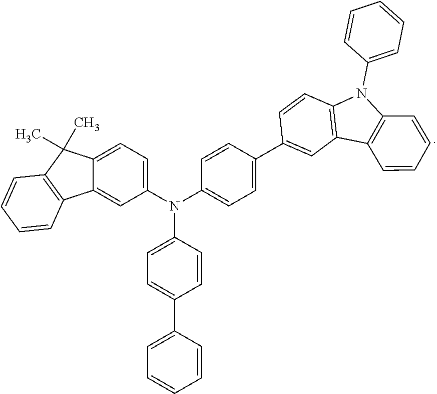 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, in one or more embodiments, the refractive index of the capping layer CPL may be about 1.6 or more with respect to light in a wavelength range of about 550 nm to about 660 nm.

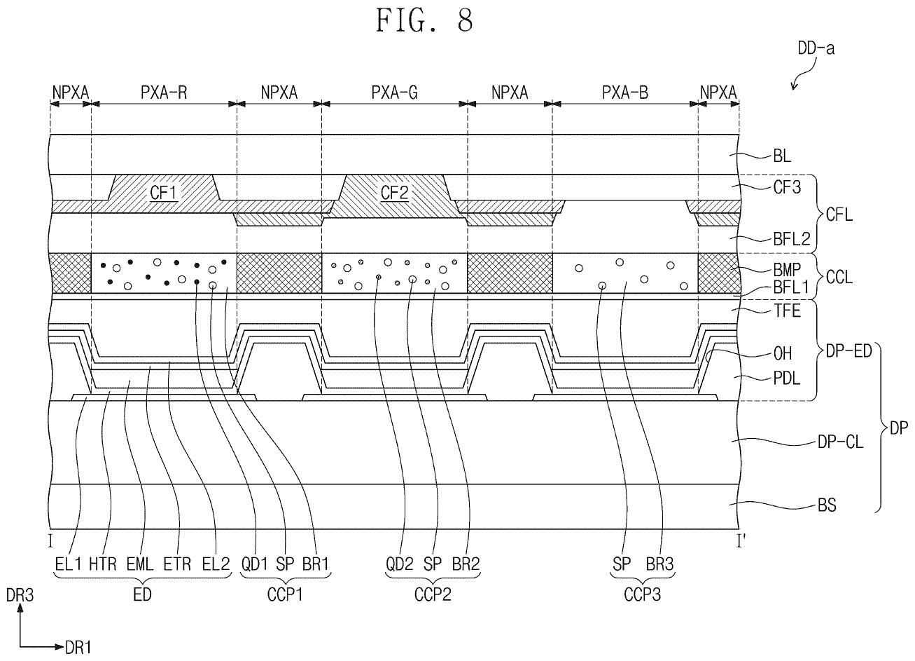

Each of FIGS. 8 to 11 is a cross-sectional view of a display device according to one or more embodiments of the disclosure. Hereinafter, in describing the display devices of embodiments with reference to FIGS. 8 to 11, the duplicated features which have been described in FIGS. 1 to 7 are not described again for conciseness, only their differences will be mainly described.

Referring to FIG. 8, the display device DD-a according to one or more embodiments may include a display panel DP including a display device layer DP-ED, a light control layer CCL arranged on the display panel DP, and a color filter layer CFL. In one or more embodiments illustrated in FIG. 8, the display panel DP may include a base layer BS, a circuit layer DP-CL provided on the base layer BS, and the display device layer DP-ED, and the display device layer DP-ED may include a light-emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the structure of any one of the light-emitting elements of FIGS. 3 to 7 as described above may be equally applied to the structure of the light-emitting element ED illustrated in FIG. 8. The light emitting element ED shown in FIG. 8 may include a heterocyclic compound according to example embodiments. Accordingly, the light emitting element ED may exhibit improved luminous efficiency and low driving voltage characteristics. Additionally, the light emitting element ED emits deep blue light and may exhibit excellent or suitable light conversion efficiency.

Referring to FIG. 8, the emission layer EML may be arranged in an opening OH defined in a pixel defining film PDL. For example, the emission layer EML which is divided by the pixel defining film PDL and provided corresponding to each of light emitting regions PXA-R, PXA-G, and PXA-B may be to emit light in substantially the same wavelength range. In the display device DD-a of one or more embodiments, the emission layer EML may be to emit blue light. In one or more embodiments, unlike the configuration illustrated, the emission layer EML may be provided as a common layer in the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing a quantum dot or a layer containing a phosphor.

The light control layer CCL may include a plurality of light control parts CCP1, CCP2, and CCP3. The light control parts CCP1, CCP2, and CCP3 may be spaced and/or apart (e.g., spaced apart or separated) from each other.

Referring to FIG. 8, divided patterns BMP may be arranged between the light control parts CCP1, CCP2, and CCP3 which are spaced and/or apart (e.g., spaced apart or separated) from each other, but embodiments of the disclosure are not limited thereto. FIG. 8 illustrates that the divided patterns BMP do not overlap the light control parts CCP1, CCP2, and CCP3, but, in some embodiments, at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light-emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light-emitting element ED. For example, the first quantum dot QD1 may be a red quantum dot to emit red light, and the second quantum dot QD2 may be a green quantum dot to emit green light. The same as described above on quantum dots may be applied with respect to the quantum dots QD1 and QD2.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. In one or more embodiments, the scatterer SP may include at least one or may be any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may respectively include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may each independently be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

In one or more embodiments, the light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2, and CCP3 from being exposed to moisture/oxygen. In one or more embodiments, the barrier layer BFL1 may cover the light control parts CCP1, CCP2, and CCP3. In one or more embodiments, a barrier layer BFL2 may be provided between the light control parts CCP1, CCP2, and CCP3 and the color filter layer CFL.

The barrier layers BFL1 and BFL2 may include at least one inorganic layer. For example, in some embodiments, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may further include an organic film. The barrier layers BFL1 and BFL2 may be formed of a single layer or a plurality of layers.

In the display device DD-a of one or more embodiments, the color filter layer CFL may be arranged on the light control layer CCL. For example, in one or more embodiments, the color filter layer CFL may be directly arranged on the light control layer CCL. In these embodiments, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, in one or more embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. The first filter CF1 may include a red pigment and/or a red dye, the second filter CF2 may include a green pigment and/or a green dye, and the third filter CF3 may include a blue pigment and/or a blue dye.

In one or more embodiments, the third filter CF3 may not include (e.g., may exclude) a (e.g., any) pigment and/or dye. The third filter CF3 may include a polymeric photosensitive resin and may not include (e.g., may exclude) a (e.g., any) pigment and/or dye. The third filter CF3 may be transparent. The third filter CF3 may be formed of a transparent photosensitive resin.

Furthermore, in one or more embodiments, the first filter CF1 and the second filter CF2 may each be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment and/or a black dye. The light shielding part may prevent or reduce light leakage, and may separate boundaries between the adjacent filters CF1, CF2, and CF3. Optionally, the light shielding part may be formed of a blue filter.

The first to third filters CF1, CF2, and CF3 may be arranged corresponding to the red light emitting region PXA-R, the green light emitting region PXA-G, and the blue light emitting region PXA-B, respectively.

In one or more embodiments, a base substrate BL may be arranged on the color filter layer CFL. The base substrate BL may be a member which provides a base surface on which the color filter layer CFL, the light control layer CCL, and/or the like are arranged. The base substrate BL may be a glass substrate, a metal substrate, a plastic substrate, and/or the like. However, embodiments of the disclosure are not limited thereto, and the base substrate BL may be an inorganic layer, an organic layer, or a composite material layer. In one or more embodiments, the base substrate BL may not be provided.

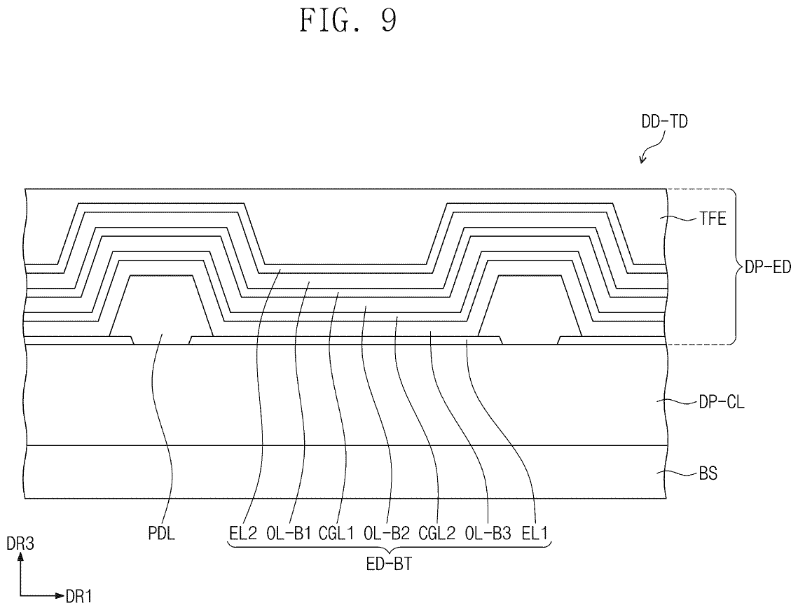

FIG. 9 is a cross-sectional view illustrating a portion of a display device according to one or more embodiments. In the display device DD-TD of one or more embodiments, the light-emitting element ED-BT may include a plurality of light emitting structures OL-B1, OL-B2, and OL-B3. At least one selected from among the plurality of light-emitting structures OL-B1, OL-B2, and OL-B3 may include a heterocyclic compound of embodiments. Accordingly, the light emitting element ED-BT may exhibit improved luminous efficiency and low driving voltage characteristics. Additionally, the light emitting element ED-BT emits deep blue light and may exhibit excellent or suitable light conversion efficiency.

The light-emitting element ED-BT may include a first electrode EL1 and a second electrode EL2 which face each other, and the plurality of light emitting structures OL-B1, OL-B2, and OL-B3 sequentially stacked in a thickness direction between the first electrode EL1 and the second electrode EL2. The light emitting structures OL-B1, OL-B2, and OL-B3 each may include an emission layer EML (FIG. 8) and a hole transport region HTR and an electron transport region ETR arranged with the emission layer EML (FIG. 8) located therebetween.

For example, the light-emitting element ED-BT included in the display device DD-TD of one or more embodiments may be a light-emitting element having a tandem structure and including a plurality of emission layers.

In one or more embodiments illustrated in FIG. 9, all light beams respectively emitted from the light emitting structures OL-B1, OL-B2, and OL-B3 may be blue light. However, embodiments of the disclosure are not limited thereto, and the light beams respectively emitted from the light emitting structures OL-B1, OL-B2, and OL-B3 may have wavelength ranges different from each other. For example, in one or more embodiments, the light-emitting element ED-BT including the plurality of light emitting structures OL-B1, OL-B2, and OL-B3 which emit light beams having wavelength ranges different from each other may be to emit white light (e.g., combined white light).

Charge generation layers CGL1 and CGL2 may be respectively arranged between two of the neighboring light emitting structures OL-B1, OL-B2, and OL-B3. The charge generation layers CGL1 and CGL2 may include a p-type or kind charge (e.g., P-charge) generation layer and/or an n-type or kind charge (e.g., N-charge) generation layer.

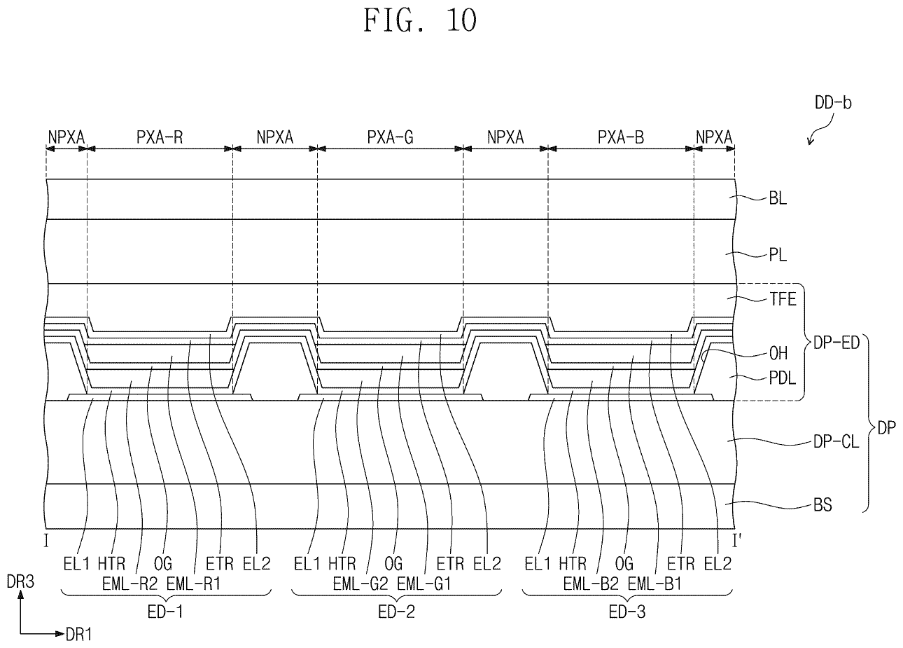

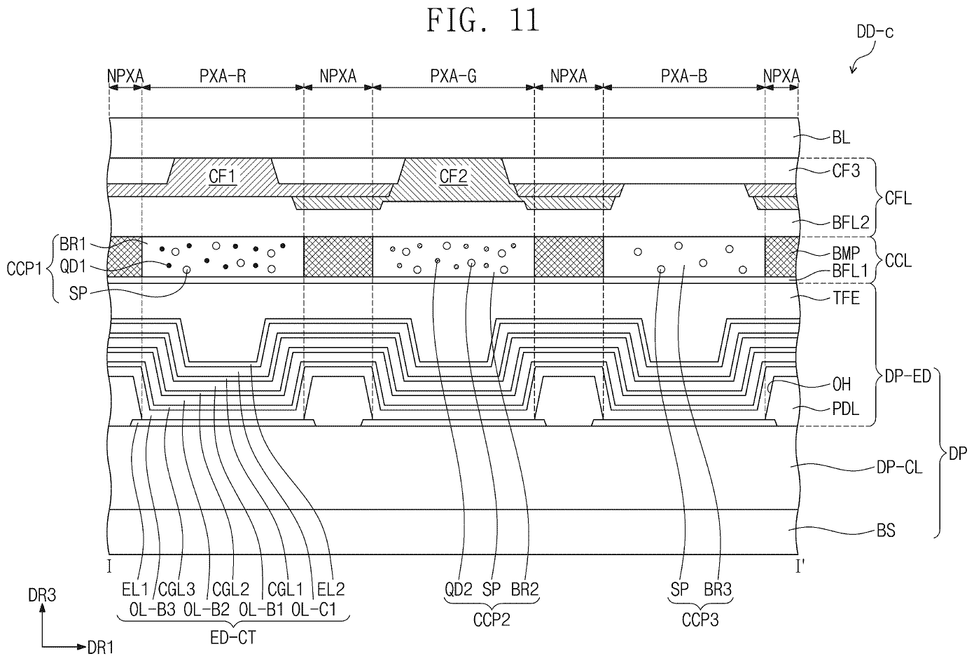

Referring to FIG. 10, a display device DD-b according to one or more embodiments may include light-emitting elements ED-1, ED-2, and ED-3 in each of which two emission layers are stacked. At least one selected from among the light emitting elements ED-1, ED-2, and ED-3 may include a heterocyclic compound of embodiments. Accordingly, the light-emitting elements ED-1, ED-2, and ED-3 may exhibit improved luminous efficiency and low driving voltage characteristics. Additionally, the light emitting elements ED-1, ED-2, and ED-3 emit deep blue light and may exhibit excellent or suitable light conversion efficiency.

Compared with the display device DD of one or more embodiments illustrated in FIG. 2, the display apparatus DD-b illustrated in FIG. 10 has a difference in that the first to third light-emitting elements ED-1, ED-2, and ED-3 each include two emission layers stacked in a thickness direction. In each of the first to third light-emitting elements ED-1, ED-2, and ED-3, the two emission layers may be to emit light in substantially the same wavelength region.

In one or more embodiments, the first light-emitting element ED-1 may include a first red emission layer EML-R1 and a second red emission layer EML-R2. The second light-emitting element ED-2 may include a first green emission layer EML-G1 and a second green emission layer EML-G2. In addition, the third light-emitting element ED-3 may include a first blue emission layer EML-B1 and a second blue emission layer EML-B2. An emission auxiliary part OG may be separately arranged between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. In one or more embodiments, the emission auxiliary part OG may include an electron transport region, a charge generation layer, and a hole transport region that are sequentially stacked (e.g., in the stated order). The emission auxiliary part OG may be provided as a common layer in the whole of the first to third light-emitting elements ED-1, ED-2, and ED-3. However, embodiments of the disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be arranged between the emission auxiliary part OG and the electron transport region ETR. The second red emission layer EML-R2, the second green emission layer EML-G2, and the second blue emission layer EML-B2 may each be arranged between the hole transport region HTR and the emission auxiliary part OG.

For example, in one or more embodiments, the first light-emitting element ED-1 may include a first electrode EL1, a hole transport region HTR, a second red emission layer EML-R2, an emission auxiliary part OG, a first red emission layer EML-R1, an electron transport region ETR, and a second electrode EL2 that are sequentially stacked (e.g., in the stated order). The second light-emitting element ED-2 may include a first electrode EL1, a hole transport region HTR, a second green emission layer EML-G2, an emission auxiliary part OG, a first green emission layer EML-G1, an electron transport region ETR, and a second electrode EL2 that are sequentially stacked (e.g., in the stated order). The third light-emitting element ED-3 may include a first electrode EL1, a hole transport region HTR, a second blue emission layer EML-B2, an emission auxiliary part OG, a first blue emission layer EML-B1, an electron transport region ETR, and a second electrode EL2 that are sequentially stacked (e.g., in the stated order).

In one or more embodiments, an optical auxiliary layer PL may be arranged on the display device layer DP-ED. The optical auxiliary layer PL may include a polarizing layer. The optical auxiliary layer PL may be arranged on the display panel DP and control reflected light in the display panel DP due to external light. In some embodiments, the optical auxiliary layer PL may not be provided in the display device.

Unlike FIGS. 9 and 10, FIG. 11 illustrates that a display device DD-c includes four light emitting structures OL-B1, OL-B2, OL-B3, and OL-C1. A light-emitting element ED-CT may include a first electrode EL1 and a second electrode EL2 which face each other, and first to fourth light emitting structures OL-B1, OL-B2, OL-B3, and OL-C1 that are stacked in the thickness direction between the first electrode EL1 and the second electrode EL2. Charge generation layers CGL1, CGL2, and CGL3 may each be separately arranged between the first to fourth light emitting structures OL-B1, OL-B2, OL-B3, and OL-C1. In one or more embodiments, among the four light emitting structures, the first to third light emitting structures OL-B1, OL-B2, and OL-B3 may each be to emit blue light, and the fourth light emitting structure OL-C1 may be to emit green light. However, embodiments of the disclosure are not limited thereto, and the first to fourth light emitting structures OL-B1, OL-B2, OL-B3, and OL-C1 may each be to emit light beams in different wavelength regions.

The charge generation layers CGL1, CGL2, and CGL3 arranged between adjacent light emitting structures OL-B1, OL-B2, OL-B3, and OL-C1 may include a p-type or kind charge (e.g., P-charge) generation layer and/or an n-type or kind charge (e.g., N-charge) generation layer.

In one or more embodiments, an electronic apparatus may include a display device including a plurality of light-emitting elements, and a control part which controls the display device. The electronic apparatus of one or more embodiments may be a device that is activated according to an electrical signal. The electronic apparatus may include display devices of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

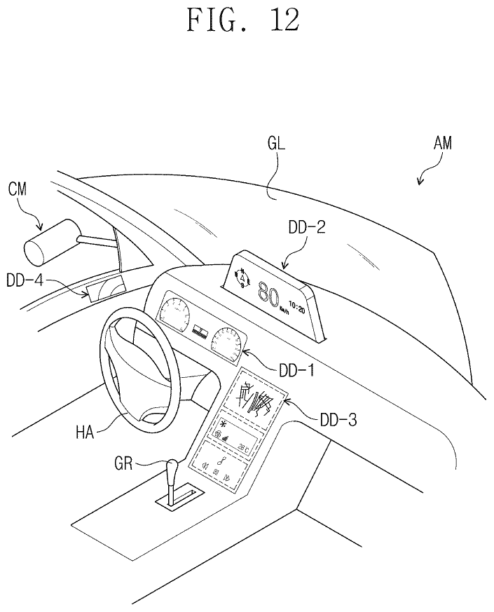

FIG. 12 is a view illustrating a vehicle AM in which first to fourth display devices DD-1, DD-2, DD-3, and DD-4 are arranged. At least one selected from among the first to fourth display devices DD-1, DD-2, DD-3, and DD-4 may include substantially the same configuration as the display devices DD, DD-TD, DD-a, DD-b, and/or DD-c as described with reference to FIGS. 1, and 2, and 8 to 11.

FIG. 12 illustrates a vehicle AM, but this is an example, and the first to fourth display devices DD-1, DD-2, DD-3, and DD-4 may be arranged in other transportation apparatuses such as bicycles, motorcycles, trains, ships, and/or airplanes. In one or more embodiments, at least one selected from among the first to fourth display devices DD-1, DD-2, DD-3, and DD-4 including substantially the same configuration as the display devices DD, DD-TD, DD-a, DD-b, and/or DD-c of one or more embodiments may be employed in a personal computer, a laptop computer, a personal digital terminal, a game console, a portable electronic device, a television, a monitor, an outdoor billboard, and/or the like. These are merely provided as embodiments, and thus the display device may be employed in other electronic apparatuses unless departing from the disclosure.

In one or more embodiments, at least one selected from among the first to fourth display devices DD-1, DD-2, DD-3, and DD-4 may include the light-emitting element ED of one or more embodiments as described with reference to FIGS. 3 to 7.

Referring to FIG. 12, the vehicle AM may include a steering wheel HA and a gear GR for driving the vehicle AM. In addition, the vehicle AM may include a front window GL arranged so as to face a driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. The first scale and the second scale may be indicated as a digital image.

The second display device DD-2 may be arranged in a second region facing (e.g., opposite to) a driver seat and overlapping the front window GL. The driver seat may be a seat in which the steering wheel HA faces. For example, the second display device DD-2 may be a head up display (HUD) which displays second information of the vehicle AM. The second display device DD-2 may be optically transparent. The second information may include digital numbers which indicate a driving speed, and may further include information such as the current time. In one or more embodiments, the second information of the second display device DD-2 may be projected to the front window GL to be displayed.

The third display device DD-3 may be arranged in a third region adjacent to the gear GR. For example, the third display device DD-3 may be arranged between a driver seat and a passenger seat and may be a center information display (CID) for the vehicle for displaying third information. The passenger seat may be a seat spaced and/or apart (e.g., spaced apart or separated) from the driver seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR, and may be arranged in a fourth region adjacent to a side of the vehicle AM. For example, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may include different information. However, embodiments of the disclosure are not limited thereto, and a part of the first to fourth information may include the same information as one another.

Hereinafter, with reference to Examples and Comparative Examples, a heterocyclic compound according to one or more embodiments of the disclosure and a light-emitting element according to one or more embodiments will be specifically described. In addition, Examples shown are only for the understanding of the disclosure, and the scope of the disclosure is not limited thereto.

### EXAMPLES

1. Synthesis of Heterocyclic Compound according to Examples

A synthetic method of a heterocyclic compound according to example embodiments will be described in more detail by exemplifying synthetic methods of Compounds AH2, AH5, AH8, AH12, AH13, AH20, and AH25. In addition, in the following descriptions, the synthetic method of the heterocyclic compound is provided as an example, but the synthetic method of the compound according to one or more embodiments of the disclosure is not limited to Examples.

### (1) Synthesis of Compound AH2

Compound AH2 according to an example may be synthesized by, for example, Reaction Scheme 1.

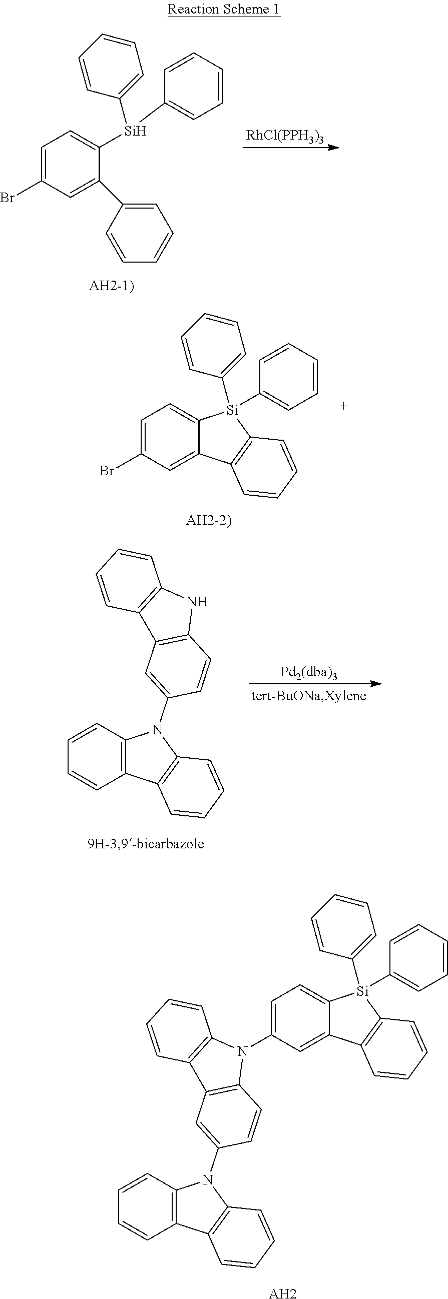

1 eq of Intermediate AH2-1 above, 10.5 eq of RhCl(PPH₃)₃ were dissolved in diethyether (Et₂O)/tetrahydrofuran (THF) (weight ratio of 2:8) of 10° C. to generate Intermediate AH2-2 (yield: 35%). 1 eq of Intermediate AH2-2 was dissolved in xylene, then 10 eq of 9H-3,9′-bicarbazole, and sodium tert-butoxide (tert-BuONa), and 10 mol % of tris(dibenzylideneacetone)dipalladium(0) (Pd₂(dba)₃) were added, and the mixture was stirred at about 120° C. for about 3 hours. After cooling, the resultant was diluted with ethyl acetate and washed three times with water, and then separated to obtain an organic layer. The obtained organic layer was dried over magnesium sulfate anhydrous and then dried under reduced pressure. Thereafter, the resultant was purified by column chromatography with methylene chloride (MC) and n-hexane as an eluent to obtain Compound AH2 (yield 50%).

### 2) Synthesis of Compound AH5

Compound AH5 according to an example may be synthesized by, for example, Reaction Scheme 2.

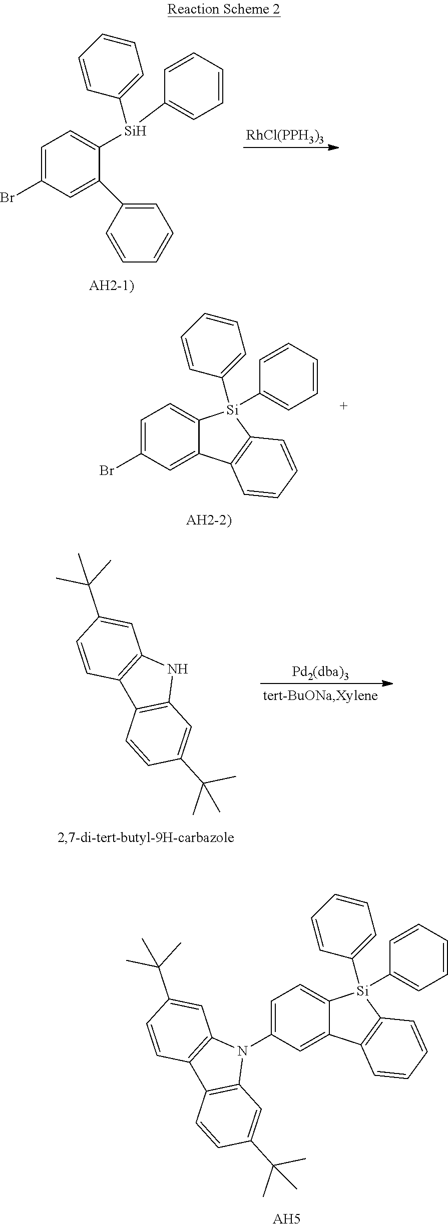

1 eq of Intermediate AH2-1, 10.5 eq of RhCl(PPH₃)₃ were dissolved in Et₂O/THF (weight ratio of 2:8) of 10° C. to generate Intermediate AH2-2 (yield: 35%). 1 eq of Intermediate AH2-2 was dissolved in xylene, then 10 eq of 2,7-di-t-Bu-9H-Carbazole, and tert-BuONa, and 10 mol % of Pd₂(dba)₃ were added, and the mixture was stirred at about 120° C. for about 3 hours. After cooling, the resultant was diluted with ethyl acetate and washed three times with water, and then separated to obtain an organic layer. The obtained organic layer was dried over magnesium sulfate anhydrous and then dried under reduced pressure. Thereafter, the resultant was purified by column chromatography with MC and n-hexane as an eluent to obtain Compound AH5 (yield 50%).

### (3) Synthesis of Compound AH8

Compound AH8 according to an example may be synthesized by, for example, Reaction Scheme 3.

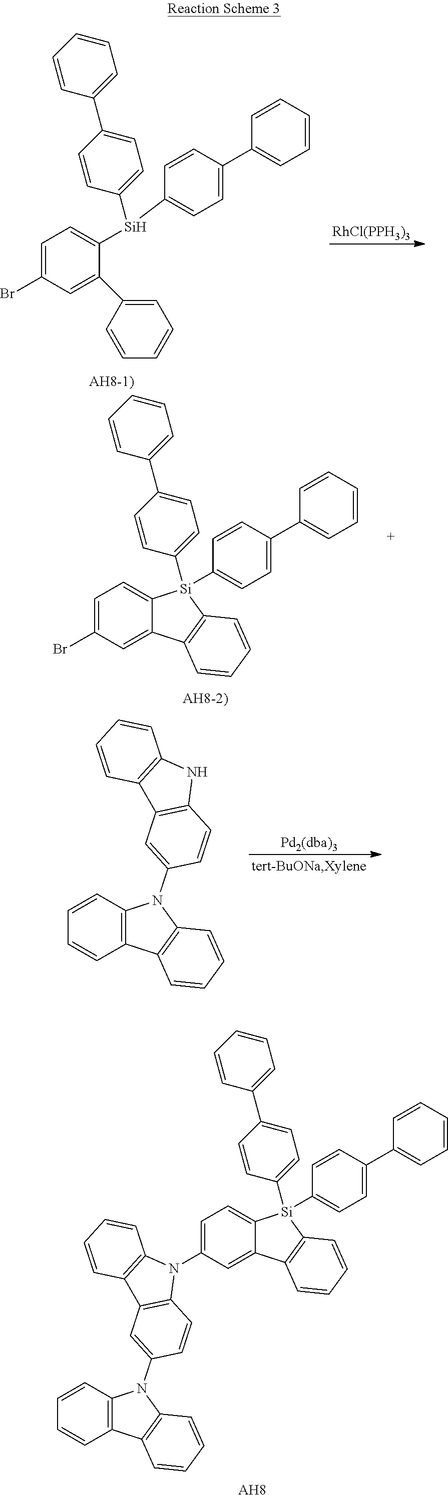

1 eq of Intermediate AH8-1, 10.5 eq of RhCl(PPH₃)₃ were dissolved in Et₂O/THF (weight ratio 2:8) of 10° C. to generate Intermediate AH8-2 (yield: 35%). 1 eq of Intermediate AH8-2 was dissolved in xylene, then 10 eq of 9H-3,9′-bicarbazole, and tert-BuONa, and 10 mol % of Pd₂(dba)₃ were added, and the mixture was stirred at about 120° C. for about 3 hours. After cooling, the resultant was diluted with ethyl acetate and washed three times with water, and then separated to obtain an organic layer. The obtained organic layer was dried over magnesium sulfate anhydrous and then dried under reduced pressure. Thereafter, the resultant was purified by column chromatography with MC and n-hexane as an eluent to obtain Compound AH8 (yield 50%).

### (4) Synthesis of Compound AH12

Compound AH12 according to an example may be synthesized by, for example, Reaction Scheme 4.

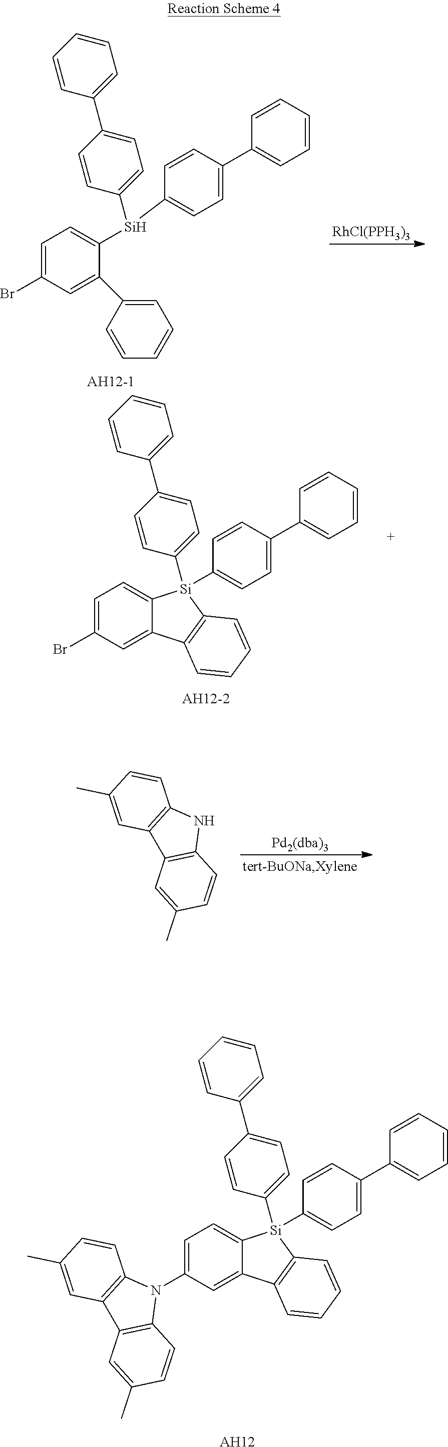

1 eq of Intermediate AH2-1, 10.5 eq of RhCl(PPH₃)₃ were dissolved in Et₂O/THF (weight ratio 2:8) of 10° C. to generate Intermediate AH12-2 (yield: 35%). 1 eq of Intermediate AH12-2 was dissolved in xylene, then 10 eq of 3,6-dimethyl-9H-carbazole, and tert-BuONa, and 10 mol % of Pd₂(dba)₃ were added, and the mixture was stirred at about 120° C. for about 3 hours. After cooling, the resultant was diluted with ethyl acetate and washed three times with water, and then separated to obtain an organic layer. The obtained organic layer was dried over magnesium sulfate anhydrous and then dried under reduced pressure. Thereafter, the resultant was purified by column chromatography with MC and n-hexane as an eluent to obtain Compound AH12 (yield 50%).

### (5) Synthesis of Compound AH13

Compound AH13 according to an example may be synthesized by, for example, Reaction Scheme 5.

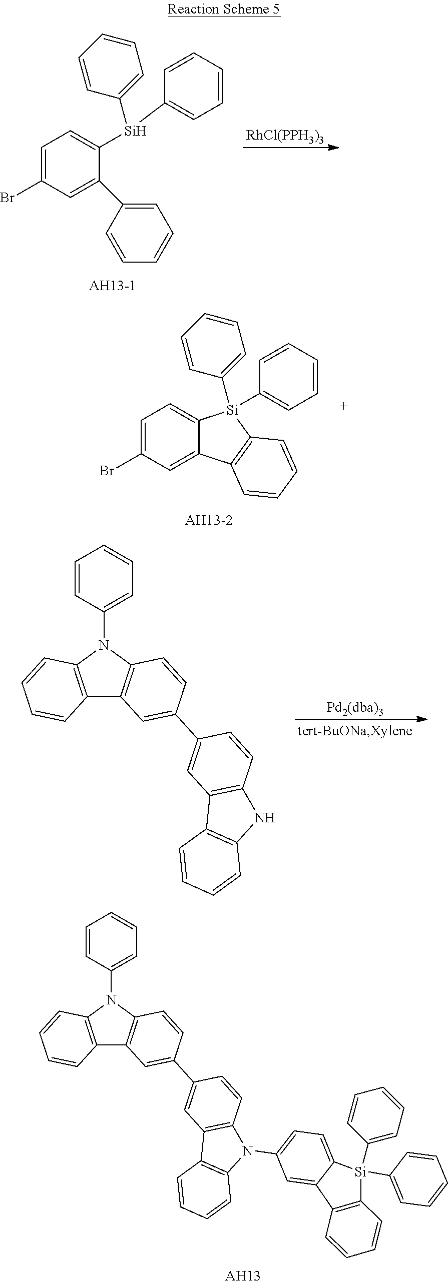

1 eq of Intermediate AH3-1, 10.5 eq of RhCl(PPH₃)₃ were dissolved in Et₂O/THF (weight ratio 2:8) of 10° C. to generate Intermediate AH13-2 (yield: 35%). 1 eq of Intermediate AH13-2 was dissolved in xylene, then 10 eq of 9-phenyl-9H,9′H-3,3′-bicarbazole, and tert-BuONa, and 10 mol % of Pd₂(dba)₃ were added, and the mixture was stirred at about 120° C. for about 3 hours. After cooling, the resultant was diluted with ethyl acetate and washed three times with water, and then separated to obtain an organic layer. The obtained organic layer was dried over magnesium sulfate anhydrous and then dried under reduced pressure. Thereafter, the resultant was purified by column chromatography with MC and n-hexane as an eluent to obtain Compound AH13 (yield 50%).

### (6) Synthesis of Compound AH20

Compound AH20 according to an example may be synthesized by, for example, Reaction Scheme 6.

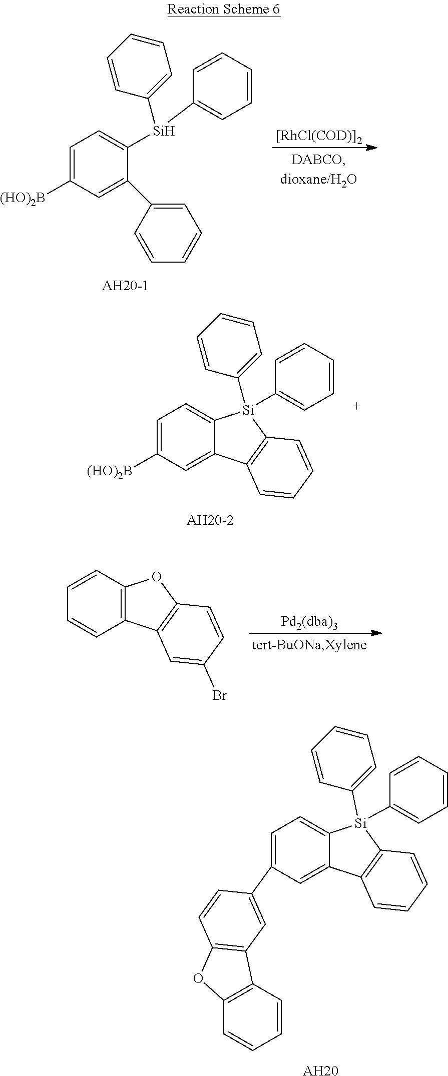

1 eq of Intermediate AH20-1, 10.5 eq of [RhCl(COD)]2 (Chloro(1,5-cyclooctadiene)rhodium(I) dimer) were dissolved in 1 eq of 1,4-diazabicyclo[2.2.2]octane (DABCO), dioxane/H₂O (weight ratio of 1:1) of 65° C. to generate Intermediate AH20-2 (yield: 35%). 1 eq of Intermediate AH20-2 was dissolved in xylene, then 10 eq of 2-bromodibenzofuran and tert-BuONa, and 10 mol % of Pd₂(dba)₃ were added, and the mixture was stirred at about 120° C. for about 3 hours. After cooling, the resultant was diluted with ethyl acetate and washed three times with water, and then separated to obtain an organic layer. The obtained organic layer was dried over magnesium sulfate anhydrous and then dried under reduced pressure. Thereafter, the resultant was purified by column chromatography with MC and n-hexane as an eluent to obtain Compound AH20 (yield 50%).

### (7) Synthesis of Compound AH25

Compound AH25 according to an example may be synthesized by, for example, Reaction Scheme 7.

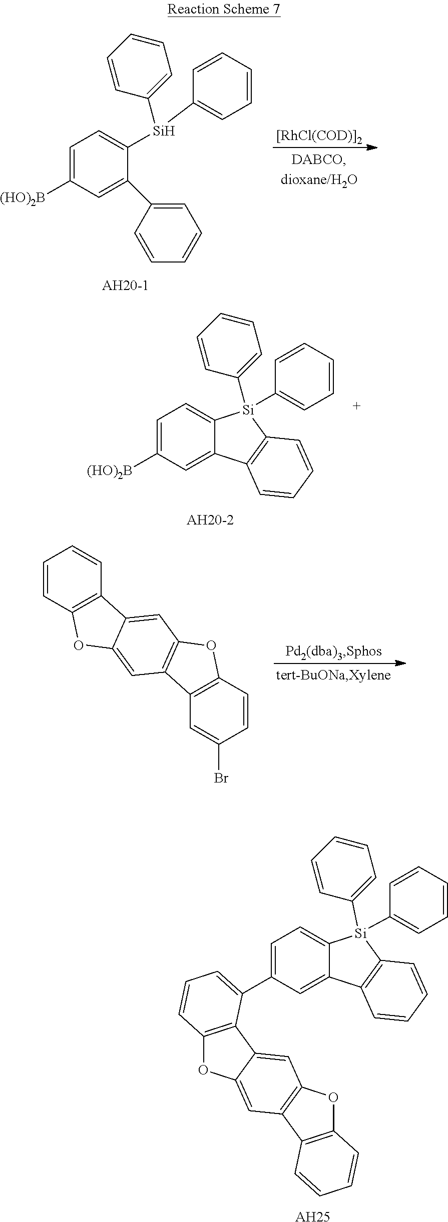

1 eq of Intermediate AH20-1, 10.5 eq of [RhCl(COD)]2 were dissolved in 1 eq 1,4-diazabicyclo[2.2.2]octane (DABCO) of Et₂O/THF (weight ratio 2:8) of 10° C. to generate Intermediate AH20-2 (yield: 35%). 1 eq of Intermediate AH20-2 was dissolved in xylene, then 10 eq of bromo-benzo[1,2-b:4,5-b′]bisbenzofuran and tert-BuONa, and 5 mol % of Pd₂(dba)₃ and 10 mol % of 2-dicyclohexylphosphino-2′,6′-dimethoxybiphenyl (Sphos) were added, and the mixture was stirred at about 120° C. for about 3 hours. After cooling, the resultant was diluted with ethyl acetate and washed three times with water and then separated to obtain an organic layer. The obtained organic layer was dried over magnesium sulfate anhydrous and then dried under reduced pressure. Thereafter, the resultant was purified by column chromatography with MC and n-hexane as an eluent to obtain Compound AH25 (yield: 50%).

### 2. Manufacture and Evaluation of Light-Emitting Element

### (1) Manufacture of Light-Emitting Element

In the light-emitting elements according to Examples and Comparative Examples, a glass substrate (made by Corning Co.), on which an ITO electrode of about 15 Ω/cm² (1,200 Å) was formed as an anode, was cut to a size of about 50 mm×50 mm×0.7 mm, cleansed by ultrasonic waves with isopropyl alcohol and then pure water for about five minutes each, and then irradiated with ultraviolet rays for about 30 minutes and exposed to ozone and cleansed. Then, the glass substrate was mounted on a vacuum deposition apparatus.

NPD was deposited on the anode to form a hole injection layer having a thickness of 300 Å, then TCTA was deposited on the hole injection layer to form a hole transport layer having a thickness of 200 Å, and then CzSi was deposited on the hole transport layer to form an emission auxiliary layer having a thickness of 100 Å.

Thereafter, the heterocyclic compound according to one or more embodiments (the first compound) or Comparative Example Compound, the second compound, the fourth compound, and the third compound were co-deposited at a weight ratio of 70:30:15:1.0 (the first compound or Comparative Example Compound: the second compound: the fourth compound: the third compound) to form an emission layer having a thickness of 250 Å, and TSPO1 was deposited on the emission layer to form an electron transport layer having a thickness of 200 Å. Thereafter, TPBI was deposited on the electron transport layer to form an electron injection layer having a thickness of 300 Å, then LiF was deposited on the electron injection layer to a thickness of 10 Å, and Al was deposited to a thickness of 3000 Å to form a LiF cathode, thereby manufacturing the light-emitting element. Each layer was formed by a vacuum deposition method.

Compounds utilized for manufacturing the light-emitting elements according to Examples and Comparative Examples are disclosed herein. The materials were utilized in manufacture of elements by purifying commercial products by sublimation.

### Example Compounds

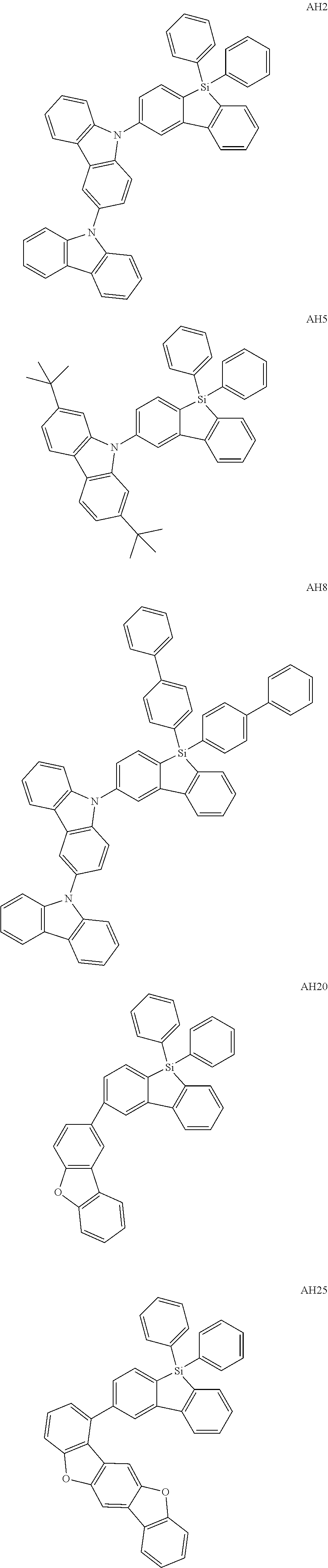 [SMILES: c1ccc([Si]2(c3ccccc3)c3ccccc3-c3cc(-n4c5ccccc5c5cc(-n6c7ccccc7c7ccccc76)ccc54)ccc32)cc1 ; CC(C)(C)c1ccc2c3ccc(C(C)(C)C)cc3n(-c3ccc4c(c3)-c3ccccc3[Si]4(c3ccccc3)c3ccccc3)c2c1 ; c1ccc(-c2ccc([Si]3(c4ccc(-c5ccccc5)cc4)c4ccccc4-c4cc(-n5c6ccccc6c6cc(-n7c8ccccc8c8ccccc87)ccc65)ccc43)cc2)cc1 ; c1ccc([Si]2(c3ccccc3)c3ccccc3-c3cc(-c4ccc5oc6ccccc6c5c4)ccc32)cc1 ; c1ccc([Si]2(c3ccccc3)c3ccccc3-c3cc(-c4cccc5oc6cc7c(cc6c45)oc4ccccc47)ccc32)cc1]

### Comparative Example Compounds

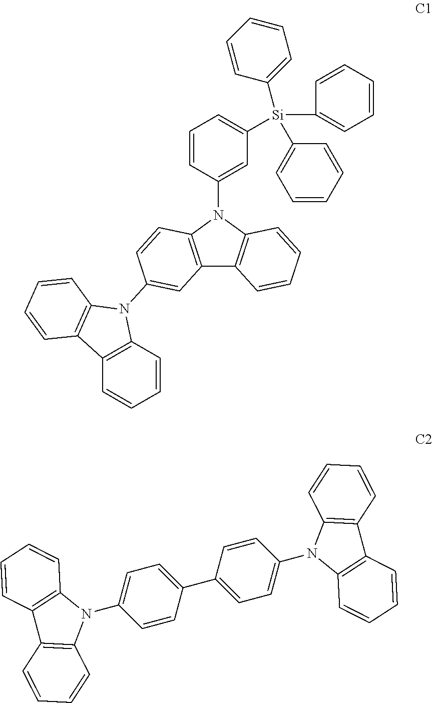 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc2c(c1)c1ccccc1n2-c1ccc(-c2ccc(-n3c4ccccc4c4ccccc43)cc2)cc1]

### Materials Utilized in Manufacture of Light-Emitting Element

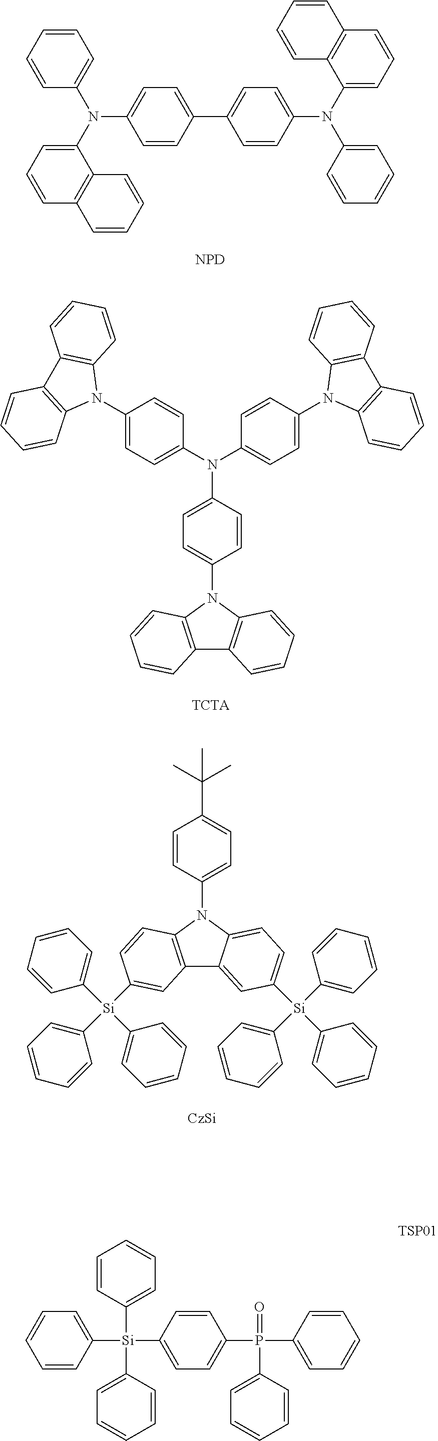 [SMILES: c1ccc(N(c2ccc(-c3ccc(N(c4ccccc4)c4cccc5ccccc45)cc3)cc2)c2cccc3ccccc23)cc1 ; "NPD" ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; O=P(c1ccccc1)(c1ccccc1)c1ccc([Si](c2ccccc2)(c2ccccc2)c2ccccc2)cc1]

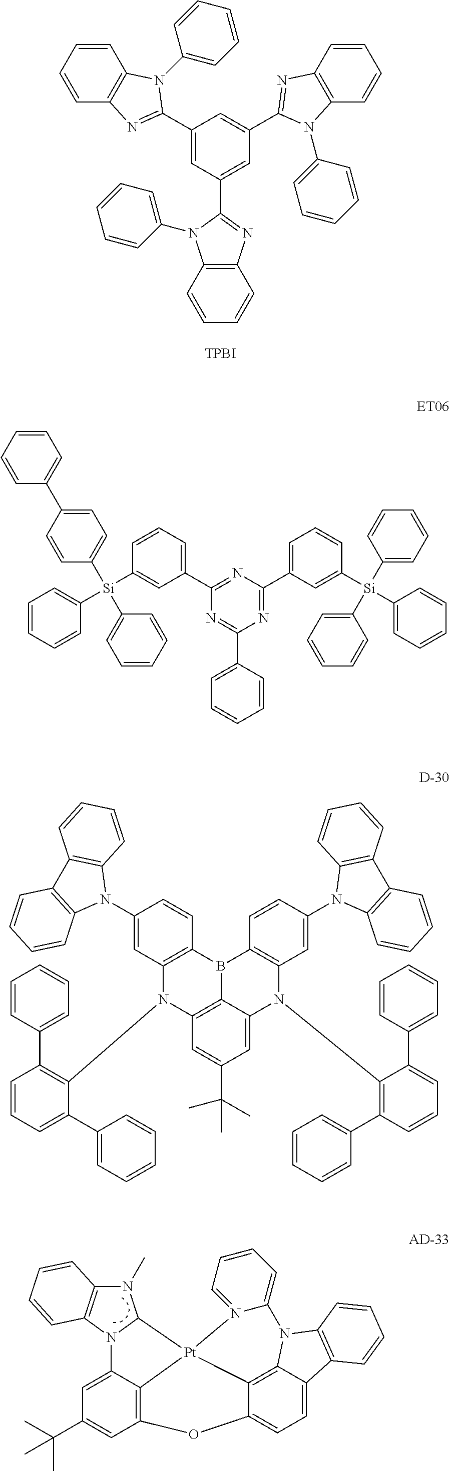

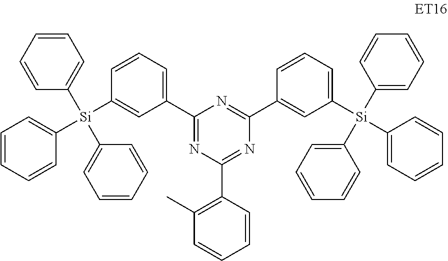 [SMILES: Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

### (2) Evaluation of Light-Emitting Element

The light-emitting elements according to Examples and Comparative Examples were each evaluated and the results are listed in Table 1. In the light-emitting elements according to Examples and Comparative Examples, evaluation of the characteristics of each of the light-emitting elements was performed utilizing a luminance orientation characteristic measurement apparatus. In order to evaluate the characteristics of each of the light-emitting elements according to Examples and Comparative Examples, a driving voltage, luminance, efficiency, and an emission wavelength of the light-emitting element were measured. The emission efficiency (cd/A) at a current density of 10 mA/cm², and luminance of 1000 cd/m² for each of the manufactured organic electroluminescence elements are shown in Table 1. In addition, a luminance spectrum of each of the light-emitting elements according to Examples and Comparative Examples was measured utilizing a spectroradiometer. An emission peak, which is a maximum emission wavelength, was measured from the measured luminance spectrum.

TABLE 1

| | | | | | Driving | | Emission | |
|---|---|---|---|---|---|---|---|---|
| | First | Second | Third | Fourth | voltage | Efficiency | wavelength | Lifespan |
| | Compound | Compound | Compound | Compound | (V) | (Cd/A/y) | (nm) | (hr) |
| Example 1 | Compound | ET06 | D-30 | AD-33 | 4.3 | 123 | 463 | 80 |
| | AH5 | | | | | | | |
| Example 2 | Compound | ET06 | D-30 | AD-33 | 4.2 | 100 | 463 | 90 |
| | AH8 | | | | | | | |
| Example 3 | Compound | ET06 | D-30 | AD-33 | 4.1 | 121 | 461 | 150 |
| | AH12 | | | | | | | |
| Example 4 | Compound | ET06 | D-30 | AD-33 | 4.1 | 133 | 462 | 130 |
| | AH13 | | | | | | | |
| Example 5 | Compound | ET16 | D-30 | AD-33 | 4.4 | 90 | 462 | 100 |
| | AH20 | | | | | | | |
| Example 6 | Compound | ET16 | D-30 | D-30 | 4.5 | 99 | 464 | 99 |
| | AH25 | | | | | | | |
| Example 7 | Compound | ET06 | D-30 | D-30 | 4.1 | 132 | 461 | 148 |
| | AH2 | | | | | | | |
| Comparative | Compound | — | D-30 | — | 5.7 | 50 | 464 | 0.1 |
| Example 1 | C2 | | | | | | | |
| Comparative | Compound | — | D-30 | — | 5.8 | 55 | 463 | 0.2 |
| Example 2 | C1 | | | | | | | |
| Comparative | Compound | ET06 | — | AD-33 | 5.5 | 65 | 463 | 50 |
| Example 3 | C1 | | | | | | | |
| Comparative | Compound | ET06 | D-30 | AD-33 | 5.1 | 80 | 462 | 65 |
| Example 4 | C1 | | | | | | | |
| Comparative | Compound | ET15 | D-30 | AD-33 | 5.0 | 75 | 462 | 66 |
| Example 5 | C1 | | | | | | | |
| Comparative | Compound | ET06 | D-30 | D-30 | 4.7 | 90 | 462 | 65 |
| Example 6 | C2 | | | | | | | |

Referring to the results listed in Table 1, it can be seen that the light-emitting elements according to Examples each exhibit a lower level of driving voltage than those of the light-emitting elements according to Comparative Examples. In addition, the light-emitting elements according to Examples each exhibit excellent or suitable emission efficiency and long lifespan characteristics, compared to the light-emitting elements according to Comparative Examples including Comparative Example Compounds containing a heterocyclic compound, which is different from the Example Compounds.

In the light-emitting element according to one or more embodiments, the emission layer may include the heterocyclic compound according to one or more embodiments. The heterocyclic compound according to one or more embodiments may exhibit excellent or suitable emission efficiency and long lifespan characteristics by containing a dibenzosilole skeleton containing a silicon atom as a ring-forming atom.

In addition, the heterocyclic compound according to one or more embodiments may be utilized as a host material and a hole transport material, and the light-emitting element containing the heterocyclic compound according to one or more embodiments may exhibit characteristics of high efficiency, long lifespan, and low driving voltage.

The light-emitting element according to one or more embodiments may exhibit low driving voltage characteristics, high-efficiency characteristics, and long lifespan characteristics by containing the heterocyclic compound according to one or more embodiments in at least one functional layer, for example, in the emission layer.

The heterocyclic compound according to one or more embodiments may contribute to improving light efficiency and lifespan of the light-emitting element.

The electronic device according to one or more embodiments may exhibit excellent or suitable display quality.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In the present disclosure, when particles (e.g., quantum dots) are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The light-emitting element, the display device, the display apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hitherto, although one or more embodiments of disclosure have been described, it is understood that disclosure should not be limited to these embodiments but one or more suitable changes and modifications can be made by one ordinary skilled in the art within the spirit and scope of disclosure as hereinafter claimed.

Therefore, the technical scope of the disclosure is not intended to be limited to the contents set forth in the detailed description of the present disclosure, but is intended to be defined by the appended claims and equivalents thereof.

What is claimed is:

1. A light-emitting element comprising:
a first electrode;
a second electrode on the first electrode; and
at least one functional layer between the first electrode and the second electrode and containing a first compound represented by Formula 1: 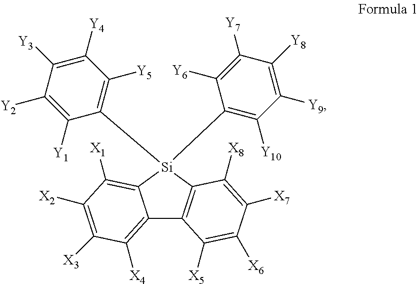
wherein, in Formula 1,
X₁ to X₈ and Y₁ to Y₁₀ are each independently hydrogen, deuterium, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 5 to 30 ring-forming carbon atoms.

2. The light-emitting element of claim 1, wherein the at least one functional layer comprises:
a hole transport region on the first electrode;
an emission layer on the hole transport region; and
an electron transport region on the emission layer, and
the emission layer comprises the first compound represented by Formula 1.

3. The light-emitting element of claim 1, wherein the emission layer further comprises a second compound represented by Formula ET: 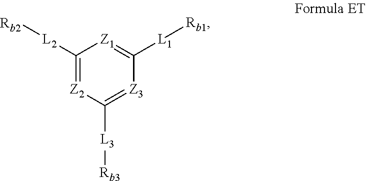
in Formula ET,
at least one selected from among Z₁ to Z₃ being N, and the rest being CR_{b4},
R_{b1} to R_{b3} being each independently hydrogen, deuterium, a halogen, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{b4} being hydrogen, deuterium, a substituted or unsubstituted alkyl group having 1 to 20 carbon atoms, a substituted or unsubstituted aryl group having 6 to 60 ring-forming carbon atoms, or a heteroaryl group having 2 to 60 ring-forming carbon atoms, and
L₁ to L₃ being each independently a direct linkage, a substituted or unsubstituted arylene group having 6 to 30 ring-forming carbon atoms, or a substituted or unsubstituted heteroarylene group having 2 to 30 ring-forming carbon atoms.

4. The light-emitting element of claim 3, wherein the emission layer further comprises a third compound represented by Formula F-1: 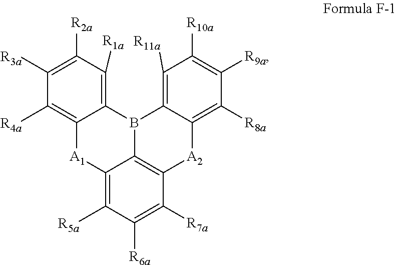
in Formula F-1,
A₁ and A₂ being each independently NRₘ or O,
Rₘ being hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁ₐ to R₁₁ₐ being each independently hydrogen, deuterium, a halogen, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 30 carbon atoms, a substituted or unsubstituted aryl group having 6 to 60 ring-forming carbon atoms, or a substituted or unsubstituted heteroaryl group having 2 to 60 ring-forming carbon atoms, and/or being bonded to an adjacent group to form a ring.

5. The light-emitting element of claim 4, wherein the emission layer further comprises a fourth compound represented by Formula D-1: 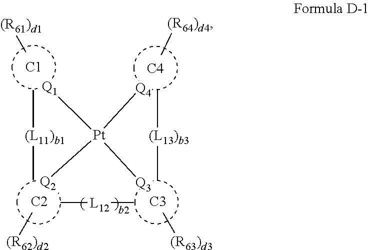
in Formula D-1,
Q₁ to Q₄ being each independently C or N,
C₁ to C₄ being each independently a substituted or unsubstituted hydrocarbon ring having 5 to 30 ring-forming carbon atoms or a substituted or unsubstituted hetero ring having 2 to 30 ring-forming carbon atoms,
L₁₁ to L₁₃ being each independently a direct linkage, 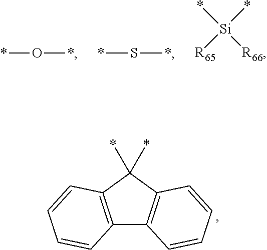
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 being each independently 0 or 1,
R₆₁ to R₆₆ being each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 being each independently an integer of 0 to 4.

6. The light-emitting element of claim 2, wherein the emission layer is to emit blue light with a maximum center wavelength of about 470 nm or less.

7. The light-emitting element of claim 1, wherein at least one selected from among X₁ to X₈ and Y₁ to Y₁₀ is represented by Formula 1a, or Formula 1b: 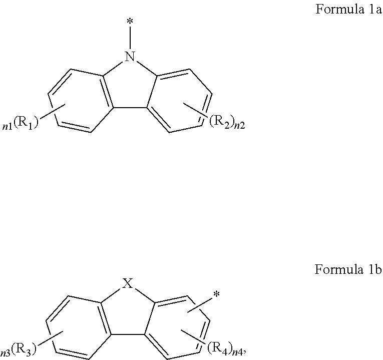
in Formula 1a and Formula 1b,
X being O or S,
R₁ to R₄ being each independently hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
n1 to n3 being each independently an integer of 0 to 4, and
n4 being an integer of 0 to 3.

8. The light-emitting element of claim 7, wherein:
at least one selected from among X₁ to X₈ is represented by Formula 1a or Formula 1b; and
the remaining among X₁ to X₈, which is not represented by Formula 1a or Formula 1b, and Y₁ to Y₁₀ are each independently hydrogen, deuterium, a substituted or unsubstituted methyl group, a substituted or unsubstituted phenyl group, or a substituted or unsubstituted carbazole group.

9. The light-emitting element of claim 1, wherein the first compound represented by Formula 1 is represented by Formula 2 or Formula 3: 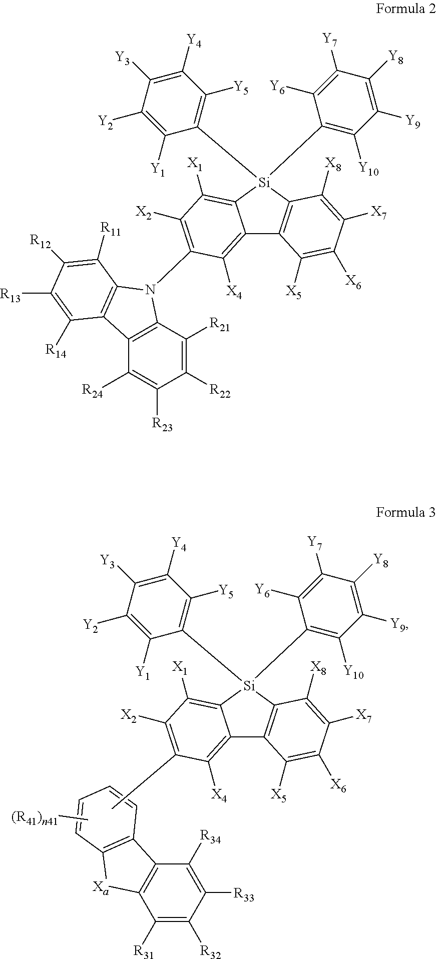
in Formula 2 and Formula 3,
Xₐ being O or S,
R₁₁ to R₁₄, R₂₁ to R₂₄, and R₃₁ to R₃₄ being each independently hydrogen, deuterium, a substituted or unsubstituted alky group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
R₄₁ being hydrogen or deuterium,
n41 being an integer of 0 to 3, and
X₁, X₂, X₄ to X₈, and Y₁ to Y₁₀ being the same as defined in Formula 1.

10. The light-emitting element of claim 9, wherein the first compound represented by Formula 2 is represented by Formula 2-1 or Formula 2-2: 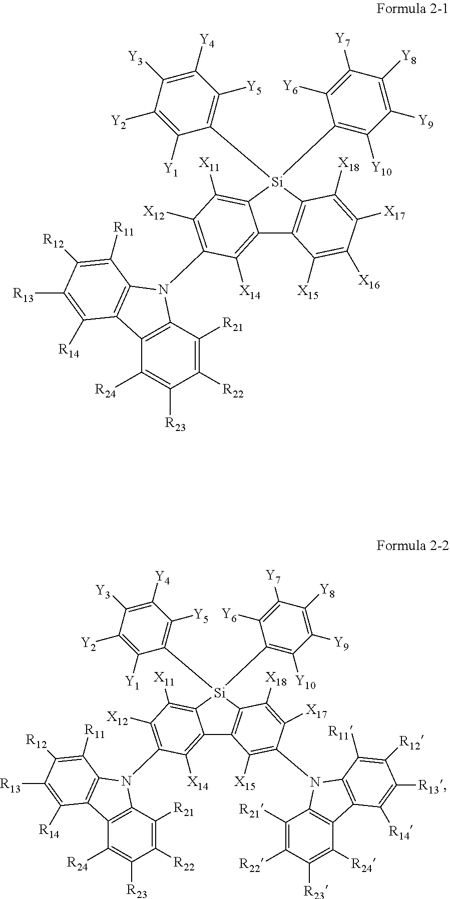
in Formula 2-1 and Formula 2-2,
X₁₁, X₁₂, X₁₄, X₁₅, X₁₆, X₁₇, and X₁₈ being each independently hydrogen or deuterium,
R₁₁′ to R₁₄′ and R₂₁′ to R₂₄′ being each independently hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring, and
Y₁ to Y₁₀, R₁₁ to R₁₄, and R₂₁ to R₂₄ being the same as defined in Formula 1 and Formula 2.

11. The light-emitting element of claim 9, wherein the first compound represented by Formula 3 is represented by Formula 3-1 or Formula 3-2: 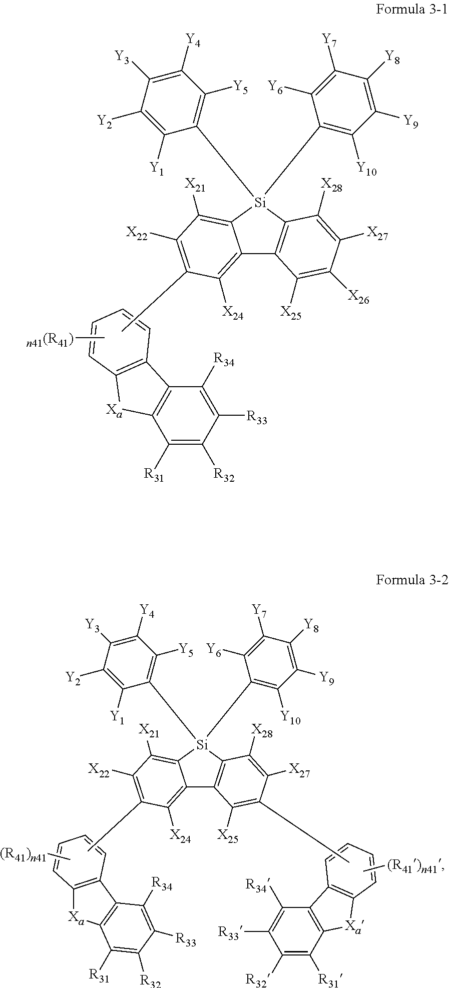
in Formula 3-1 and Formula 3-2,
Xₐ′ being O or S,
X₂₁, X₂₂, X₂₄, X₂₅, X₂₆, X₂₇, X₂₈, and R₄₁′ being each independently hydrogen or deuterium,
R₃₁′ to R₃₄′ being each independently hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
n41′ being an integer of 0 to 3, and
Xₐ, Y₁ to Y₁₀, R₃₁ to R₃₄, R₄₁, and n41 being the same as defined in Formula 1 and Formula 3.

12. The light-emitting element of claim 1, wherein Y₃ and Y₈ are each independently hydrogen, deuterium, a substituted or unsubstituted methyl group, a substituted or unsubstituted phenyl group, or a substituted or unsubstituted carbazole group.

13. The light-emitting element of claim 1, wherein the first compound is any one selected from among compounds in Compound Group 1:

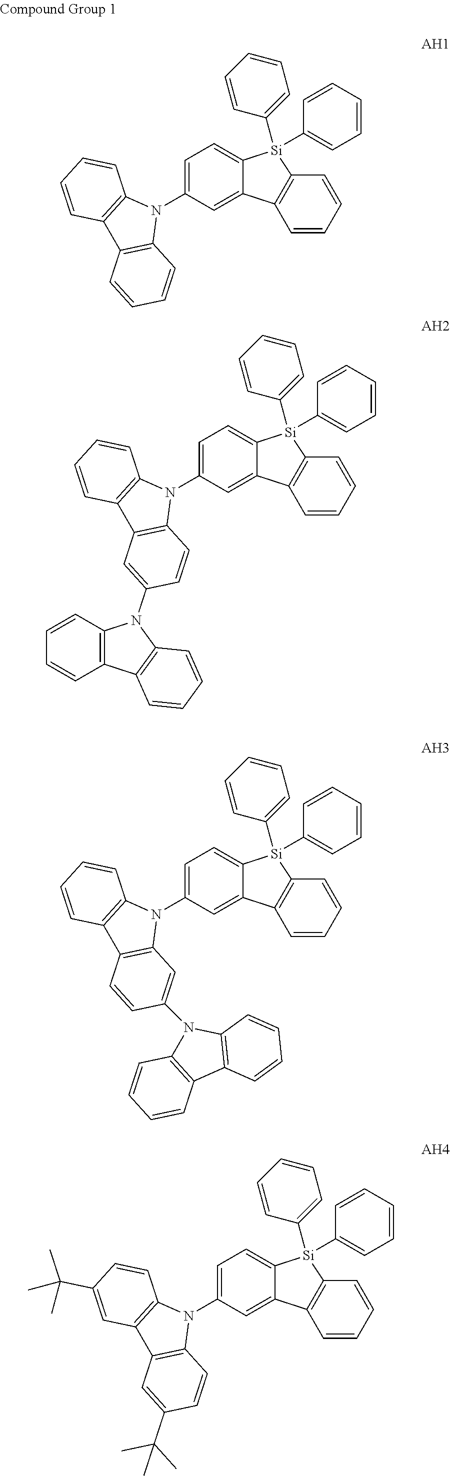 [SMILES: c1ccc([Si]2(c3ccccc3)c3ccccc3-c3cc(-n4c5ccccc5c5ccccc54)ccc32)cc1 ; c1ccc([Si]2(c3ccccc3)c3ccccc3-c3cc(-n4c5ccccc5c5cc(-n6c7ccccc7c7ccccc76)ccc54)ccc32)cc1 ; c1ccc([Si]2(c3ccccc3)c3ccccc3-c3cc(-n4c5ccccc5c5ccc(-n6c7ccccc7c7ccccc76)cc54)ccc32)cc1 ; CC(C)(C)c1ccc2c(c1)c1cc(C(C)(C)C)ccc1n2-c1ccc2c(c1)-c1ccccc1[Si]2(c1ccccc1)c1ccccc1]

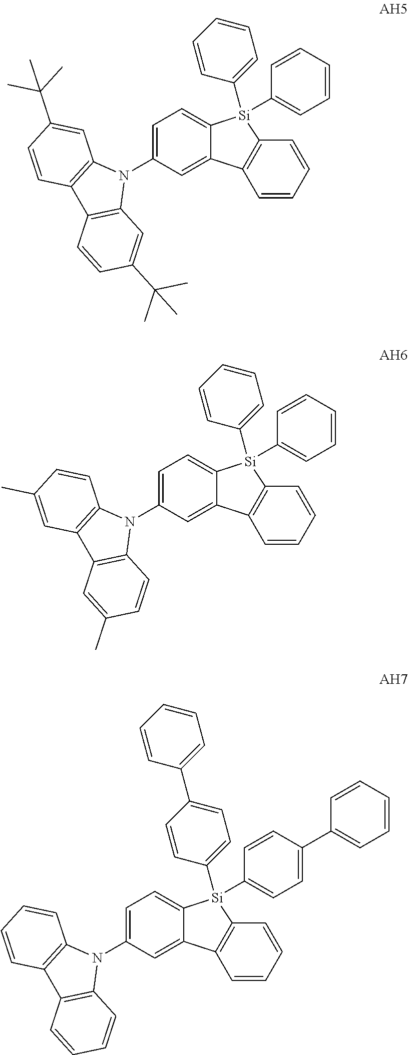 [SMILES: CC(C)(C)c1ccc2c3ccc(C(C)(C)C)cc3n(-c3ccc4c(c3)-c3ccccc3[Si]4(c3ccccc3)c3ccccc3)c2c1 ; Cc1ccc2c(c1)c1cc(C)ccc1n2-c1ccc2c(c1)-c1ccccc1[Si]2(c1ccccc1)c1ccccc1 ; c1ccc(-c2ccc([Si]3(c4ccc(-c5ccccc5)cc4)c4ccccc4-c4cc(-n5c6ccccc6c6ccccc65)ccc43)cc2)cc1]

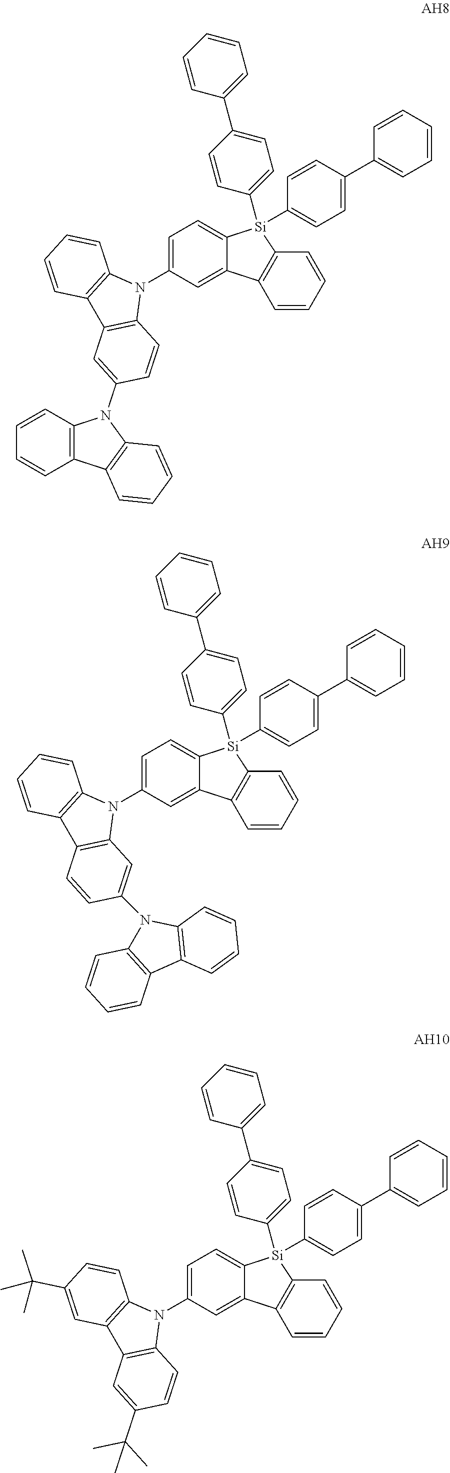 [SMILES: c1ccc(-c2ccc([Si]3(c4ccc(-c5ccccc5)cc4)c4ccccc4-c4cc(-n5c6ccccc6c6cc(-n7c8ccccc8c8ccccc87)ccc65)ccc43)cc2)cc1 ; c1ccc(-c2ccc([Si]3(c4ccc(-c5ccccc5)cc4)c4ccccc4-c4cc(-n5c6ccccc6c6ccc(-n7c8ccccc8c8ccccc87)cc65)ccc43)cc2)cc1 ; CC(C)(C)c1ccc2c(c1)c1cc(C(C)(C)C)ccc1n2-c1ccc2c(c1)-c1ccccc1[Si]2(c1ccc(-c2ccccc2)cc1)c1ccc(-c2ccccc2)cc1]

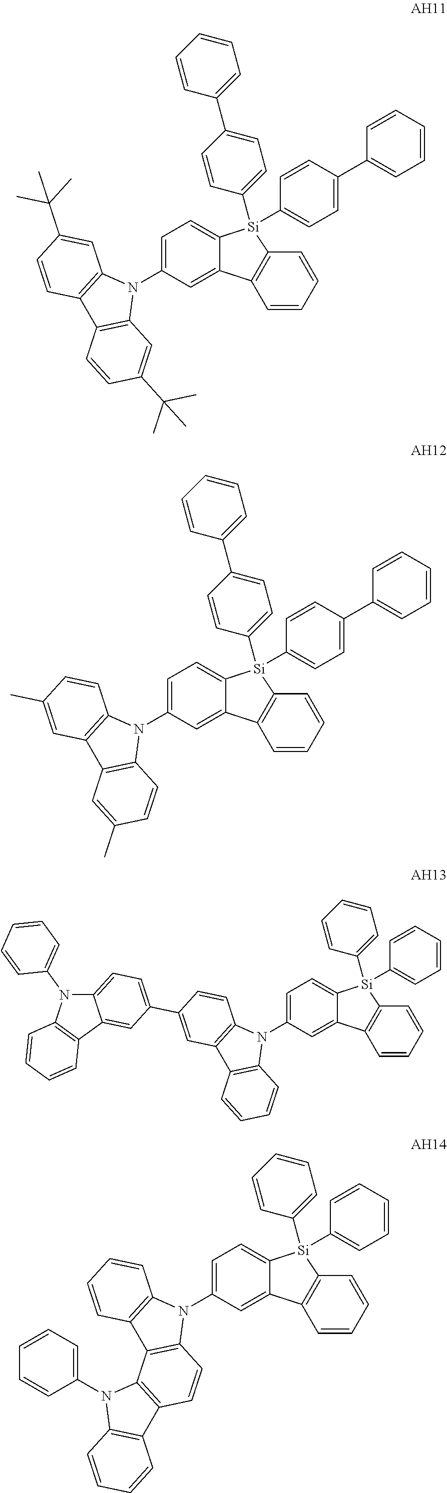

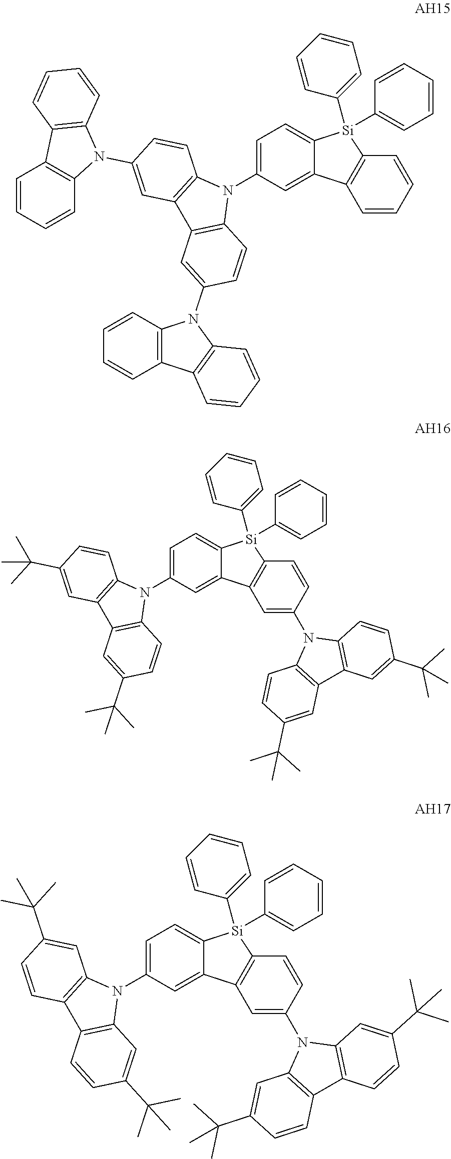

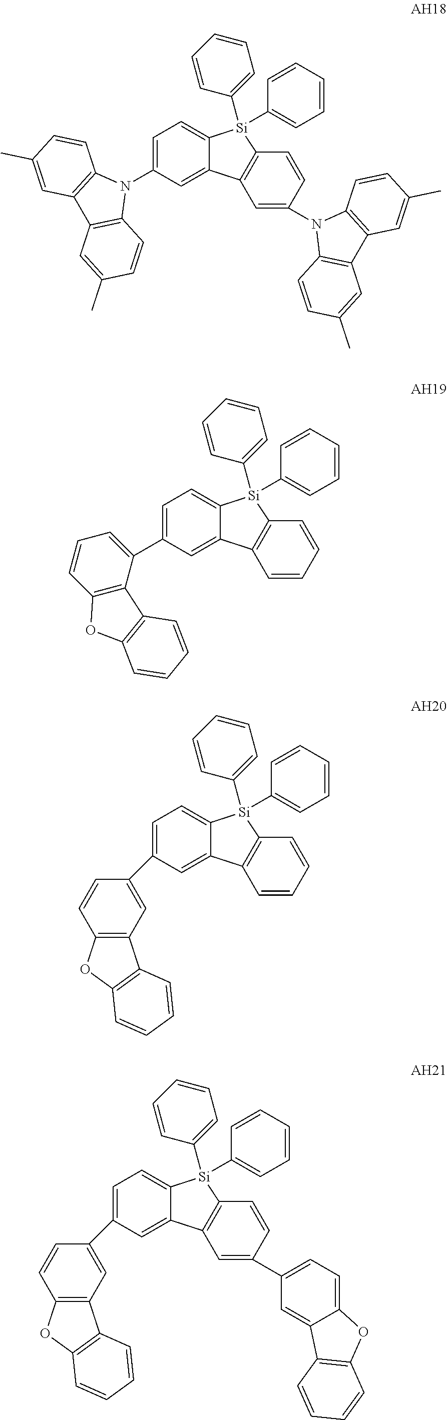

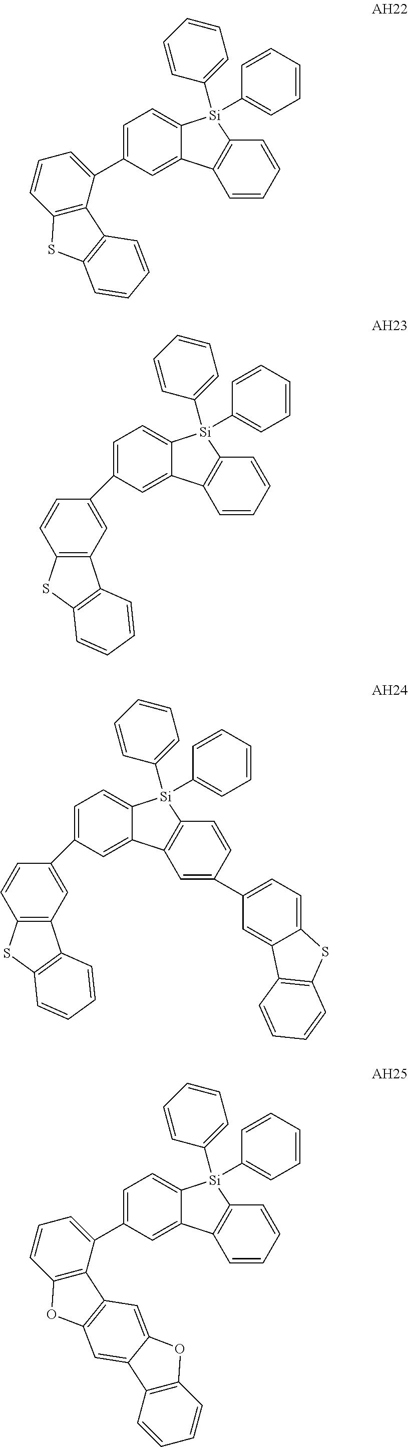 [SMILES: c1ccc([Si]2(c3ccccc3)c3ccccc3-c3cc(-c4cccc5sc6ccccc6c45)ccc32)cc1 ; c1ccc([Si]2(c3ccccc3)c3ccccc3-c3cc(-c4ccc5sc6ccccc6c5c4)ccc32)cc1 ; c1ccc([Si]2(c3ccccc3)c3ccc(-c4ccc5sc6ccccc6c5c4)cc3-c3cc(-c4ccc5sc6ccccc6c5c4)ccc32)cc1 ; c1ccc([Si]2(c3ccccc3)c3ccccc3-c3cc(-c4cccc5oc6cc7c(cc6c45)oc4ccccc47)ccc32)cc1]

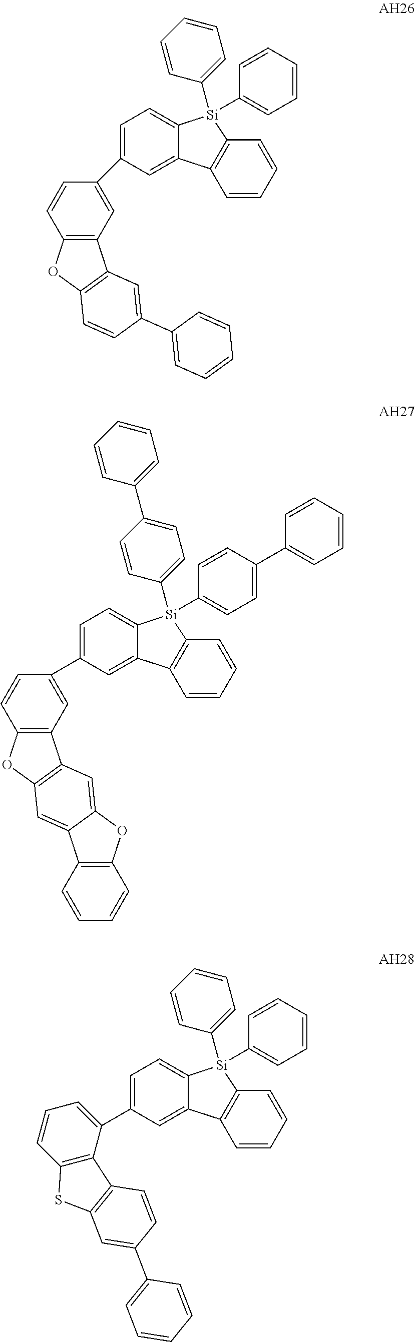 [SMILES: c1ccc(-c2ccc3oc4ccc(-c5ccc6c(c5)-c5ccccc5[Si]6(c5ccccc5)c5ccccc5)cc4c3c2)cc1 ; c1ccc(-c2ccc([Si]3(c4ccc(-c5ccccc5)cc4)c4ccccc4-c4cc(-c5ccc6oc7cc8c(cc7c6c5)oc5ccccc58)ccc43)cc2)cc1 ; c1ccc(-c2ccc3c(c2)sc2cccc(-c4ccc5c(c4)-c4ccccc4[Si]5(c4ccccc4)c4ccccc4)c23)cc1]

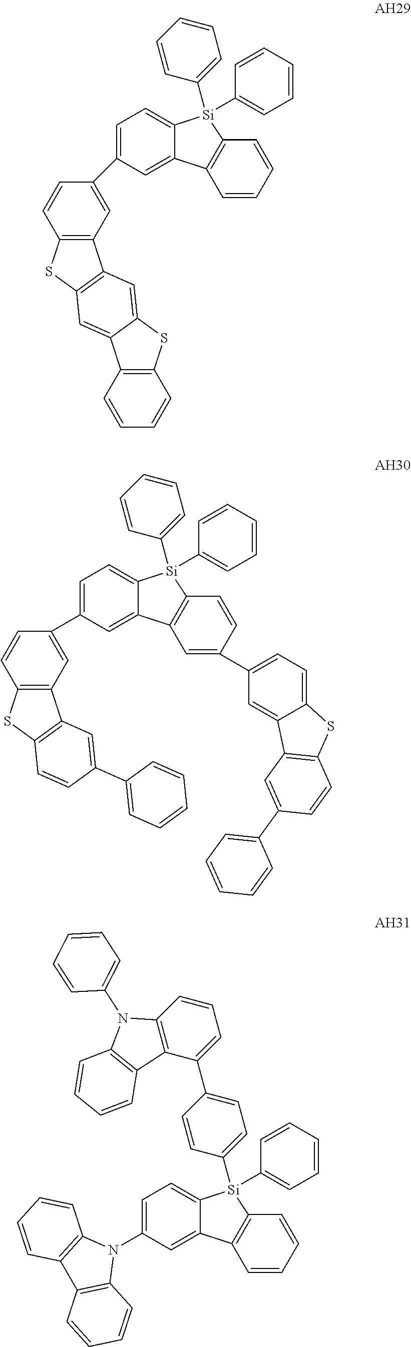 [SMILES: c1ccc([Si]2(c3ccccc3)c3ccccc3-c3cc(-c4ccc5sc6cc7c(cc6c5c4)sc4ccccc47)ccc32)cc1 ; c1ccc(-c2ccc3sc4ccc(-c5ccc6c(c5)-c5cc(-c7ccc8sc9ccc(-c%10ccccc%10)cc9c8c7)ccc5[Si]6(c5ccccc5)c5ccccc5)cc4c3c2)cc1 ; c1ccc(-n2c3ccccc3c3c(-c4ccc([Si]5(c6ccccc6)c6ccccc6-c6cc(-n7c8ccccc8c8ccccc87)ccc65)cc4)cccc32)cc1]

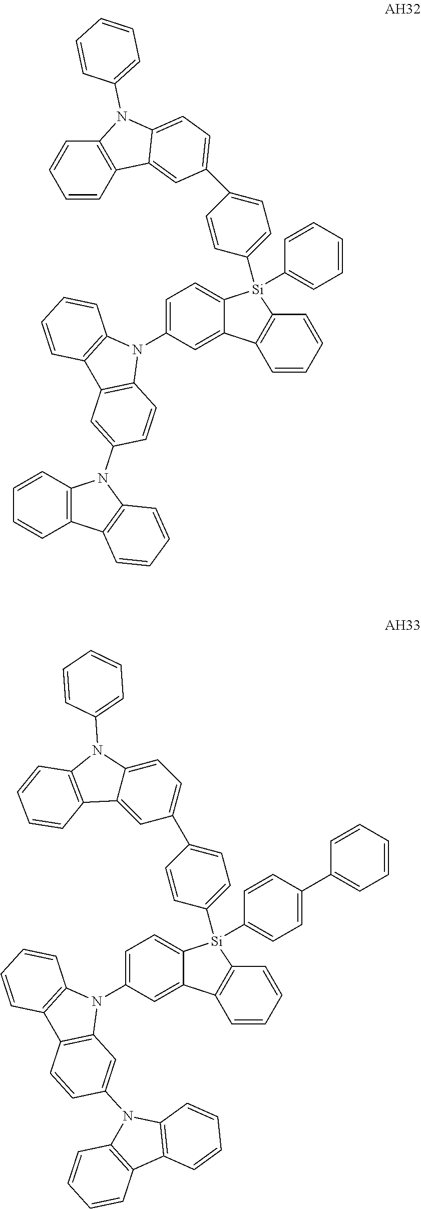 [SMILES: c1ccc(-n2c3ccccc3c3cc(-c4ccc([Si]5(c6ccccc6)c6ccccc6-c6cc(-n7c8ccccc8c8cc(-n9c%10ccccc%10c%10ccccc%109)ccc87)ccc65)cc4)ccc32)cc1 ; c1ccc(-c2ccc([Si]3(c4ccc(-c5ccc6c(c5)c5ccccc5n6-c5ccccc5)cc4)c4ccccc4-c4cc(-n5c6ccccc6c6ccc(-n7c8ccccc8c8ccccc87)cc65)ccc43)cc2)cc1]

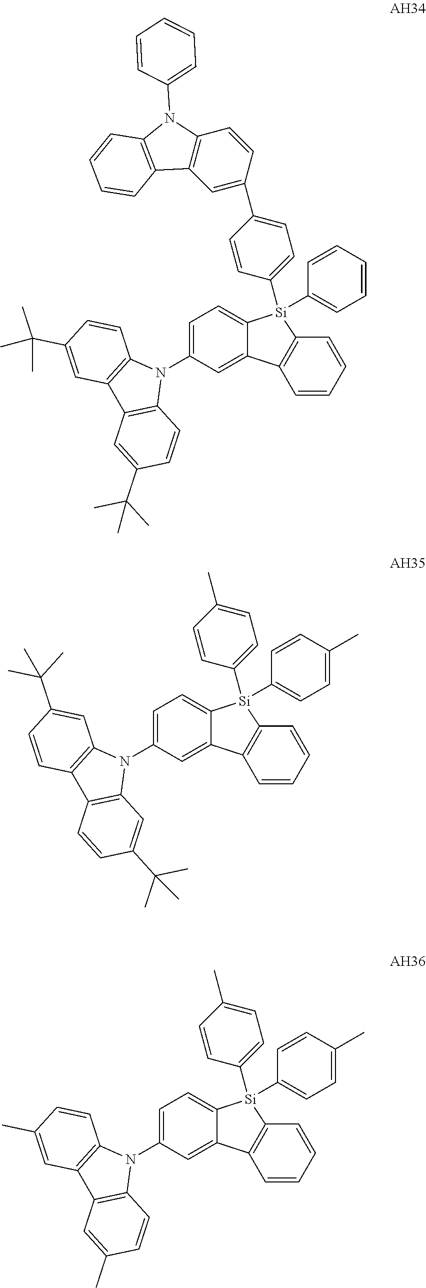

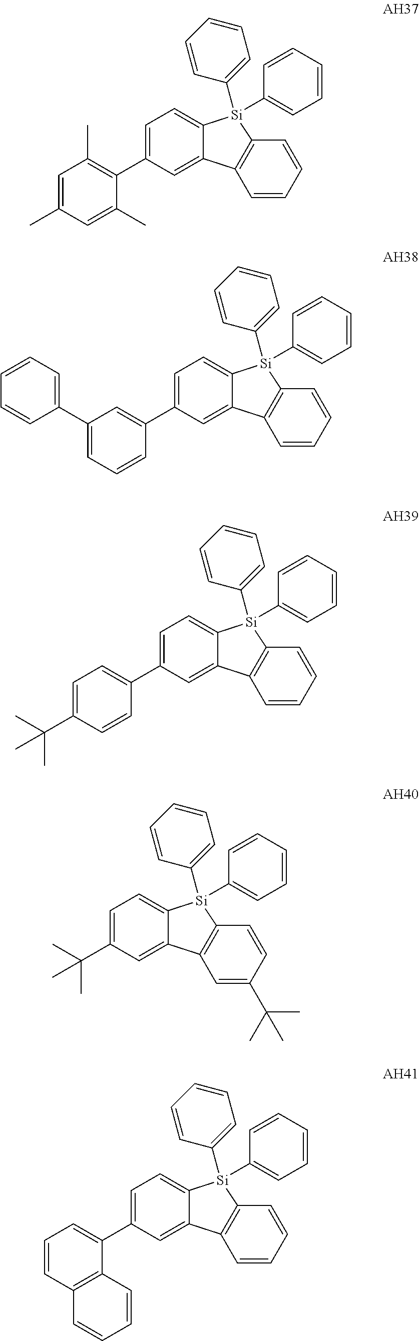 [SMILES: Cc1cc(C)c(-c2ccc3c(c2)-c2ccccc2[Si]3(c2ccccc2)c2ccccc2)c(C)c1 ; c1ccc(-c2cccc(-c3ccc4c(c3)-c3ccccc3[Si]4(c3ccccc3)c3ccccc3)c2)cc1 ; CC(C)(C)c1ccc(-c2ccc3c(c2)-c2ccccc2[Si]3(c2ccccc2)c2ccccc2)cc1 ; CC(C)(C)c1ccc2c(c1)-c1cc(C(C)(C)C)ccc1[Si]2(c1ccccc1)c1ccccc1 ; c1ccc([Si]2(c3ccccc3)c3ccccc3-c3cc(-c4cccc5ccccc45)ccc32)cc1]

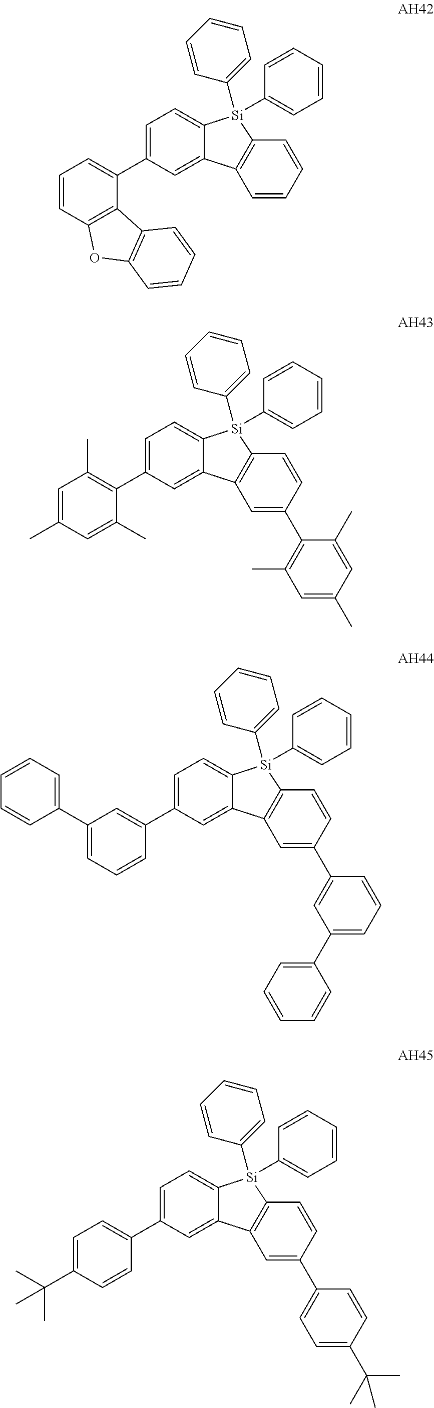

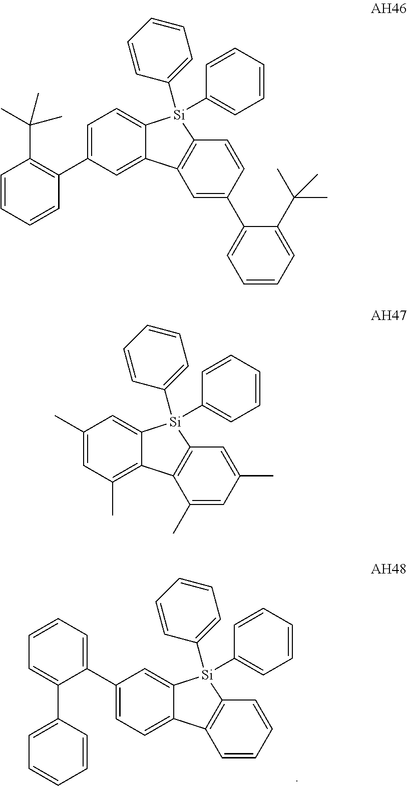

14. A heterocyclic compound represented by Formula 1: 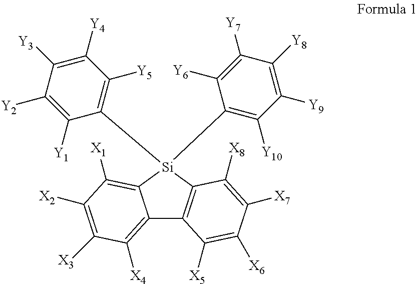
wherein, in Formula 1,
X₁ to X₈, and Y₁ to Y₁₀ are each independently hydrogen, deuterium, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 5 to 30 ring-forming carbon atoms.

15. The heterocyclic compound of claim 14, wherein at least one selected from among X₁ to X₈ and Y₁ to Y₁₀ is represented by Formula 1a or Formula 1b: 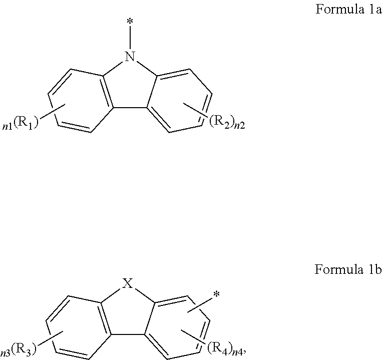
in Formula 1a and Formula 1b,
X being O or S,
R₁ to R₄ being each independently a hydrogen atom, a deuterium atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
n1 to n3 being each independently an integer of 0 to 4, and
n4 being an integer of 0 to 3.

16. The heterocyclic compound of claim 15, wherein:
at least one selected from among X₁ to X₈ is represented by Formula 1a or Formula 1b; and
the remaining among X₁ to X₈, which is not represented by Formula 1a or Formula 1b, and Y₁ to Y₁₀ are each independently hydrogen, deuterium, a substituted or unsubstituted methyl group, a substituted or unsubstituted phenyl group, or a substituted or unsubstituted carbazole group.

17. The heterocyclic compound of claim 14, wherein the heterocyclic compound represented by Formula 1 is represented by Formula 2 or Formula 3: 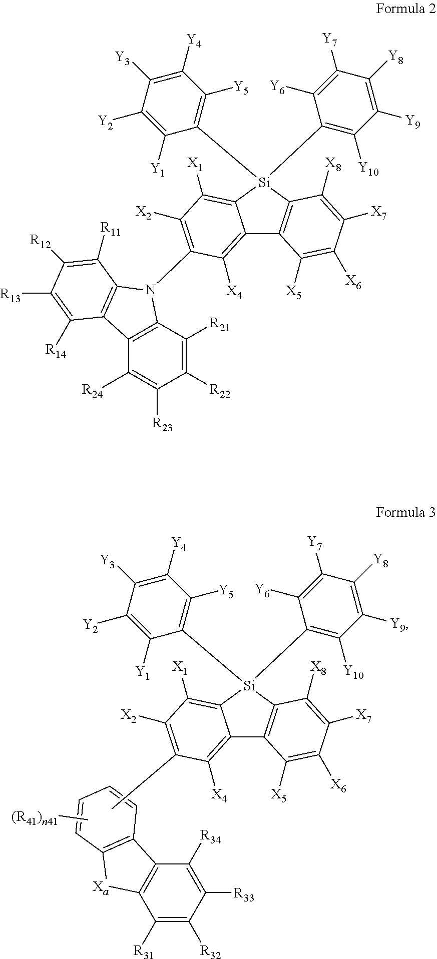
in Formula 2 and Formula 3,
Xₐ being 0 or 8,
R₁₁ to R₁₄, R₂₁ to R₂₄, and R₃₁ to R₃₄ being each independently hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
R₄₁ being hydrogen or deuterium,
n41 being an integer of 0 to 3, and
X₁, X₂, X₄ to X₈, and Y₁ to Y₁₀ being the same as defined in Formula 1.

18. The heterocyclic compound of claim 17, wherein the heterocyclic compound represented by Formula 2 is represented by Formula 2-1 or Formula 2-2: 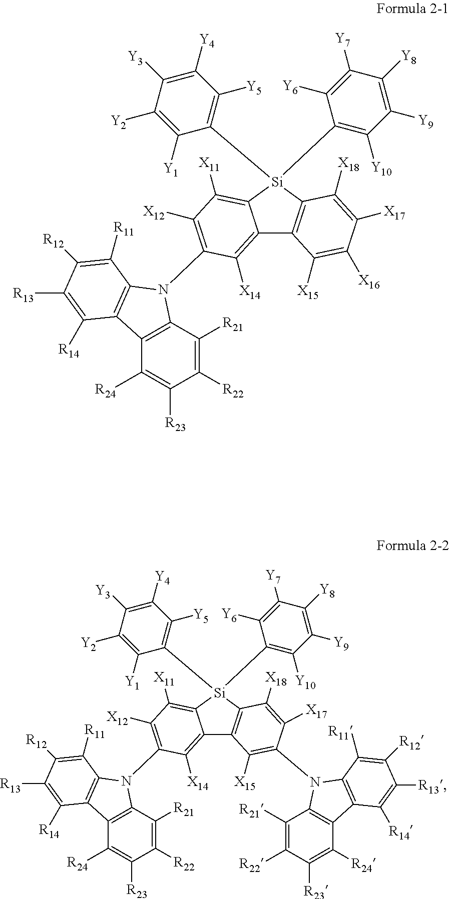
in Formula 2-1 and Formula 2-2,
X₁₁, X₁₂, X₁₄, X₁₅, X₁₆, X₁₇, and X₁₈ being each independently hydrogen or deuterium,
R₁₁′ to R₁₄′ and R₂₁′ to R₂₄′ being each independently hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring, and
Y₁ to Y₁₀, R₁₁ to R₁₄, and R₂₁ to R₂₄ being the same as defined in Formula 1 and Formula 2.

19. The heterocyclic compound of claim 17, wherein the heterocyclic compound represented by Formula 3 is represented by Formula 3-1 or Formula 3-2: 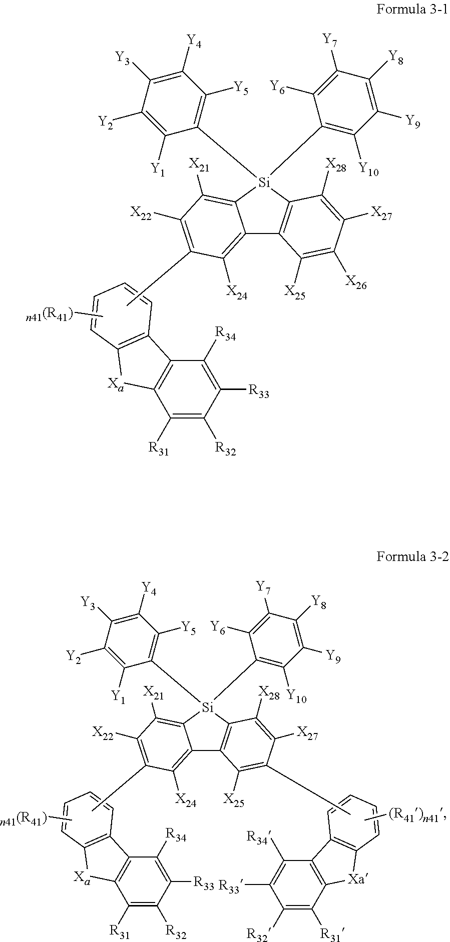
in Formula 3-1 and Formula 3-2,
Xₐ′ being O or S,
X₂₁, X₂₂, X₂₄, X₂₅, X₂₆, X₂₇, X₂₈, and R₄₁′ being each independently hydrogen or deuterium,
R₃₁′ to R₃₄′ being each independently hydrogen, deuterium, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and/or being bonded to an adjacent group to form a ring,
n41′ being an integer of 0 to 3, and
Xₐ, Y₁ to Y₁₀, R₃₁ to R₃₄, R₄₁, and n41 being the same as defined in Formula 1, and Formula 3.

20. The heterocyclic compound of claim 17, wherein Y₃ and Y₈ are each independently hydrogen, deuterium, a substituted or unsubstituted methyl group, a substituted or unsubstituted phenyl group, or a substituted or unsubstituted carbazole group.

21. The heterocyclic compound of claim 14, wherein the heterocyclic compound represented by Formula 1 is any one selected from among compounds in Compound Group 1:

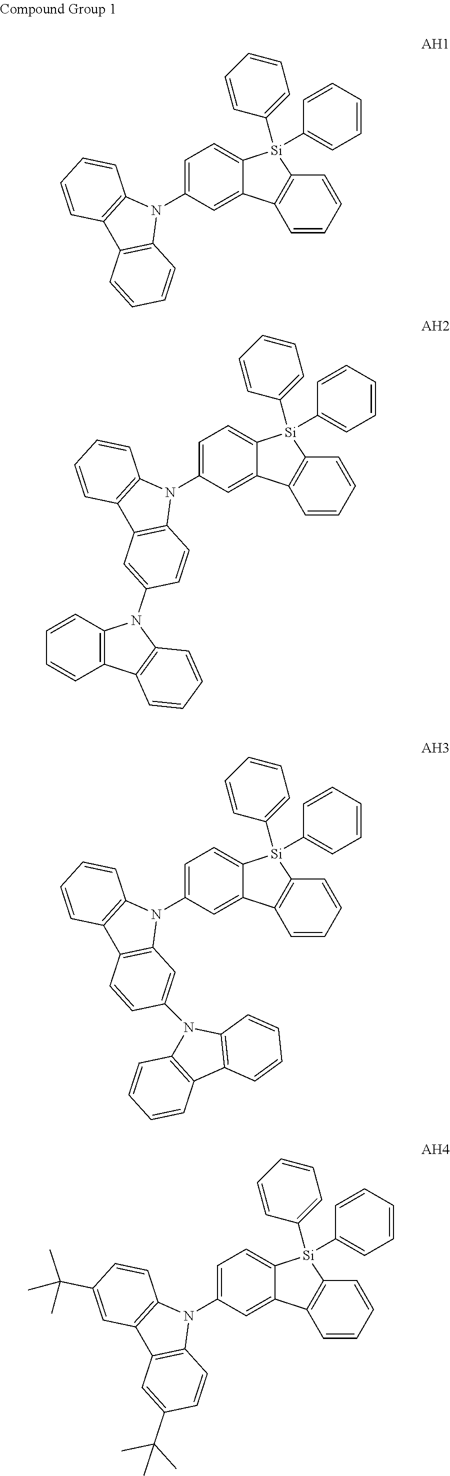 [SMILES: c1ccc([Si]2(c3ccccc3)c3ccccc3-c3cc(-n4c5ccccc5c5ccccc54)ccc32)cc1 ; c1ccc([Si]2(c3ccccc3)c3ccccc3-c3cc(-n4c5ccccc5c5cc(-n6c7ccccc7c7ccccc76)ccc54)ccc32)cc1 ; c1ccc([Si]2(c3ccccc3)c3ccccc3-c3cc(-n4c5ccccc5c5ccc(-n6c7ccccc7c7ccccc76)cc54)ccc32)cc1 ; CC(C)(C)c1ccc2c(c1)c1cc(C(C)(C)C)ccc1n2-c1ccc2c(c1)-c1ccccc1[Si]2(c1ccccc1)c1ccccc1]

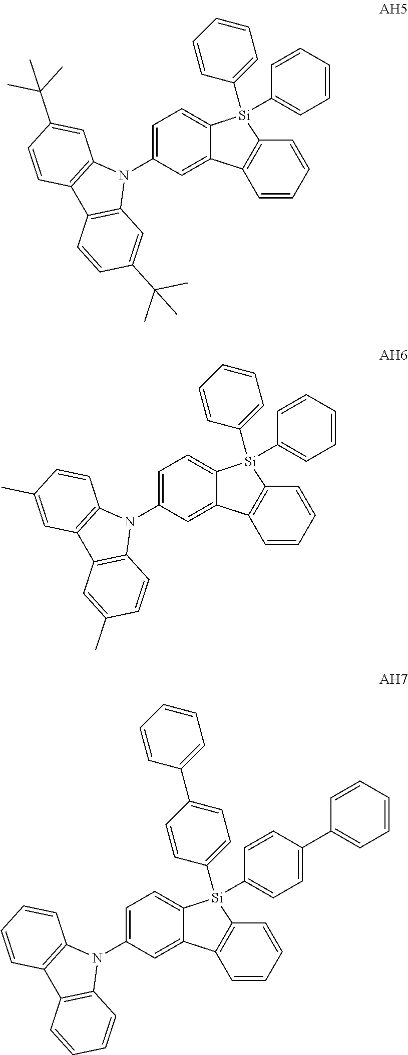 [SMILES: CC(C)(C)c1ccc2c3ccc(C(C)(C)C)cc3n(-c3ccc4c(c3)-c3ccccc3[Si]4(c3ccccc3)c3ccccc3)c2c1 ; Cc1ccc2c(c1)c1cc(C)ccc1n2-c1ccc2c(c1)-c1ccccc1[Si]2(c1ccccc1)c1ccccc1 ; c1ccc(-c2ccc([Si]3(c4ccc(-c5ccccc5)cc4)c4ccccc4-c4cc(-n5c6ccccc6c6ccccc65)ccc43)cc2)cc1]

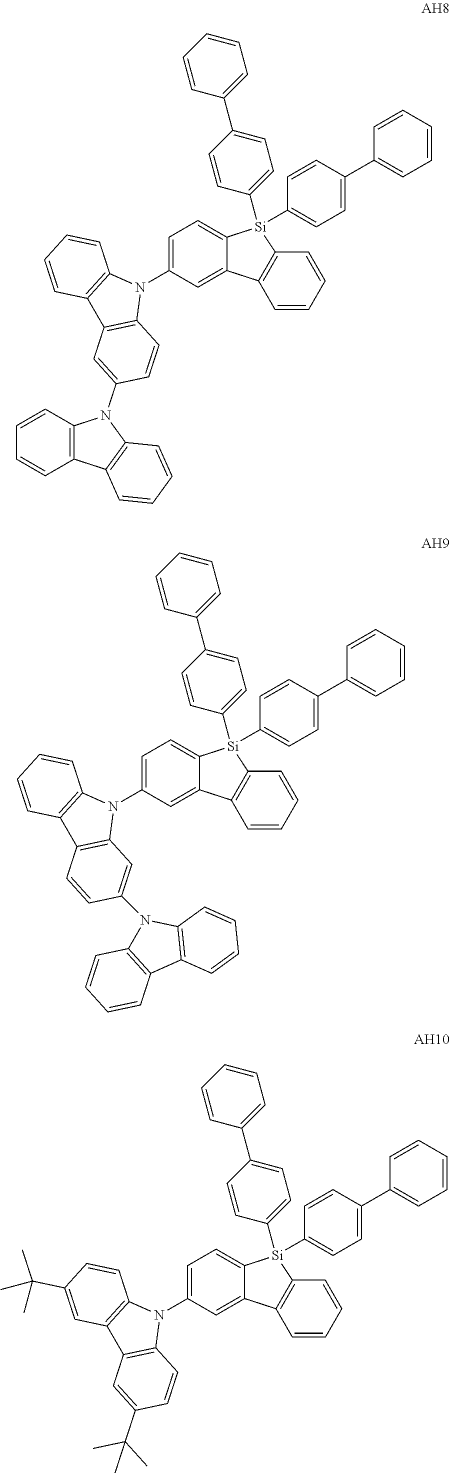 [SMILES: c1ccc(-c2ccc([Si]3(c4ccc(-c5ccccc5)cc4)c4ccccc4-c4cc(-n5c6ccccc6c6cc(-n7c8ccccc8c8ccccc87)ccc65)ccc43)cc2)cc1 ; c1ccc(-c2ccc([Si]3(c4ccc(-c5ccccc5)cc4)c4ccccc4-c4cc(-n5c6ccccc6c6ccc(-n7c8ccccc8c8ccccc87)cc65)ccc43)cc2)cc1 ; CC(C)(C)c1ccc2c(c1)c1cc(C(C)(C)C)ccc1n2-c1ccc2c(c1)-c1ccccc1[Si]2(c1ccc(-c2ccccc2)cc1)c1ccc(-c2ccccc2)cc1]

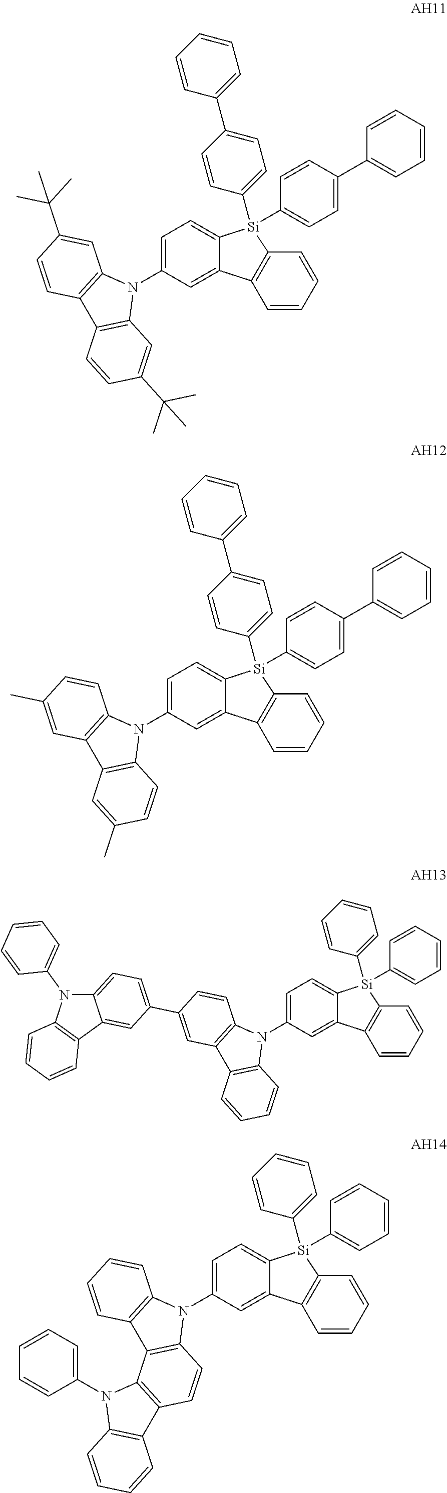

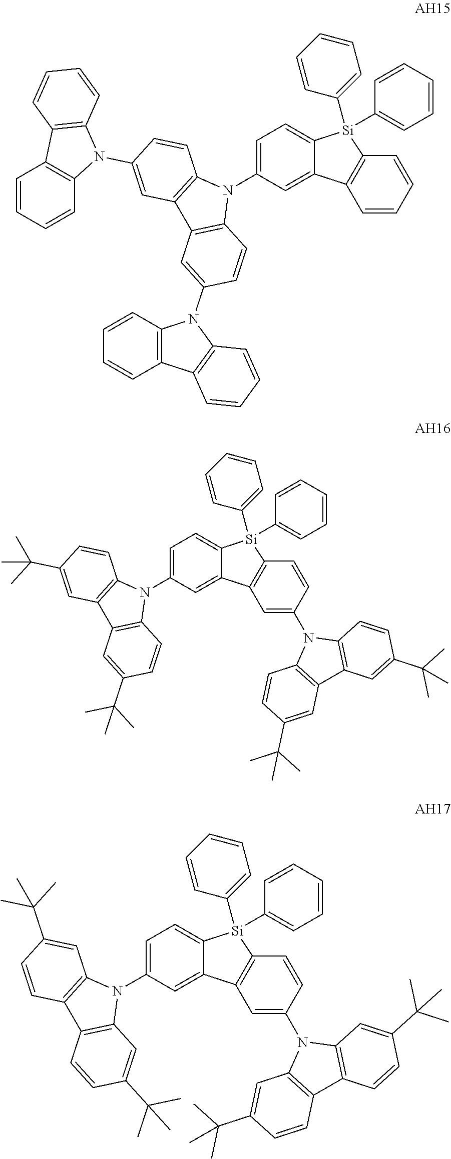

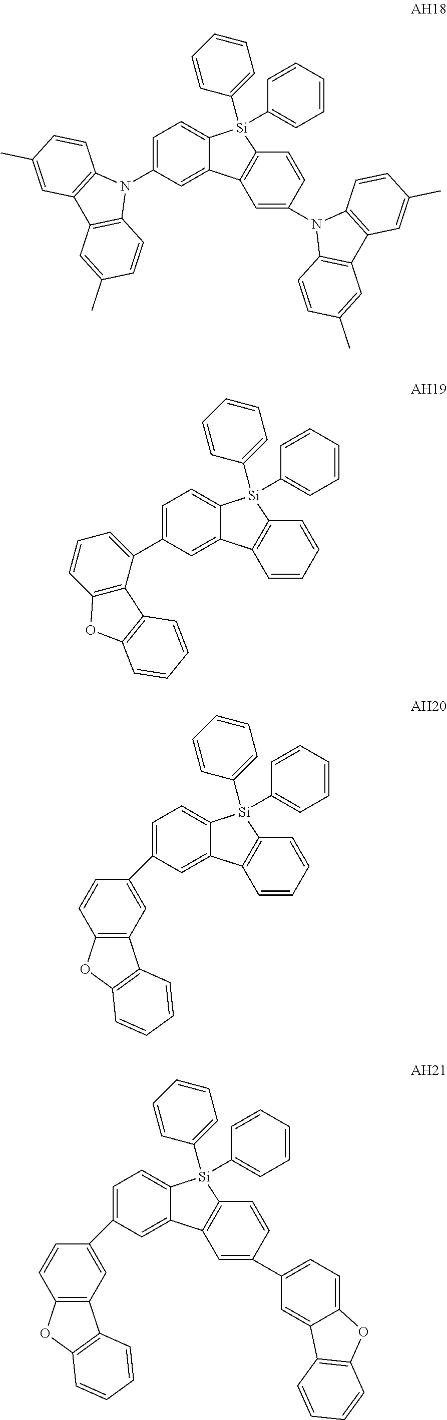

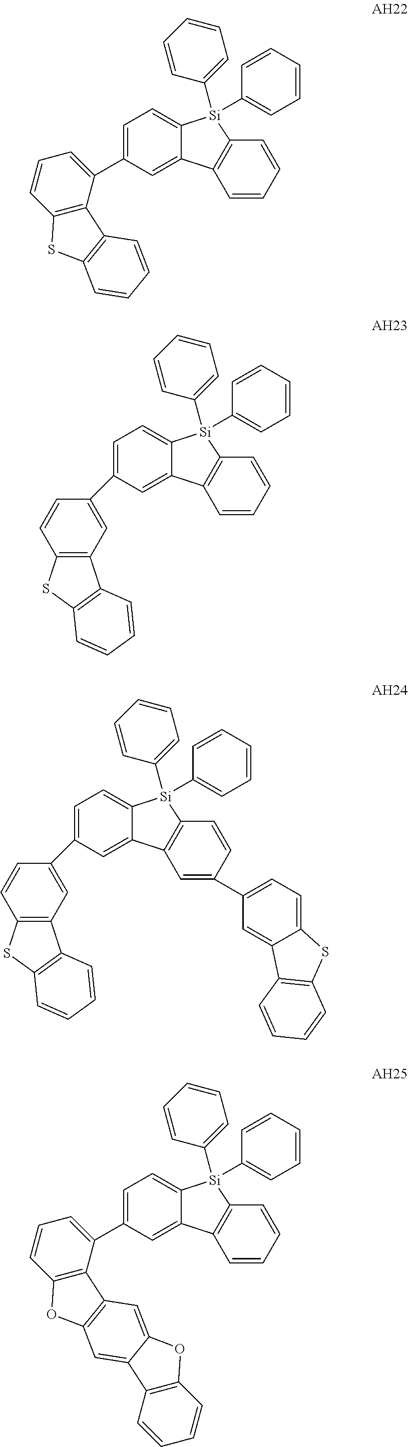 [SMILES: c1ccc([Si]2(c3ccccc3)c3ccccc3-c3cc(-c4cccc5sc6ccccc6c45)ccc32)cc1 ; c1ccc([Si]2(c3ccccc3)c3ccccc3-c3cc(-c4ccc5sc6ccccc6c5c4)ccc32)cc1 ; c1ccc([Si]2(c3ccccc3)c3ccc(-c4ccc5sc6ccccc6c5c4)cc3-c3cc(-c4ccc5sc6ccccc6c5c4)ccc32)cc1 ; c1ccc([Si]2(c3ccccc3)c3ccccc3-c3cc(-c4cccc5oc6cc7c(cc6c45)oc4ccccc47)ccc32)cc1]

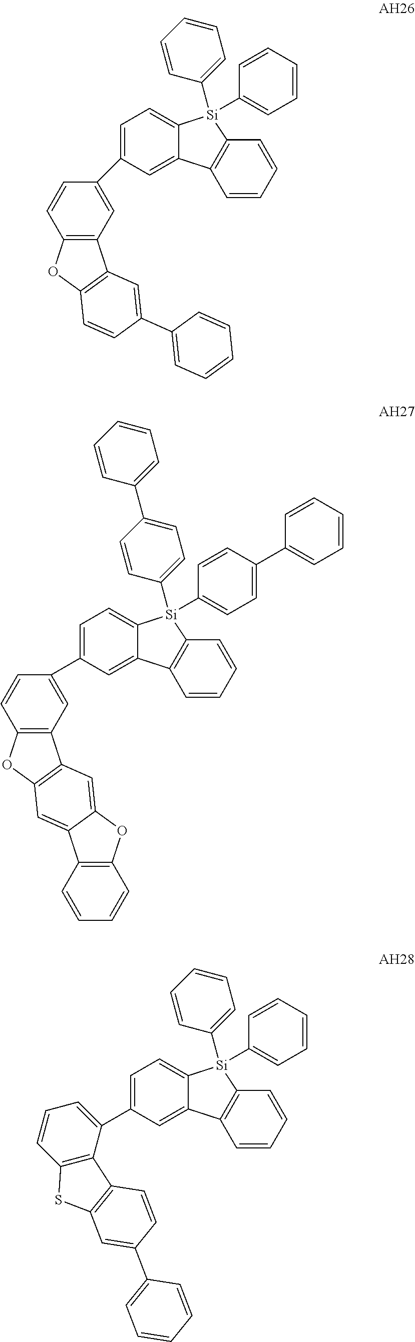 [SMILES: c1ccc(-c2ccc3oc4ccc(-c5ccc6c(c5)-c5ccccc5[Si]6(c5ccccc5)c5ccccc5)cc4c3c2)cc1 ; c1ccc(-c2ccc([Si]3(c4ccc(-c5ccccc5)cc4)c4ccccc4-c4cc(-c5ccc6oc7cc8c(cc7c6c5)oc5ccccc58)ccc43)cc2)cc1 ; c1ccc(-c2ccc3c(c2)sc2cccc(-c4ccc5c(c4)-c4ccccc4[Si]5(c4ccccc4)c4ccccc4)c23)cc1]

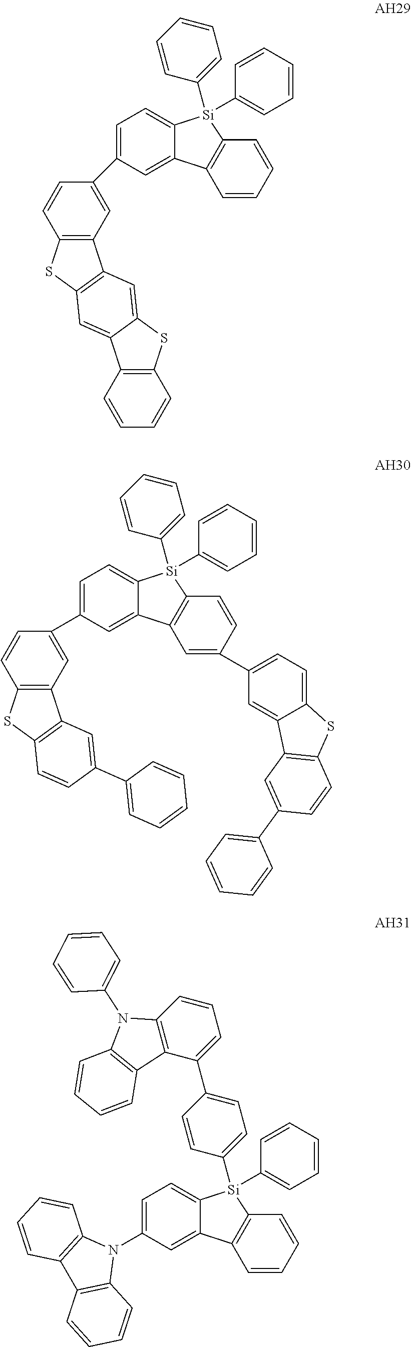 [SMILES: c1ccc([Si]2(c3ccccc3)c3ccccc3-c3cc(-c4ccc5sc6cc7c(cc6c5c4)sc4ccccc47)ccc32)cc1 ; c1ccc(-c2ccc3sc4ccc(-c5ccc6c(c5)-c5cc(-c7ccc8sc9ccc(-c%10ccccc%10)cc9c8c7)ccc5[Si]6(c5ccccc5)c5ccccc5)cc4c3c2)cc1 ; c1ccc(-n2c3ccccc3c3c(-c4ccc([Si]5(c6ccccc6)c6ccccc6-c6cc(-n7c8ccccc8c8ccccc87)ccc65)cc4)cccc32)cc1]

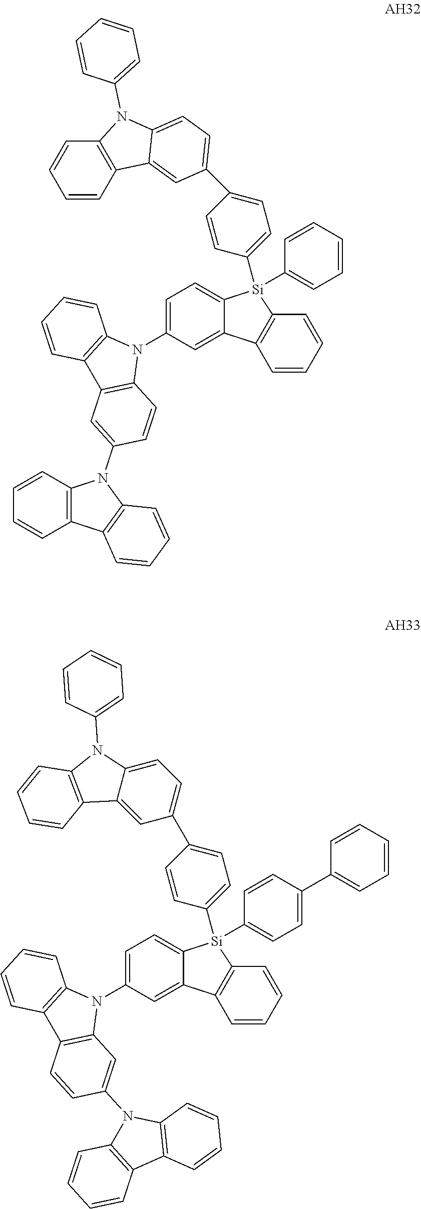 [SMILES: c1ccc(-n2c3ccccc3c3cc(-c4ccc([Si]5(c6ccccc6)c6ccccc6-c6cc(-n7c8ccccc8c8cc(-n9c%10ccccc%10c%10ccccc%109)ccc87)ccc65)cc4)ccc32)cc1 ; c1ccc(-c2ccc([Si]3(c4ccc(-c5ccc6c(c5)c5ccccc5n6-c5ccccc5)cc4)c4ccccc4-c4cc(-n5c6ccccc6c6ccc(-n7c8ccccc8c8ccccc87)cc65)ccc43)cc2)cc1]

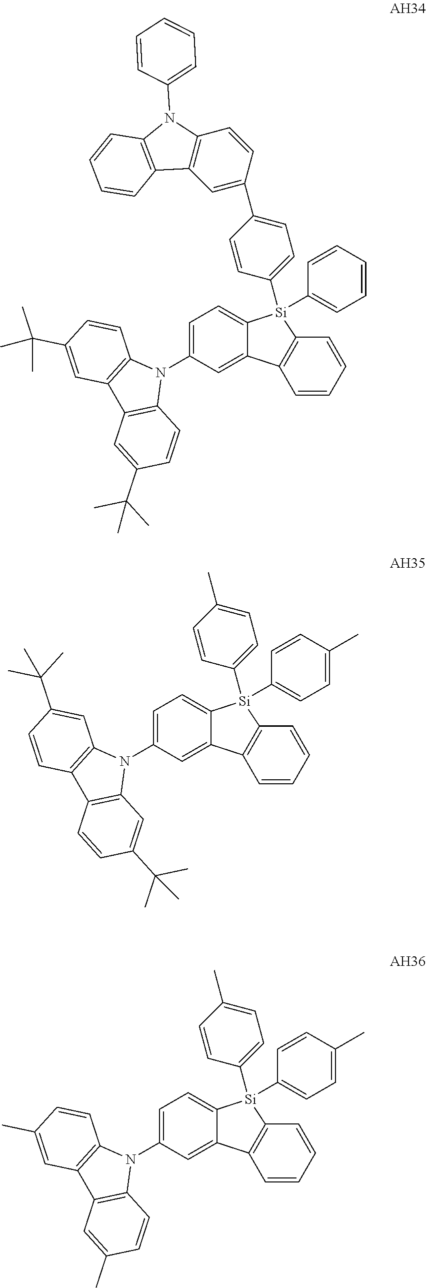

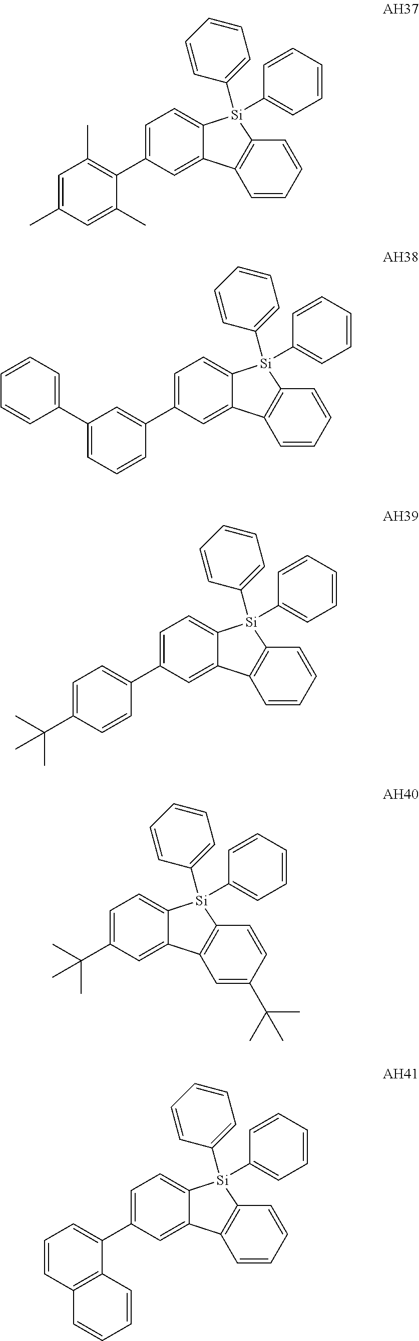 [SMILES: Cc1cc(C)c(-c2ccc3c(c2)-c2ccccc2[Si]3(c2ccccc2)c2ccccc2)c(C)c1 ; c1ccc(-c2cccc(-c3ccc4c(c3)-c3ccccc3[Si]4(c3ccccc3)c3ccccc3)c2)cc1 ; CC(C)(C)c1ccc(-c2ccc3c(c2)-c2ccccc2[Si]3(c2ccccc2)c2ccccc2)cc1 ; CC(C)(C)c1ccc2c(c1)-c1cc(C(C)(C)C)ccc1[Si]2(c1ccccc1)c1ccccc1 ; c1ccc([Si]2(c3ccccc3)c3ccccc3-c3cc(-c4cccc5ccccc45)ccc32)cc1]

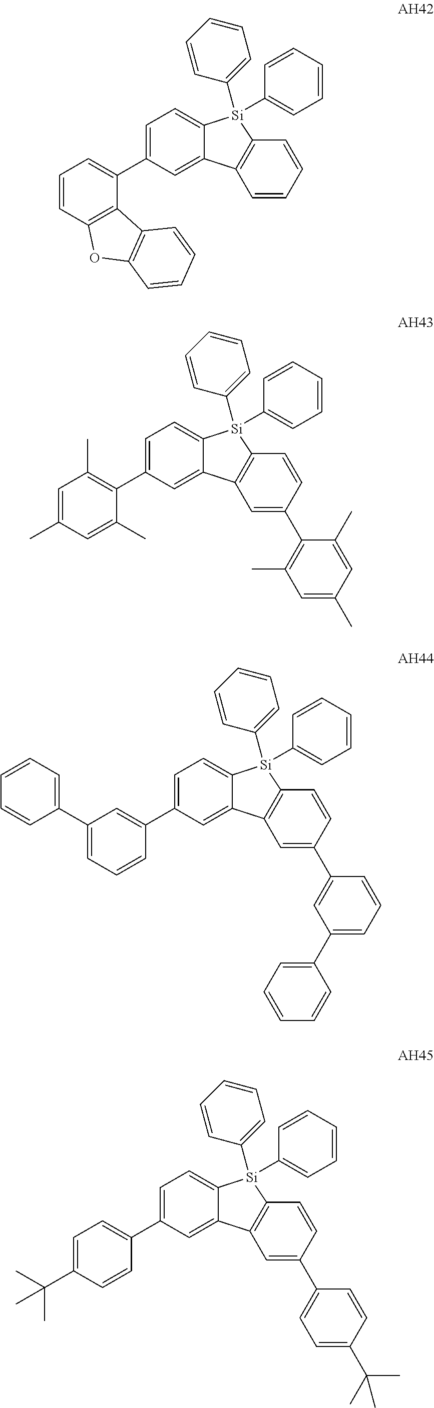

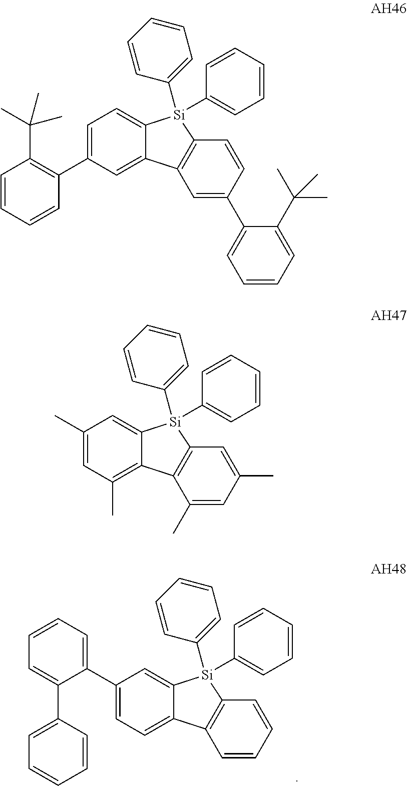

22. An electronic device, comprising:
a base layer;
a circuit layer on the base layer; and
a display element layer on the circuit layer and containing a light-emitting element,
wherein, the light-emitting element comprises a first electrode, a second electrode opposite to the first electrode, and an emission layer between the first electrode and the second electrode and comprising a heterocyclic compound represented by Formula 1: 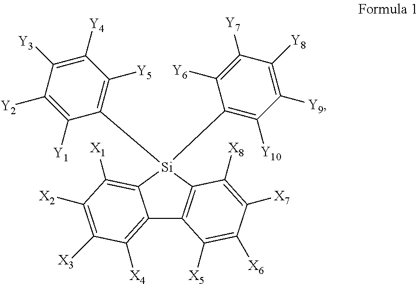
in Formula 1,
X₁ to X₈ and Y₁ to Y₁₀ being each independently hydrogen, deuterium, a substituted or unsubstituted alkyl group having 1 to 30 carbon atoms, a substituted or unsubstituted cycloalkyl group having 3 to 30 ring-forming carbon atoms, a substituted or unsubstituted aryl group having 6 to 30 ring-forming carbon atoms, or a substituted or unsubstituted heteroaryl group having 5 to 30 ring-forming carbon atoms.

23. The electronic device of claim 22, wherein the light-emitting element is to emit blue light.

24. The electronic device of claim 22, further comprising a light control layer containing a quantum dot.

25. The electronic device of claim 22, wherein the electronic device comprising a display device, and
wherein the display device comprises at least one of a television set, a monitor, an outdoor billboard, a personal computer, a laptop computer, a personal digital terminal, a display device for a vehicle, a game console, a portable electronic device, or a camera.
